(19) United States
(12) Patent Application Publication
(10) Pub. No.: US 2025/0116897 A1
(43) Pub. Date: Apr. 10, 2025

(54) LIGHT ABSORPTION FILTER, OPTICAL FILTER, MANUFACTURING METHOD FOR OPTICAL FILTER, ORGANIC ELECTROLUMINESCENT DISPLAY DEVICE, INORGANIC ELECTROLUMINESCENT DISPLAY DEVICE, AND LIQUID CRYSTAL DISPLAY DEVICE

(71) Applicant: FUJIFILM Corporation, Tokyo (JP)

(72) Inventors: Nobutaka FUKAGAWA, Kanagawa (JP); Daisuke SASAKI, Kanagawa (JP)

(73) Assignee: FUJIFILM Corporation, Tokyo (JP)

(21) Appl. No.: 18/905,725

(22) Filed: Oct. 3, 2024

Related U.S. Application Data
(63) Continuation of application No. PCT/JP2023/020289, filed on May 31, 2023.

(30) Foreign Application Priority Data
Jun. 2, 2022 (JP) 2022-090495
Aug. 1, 2022 (JP) 2022-122898
Nov. 4, 2022 (JP) 2022-177176

(51) Int. Cl. G02F 1/1335; C08K 5/00; C08K 5/3437; C08K 5/3445; C08K 5/435; C08K 5/47; C09D 5/32; C09D 7/41; G02B 5/20; H10K 59/80

(52) U.S. Cl. CPC G02F 1/133514; C09D 5/32; C09D 7/41; G02B 5/208; H10K 59/8792; C08K 5/0091; C08K 5/3437; C08K 5/3445; C08K 5/435; C08K 5/47

(57) ABSTRACT

A light absorption filter that contains a resin; a dye having a main absorption wavelength band in a wavelength range of 400 to 700 nm, including at least one of a specific azo-based coloring agent represented by any of General Formulae (i) to (iv) or a specific indoaniline-based coloring agent represented by General Formula (v); and a compound that generates a radical upon ultraviolet irradiation. There is also an optical filter that uses the light absorption filter and a manufacturing method for the optical filter, as well as an organic electroluminescent display device, an inorganic electroluminescent display device, or a liquid crystal display device, which includes the optical filter.

### CROSS-REFERENCE TO RELATED APPLICATIONS

This application is a Continuation of PCT International Application No. PCT/JP2023/020289 filed on May 31, 2023, which was published under PCT Article 21(2) in Japanese, and which claims priority under 35 U.S.C. § 119 (a) to Japanese Patent Application No. 2022-090495 filed in Japan on Jun. 2, 2022, Japanese Patent Application No. 2022-122898 filed in Japan on Aug. 1, 2022, and Japanese Patent Application No. 2022-177176 filed in Japan on Nov. 4, 2022. Each of the above applications is hereby expressly incorporated by reference, in its entirety, into the present application.

### BACKGROUND OF THE INVENTION

### 1. Field of the Invention

The present invention relates to a light absorption filter, an optical filter, a manufacturing method for the optical filter, an organic electroluminescent display device, an inorganic electroluminescent display device, and a liquid crystal display device.

### 2. Description of the Related Art

As image display devices, an organic electroluminescent (OLED) display device, an inorganic electroluminescent display device (inorganic EL display device), a liquid crystal display device, and the like have been used in recent years.

A liquid crystal display device is widely used year by year as a space-saving image display device with low power consumption. The liquid crystal display device is a non-light emitting element in which the liquid crystal panel itself displaying an image does not emit light, and thus the liquid crystal display device includes a backlight unit which is disposed on a rear surface of the liquid crystal panel and supplies light to the liquid crystal panel.

The OLED display device is a device that displays an image by utilizing self-luminescence of OLED elements. Therefore, the OLED display device has advantages that a high contrast ratio, a high color reproducibility, a wide viewing angle, a high-speed responsiveness, and a reduction in thickness and weight can be achieved, as compared with various display devices such as a liquid crystal display device and a plasma display device. In addition to these advantages, in terms of flexibility, research and development are being actively carried out as a next-generation display device.

The inorganic EL display device is a device that displays an image by utilizing self-luminescence of inorganic EL elements as a fluorescent material, instead of the OLED elements in the OLED display device. As a result of recent research, it is expected that a display device more excellent than the OLED display device in terms of a large screen size, a longer service life, and the like can be realized.

In the development of an image display device, it is known a technique of incorporating a light absorption filter as a configuration.

For example, in a liquid crystal display device, in a case where a white light emitting diode (LED) is used as a light source for a backlight unit, an attempt has been made to provide a light absorption filter in order to block light having unnecessary wavelengths emitted from the white LED. In addition, in the OLED display device, an attempt has been made to provide a light absorption filter from the viewpoint of suppressing the reflection of external light.

Regarding another form of the light absorption filter that is incorporated in an image display device, research has been also carried out on an optical filter having both a light absorptive portion having a light absorption effect and a portion in which the light absorbability has been eliminated (hereinafter, also simply referred to as a “light absorption property-eliminated portion”), which is obtained by eliminating the light absorbability of a desired portion. In particular, in a form in which an optical filter is used by being incorporated in an image display device, light absorption characteristics close to being colorless are required at a light absorption property-eliminated portion in the optical filter.

For example, WO2021/132674A describes a light absorption filter containing a resin; a dye that has a main absorption wavelength band in a wavelength range of 400 to 700 nm; and a compound that generates a radical upon ultraviolet irradiation, in which the dye includes a squaraine-based coloring agent represented by General Formula (1) or a benzylidene-based coloring agent described in WO2021/132674A or a cinnamylidene-based coloring agent represented by General formula (V). According to the light absorption filter described in WO2021/132674A, it is said that a high decolorization rate is exhibited upon ultraviolet irradiation, and absorption derived from a new coloration structure (hereinafter, also referred to as “secondary absorption”) associated with the decomposition of the dye upon ultraviolet irradiation hardly occurs, whereby high decolorizing properties can be obtained.

### SUMMARY OF THE INVENTION

However, although high decolorizing properties are obtained, in a case where the light absorption filter described in WO2021/132674A is used, it is necessary to heat the light absorption filter during ultraviolet irradiation in a case where a benzylidene-based coloring agent represented by General Formula (V) or a cinnamylidene-based coloring agent is used, and improvement has been required in terms of the productivity of the optical filter.

That is, an object of the present invention is to provide a light absorption filter that exhibits an excellent decolorization rate even in a case of being subjected to ultraviolet irradiation at room temperature and hardly causes secondary absorption associated with the decomposition of the dye upon ultraviolet irradiation.

In addition, another object of the present invention is to provide an optical filter using the above-described light absorption filter, where the optical filter includes an optical filter having a light absorptive portion and a light absorption property-eliminated portion at a desired position, and an OLED display device, an inorganic electroluminescent display device, and a liquid crystal display device, which include this optical filter, as well as a manufacturing method for an optical filter.

As a result of diligent studies in consideration of the above objects, the inventors of the present invention have found that even in a case where the light absorption filter is irradiated with ultraviolet rays at room temperature, excellent decolorizing properties can be obtained by allowing the light absorption filter to have a configuration in which an azo-based coloring agent or an indoaniline-based coloring agent having a specific structure is contained. Further studies have been carried out based on these findings, whereby the present invention has been completed.

That is, the above object has been achieved by the following means.

<1>

A light absorption filter comprising:
a resin;
a dye having a main absorption wavelength band in a wavelength range of 400 to 700 nm; and
a compound that generates a radical upon ultraviolet irradiation,
in which the dye includes at least one of an azo-based coloring agent represented by any of General Formulae (i) to (iv) or an indoaniline-based coloring agent represented by General Formula (v),

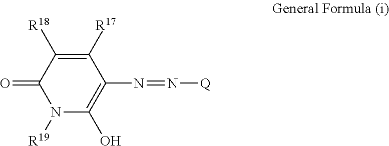

in the formula, R¹⁷ and R¹⁸ each independently represent a hydrogen atom or a monovalent substituent,
R¹⁹ represents a hydrogen atom, an aliphatic group, an aryl group, a heterocyclic group, a carbamoyl group, an alkoxycarbonyl group, an aryloxycarbonyl group, an acyl group, an alkylsulfonyl group, an arylsulfonyl group, or a sulfamoyl group, and
Q represents a diazo component residue,
provided that R¹⁷ to R¹⁹ and Q do not have a squaraine structure,

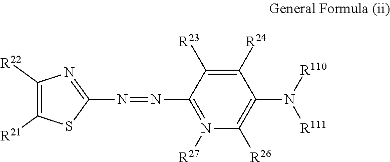

in the formula, R²¹ to R²⁴, R²⁶, and R²⁷ represent a hydrogen atom, a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, or a heterocyclic group,
R¹⁰⁸ to R¹²¹ represent a hydrogen atom, an acyclic hydrocarbon group, a monocyclic hydrocarbon group, a fused polycyclic hydrocarbon group, or a heterocyclic group, and
n is a positive integer,
here, the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, and a heterocyclic group,

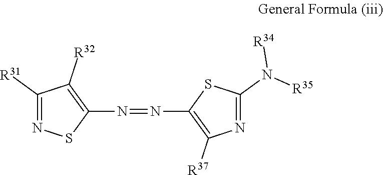

in the formula, R³¹ represents a hydrogen atom, an alkyl group, an alkoxy group, a cyano group, a carbonyl group, an aromatic group, or a heterocyclic group,
R³² represents a hydrogen atom, an alkyl group, an alkoxy group, a cyano group, a nitro group, a carbonyl group, an aromatic group, or a heterocyclic group,
R³⁴ and R³⁵ each independently represent a hydrogen atom, an alkyl group, or an aromatic group, and
R³⁷ represents a hydrogen atom, an alkyl group, an alkoxy group, a cyano group, a carbonyl group, an acylamino group, or an aromatic group,

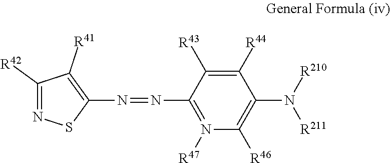

in the formula, R⁴¹ to R⁴⁴, R⁴⁶, and R⁴⁷ represent a hydrogen atom, a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, an acyclic hydrocarbon group, a monocyclic hydrocarbon group, a fused polycyclic hydrocarbon group, or a heterocyclic group,
R²⁰⁸ to R²²¹ represent a hydrogen atom, an acyclic hydrocarbon group, a monocyclic hydrocarbon group, a fused polycyclic hydrocarbon group, or a heterocyclic group, and
n is a positive integer,
here, the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, an acyclic hydrocarbon group, a monocyclic hydrocarbon group, a fused polycyclic hydrocarbon group, and a heterocyclic group,

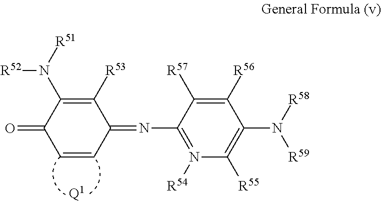

in the formula, Q¹ represents an atomic group that contains at least one nitrogen atom and is necessary for forming a 5- to 7-membered nitrogen-containing heterocyclic ring together with carbon atoms to be bonded,
R⁵¹ represents an acyl group, an alkoxycarbonyl group, an aryloxycarbonyl group, an aminocarbonyl group, or a sulfonyl group,
R⁵² represents a hydrogen atom or an alkyl group,
R⁵³ to R⁵⁷ represent a hydrogen atom, an alkyl group, an alkoxy group, an acylamino group, an alkylsulfonylamino group, or a halogen atom, and
R⁵⁸ and R⁵⁹ represent a hydrogen atom, an alkyl group, or an aryl group.
   <2>

The light absorption filter according to <1>, in which the compound that generates the radical upon the ultraviolet irradiation includes a combination of a compound A having an acid group and a compound B having a structure that is capable of forming a hydrogen bond with the acid group contained in the compound A.

<3>

The light absorption filter according to <1> or <2>, in which the dye having the main absorption wavelength band in the wavelength range of 400 to 700 nm includes a squaraine-based coloring agent represented by General Formula (1),

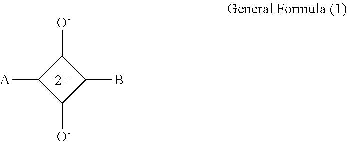

in the formula, A and B each independently represent an aryl group which may have a substituent, a heterocyclic group which may have a substituent, or —CH=G,
where G represents a heterocyclic group which may have a substituent.
   <4>

The light absorption filter according to <2>, in which the compound A having the acid group is chemically bonded to a polymer that constitutes the resin.

<5>

The light absorption filter according to any one of <1> to <4>, in which in the light absorption filter, the dye having the main absorption wavelength band in the wavelength range of 400 to 700 nm undergoes a chemical change and decolorizes upon ultraviolet irradiation.

<6>

An optical filter that is obtained by subjecting the light absorption filter according to any one of <1> to <5> to mask exposure by ultraviolet irradiation.

<7>

An organic electroluminescent display device, an inorganic electroluminescent display device, or a liquid crystal display device, comprising:
the optical filter according to <6>.
   <8>

The organic electroluminescent display device, the inorganic electroluminescent display device, or the liquid crystal display device according to <7>, in which a layer that inhibits light absorption of the compound that generates the radical upon the ultraviolet irradiation is provided on a viewer side with respect to the optical filter.

<9>

A manufacturing method for an optical filter comprising:
irradiating the light absorption filter according to any one of <1> to <5> with an ultraviolet ray to carry out mask exposure.

In the present invention, in a case where there are a plurality of substituents, linking groups, and the like (hereinafter, referred to as substituents and the like) denoted by specific reference numerals or formulae, or in a case where a plurality of substituents and the like are defined at the same time, the respective substituents and the like may be the same as or different from each other unless otherwise specified. The same applies to the definition of the number of substituents or the like. In addition, in a case where a plurality of substituents and the like come close to each other (particularly in a case where the substituents and the like are adjacent to each other), the substituents and the like may also be linked to each other to form a ring unless otherwise specified. In addition, unless otherwise specified, rings, for example, alicyclic rings, aromatic rings, and heterocyclic rings may be further fused to form a fused ring.

In the present invention, unless otherwise specified, the light absorption filter may contain one kind of each of components constituting the light absorption filter (a dye and a compound that generates a radical upon ultraviolet irradiation, as well as another component that may be appropriately contained) or may contain two or more kinds thereof. The same applies to an optical filter produced by using the light absorption filter according to the aspect of the present invention.

Unless otherwise specified, the optical filter according to the aspect of the present invention can preferably apply the description regarding the light absorption filter according to the aspect of the present invention, except that it has a light absorption property-eliminated portion formed by ultraviolet irradiation.

In the present invention, in a case where an E type double bond and a Z type double bond are present in a molecule, the double bond may be any one thereof or may be a mixture thereof, unless otherwise specified.

In the present invention, the denotation of a compound (including a complex) is used to have a meaning including not only the compound itself but also a salt thereof, and an ion thereof. In addition, it is meant to include those in which a part of the structure is changed within a range where the effect of the present invention is not impaired. Furthermore, it is meant that a compound, which is not specified to be substituted or unsubstituted, may have any substituent within a range where the effect of the present invention is not impaired. The same applies to the definition of a substituent or a linking group.

In addition, in the present invention, the numerical value range indicated by using “to” means a range including the numerical values before and after “to” as the lower limit value and the upper limit value, respectively.

In the present invention, the “composition” includes a mixture in which the component concentration varies within a range in which a desired function is not impaired, in addition to a mixture in which the component concentration is constant (respective components are uniformly dispersed).

In the present invention, the description of “having a main absorption wavelength band in a wavelength range of XX to YY nm” means that a wavelength at which the maximal absorption is exhibited (that is, the maximal absorption wavelength) is present in the wavelength range of XX to YY nm. Therefore, in a case where the maximal absorption wavelength is present in the above-described wavelength range, the entire absorption band including this wavelength may be in the above-described wavelength range or may also extend up to the outside of the above-described wavelength range. In addition, in a case where there are a plurality of maximal absorption wavelengths, it suffices that a maximal absorption wavelength at which the highest absorbance is exhibited is present in the above-described wavelength range. That is, the maximal absorption wavelength other than the maximal absorption wavelength at which the highest absorbance is exhibited may be present either inside or outside the above-described wavelength range of XX to YY nm.

In the present invention, “(meth)acrylate” represents either or both of acrylate and methacrylate, “(meth)acrylic acid” represents any one or both of acrylic acid and methacrylic acid and “(meth)acryloyl” represents any one or both of acryloyl and methacryloyl.

The light absorption filter according to the aspect of the present invention exhibits an excellent decolorization rate in a case of being subjected to ultraviolet irradiation at room temperature and hardly causes secondary absorption associated with the decomposition of the dye upon ultraviolet irradiation.

In addition, the optical filter according to the aspect of the present invention can have a light absorptive portion and a light absorption property-eliminated portion at a desired position.

In addition, the OLED display device, the inorganic electroluminescent display device, and the liquid crystal display device according to the aspect of the present invention include the optical filter according to the aspect of the present invention.

The optical filter according to the aspect of the present invention can be preferably manufactured by the manufacturing method according to the aspect of the present invention.

### BRIEF DESCRIPTION OF THE DRAWINGS

FIG. 1 is a schematic view illustrating an outline of one embodiment of a liquid crystal display device having an optical filter according to the present invention.

FIG. 2 is a schematic view showing a simulation configuration regarding the reflection of external light using a light absorption filter according to the embodiment of the present invention.

### DESCRIPTION OF THE PREFERRED EMBODIMENTS

### [Light Absorption Filter]

A light absorption filter according to an embodiment of the present invention contains a resin, a dye (hereinafter, also simply referred to as a “dye”) having a main absorption wavelength band in a wavelength range of 400 to 700 nm, and a compound that generates a radical upon ultraviolet irradiation, where the dye includes at least one of an azo-based coloring agent represented by any of General Formulae (i) to (iv) or an indoaniline-based coloring agent represented by General Formula (v).

In the present invention, the main absorption wavelength band of a dye is the main absorption wavelength band of the dye, which is measured in the state of being a light absorption filter. Specifically, in examples described later, it is measured in a state of being a base material-attached light absorption filter under the conditions described in the section of the absorbance of the light absorption filter.

In the light absorption filter according to the embodiment of the present invention, the “dye” is dispersed (preferably dissolved) in the resin to make the light absorption filter a layer that shows a specific absorption spectrum derived from the dye. This dispersion may be any type of dispersion, such as a random type or a regular type.

The light absorption filter according to the embodiment of the present invention contains a resin; a dye having a main absorption wavelength band in a wavelength range of 400 to 700 nm, where the dye includes at least one of an azo-based coloring agent represented by any of General Formulae (i) to (iv) or an indoaniline-based coloring agent represented by General Formula (v); and a compound that generates a radical upon ultraviolet irradiation. The azo-based coloring agent represented by General Formula (i) described later is a dye having a main absorption wavelength band in a wavelength range of approximately 400 to 500 nm, the azo-based coloring agent represented by any of General Formulae (ii) to (iv) described later is a dye having a main absorption wavelength band in a wavelength range of approximately 450 to 600 nm, and the indoaniline-based coloring agent represented by General Formula (v) described later is a dye having a main absorption wavelength band in a wavelength range of approximately 580 to 700 nm. The light absorption filter according to the embodiment of the present invention, which has such a configuration, can exhibit high decolorizing properties even in a case of being subjected to ultraviolet irradiation at room temperature (which means 10° C. to 30° C.), which is a mild environment.

The reason for this is presumed as follows: the azo-based coloring agent represented by General Formula (i) described later exhibits excellent decolorizing properties since a hydroxy group on a pyridine ring bonded to an azo group (—N═N—) contributes to the generation of radical species, and thus an excellent decolorization rate is obtained even in a case where the ultraviolet irradiation is carried out under a mild temperature condition such as room temperature, and the azo-based coloring agent itself represented by General Formula (i) hardly causes secondary absorption associated with the decomposition of the dye. The azo-based coloring agent represented by any of General Formulae (ii) to (iv) has a structure in which an electron donating group (an amino group) is substituted at one terminal of a chromophore and an electron withdrawing group (a thiazole group or an isothiazole group) is substituted at the other terminal thereof. In general, the effect of stabilizing a radical by substituting both an electron donating group and an electron withdrawing group with respect to a radical center is known as a “captodative effect”, which is described, for example, on pages 148 to 154 of Acc. Chem. Res., vol. 18 (1985). It is considered that since the azo-based coloring agent represented by any of General Formulae (ii) to (iv) is also likely to generate a radical due to the “captodative effect” described above, an excellent decolorization rate is obtained in a case of being irradiated with ultraviolet rays. In addition, it is considered that since the indoaniline-based coloring agent represented by General Formula (v) also has a structure in which an electron donating group (an amino group) is substituted at one terminal of a chromophore and an electron withdrawing group (a carbonyl group) is substituted at the other terminal thereof, an excellent decolorization rate is obtained due to the “captodative effect” described above, even in a case where the ultraviolet irradiation is carried out under a mild temperature condition such as room temperature, and the azo-based coloring agent itself represented by any of General Formulae (ii) to (iv) and the indoaniline-based coloring agent itself represented by General Formula (v) hardly cause secondary absorption associated with the decomposition of the dye, excellent decolorizing properties are exhibited.

On the other hand, as the dye having a main absorption wavelength band in a wavelength range of approximately 400 to 500 nm among the dyes having a main absorption wavelength band in a wavelength range of 400 to 700 nm described in WO02021/132674A, a benzylidene-based coloring agent represented by General Formula (V) or a cinnamylidene-based coloring agent, which is described in WO02021/132674A, is described. However, in a case where a light absorption filter containing this coloring agent is subjected to ultraviolet irradiation at room temperature (which means 10° C. to 30° C.), which is a mild environment, the decolorization rate is as low as 84% as described in Comparative Example No. c202 described later, and the decolorizing properties at room temperature are deteriorated. Due to containing an azo-based coloring agent represented by General Formula (i) described later instead of the benzylidene-based coloring agent represented by General Formula (V) or the cinnamylidene-based coloring agent, which is described in WO02021/132674A, the light absorption filter according to the embodiment of the present invention has a main absorption wavelength band in a wavelength range of approximately 400 to 500 nm, and can exhibit excellent decolorizing properties even in a case of being subjected to ultraviolet irradiation at room temperature (which means 10° C. to 30° C.), which is a mild environment.

In addition, due to containing the azo-based coloring agent represented by any of General Formulae (ii) to (iv) described later or the indoaniline-based coloring agent represented by General Formula (v), the light absorption filter according to the embodiment of the present invention has a main absorption wavelength band in a wavelength range of approximately 450 to 700 nm and can exhibit excellent decolorizing properties equivalent to those of a light absorption filter containing the squaraine-based coloring agent represented by General Formula (1) described in WO02021/132674A, even in a case of being subjected to ultraviolet irradiation at room temperature (which means 10° C. to 30° C.), which is a mild environment.

In a case where the light absorption filter according to the embodiment of the present invention contains a compound A having an acid group as will be described later, as a compound that generates a radical upon ultraviolet irradiation, and a compound B having a structure that is capable of forming a hydrogen bond with the acid group contained in the compound A, the efficiency of generating radical species upon ultraviolet irradiation is improved as compared with a case where a commonly used photoradical generator such as a benzophenone compound is used. Therefore, even in a case where the ultraviolet irradiation is carried out under a mild temperature condition such as room temperature, sufficient radical species are generated, the radical species directly or indirectly react with the dye, and then the dye is decomposed, whereby the dye is faded and decolorized, which makes it possible to exhibit a more excellent decolorization rate.

In addition, in the light absorption filter according to the embodiment of the present invention, in a case where the compound A having an acid group is bonded to a polymer that constitutes the resin, a radical is generated in the vicinity of the dye upon ultraviolet irradiation, and an effect that the radical easily reacts with the dye is exhibited.

In addition, “the compound A having an acid group” described later may be bonded to a polymer that constitutes the resin. Further, “the compound B having a structure that is capable of forming a hydrogen bond with the acid group contained in the compound A” described above is dispersed (preferably dissolved) in the resin by forming a hydrogen bond with the compound A or forms a hydrogen bond with the compound A in the resin in a case where the compound A containing the acid group is bonded to a polymer that constitutes the resin. In a case of being subjected to ultraviolet irradiation, the compound B generates a radical, and this radical easily reacts with a dye, which makes it possible for a dye to be efficiently faded and decolorized by a mechanism in which the generated radical reacts with a dye in the vicinity.

As described above, in the light absorption filter according to the embodiment of the present invention, the dye is chemically changed to be decolorized upon ultraviolet irradiation. That is, the light absorption filter according to the embodiment of the present invention has such a characteristic that the dye is chemically changed to be decolorized upon ultraviolet irradiation.

<Dye Having Main Absorption Wavelength Band in Wavelength Range of 400 to 700 nm>

Specific examples of the dye that is used in the present invention having a main absorption wavelength band in a wavelength range of 400 to 700 nm include tetraazaporphyrin (TAP)-based, squaraine (SQ)-based, cyanine (CY)-based, benzylidene-based, cinnamylidene-based, azo-based, and indoaniline-based coloring agents (dyes).

In the present invention, the dye includes at least one of an azo-based coloring agent represented by any of General Formulae (i) to (iv) or an indoaniline-based coloring agent represented by General Formula (v), and, as described above, it exhibits excellent decolorizing properties even in a case of carrying out ultraviolet irradiation at room temperature (which means 10° C. to 30° C.), which is a mild environment.

Examples of the form of the light absorption filter according to the embodiment of the present invention include a form in which, from the viewpoint that a secondary coloration structure associated with the decomposition of the dye is hardly generated, the dye above described includes, among those described above, at least one of an azo-based coloring agent represented by any of General Formulae (i) to (iv) or an indoaniline-based coloring agent represented by General Formula (v), and may contain a squaraine-based coloring agent represented by General Formula (1) as an optional component. Any of these coloring agents is unlikely to generate a secondary coloration structure associated with the decomposition of the dye, and thus in a case where it is as a dye, it is possible to efficiently make a portion irradiated with ultraviolet light decolorized and colorless.

That is, in a case where at least one of an azo-based coloring agent represented by any of General Formulae (i) to (iv) or an indoaniline-based coloring agent represented by General Formula (v) is used as a dye, and in a case where a squaraine-based coloring agent represented by General Formula (1) is further used as an optional component, it is possible to suitably produce the optical filter according to the embodiment of the present invention by subjecting the light absorption filter according to the present invention to mask exposure by ultraviolet irradiation.

Further, by adjusting the blending ratio between dyes of at least one of an azo-based coloring agent represented by any of General Formulae (i) to (iv) or an indoaniline-based coloring agent represented by General Formula (v), and two or more selected from a squaraine-based coloring agent represented by General Formula (1) (here, the squaraine-based coloring agent represented by General Formula (1) is an optional component), it is possible to suppress a change in the tint of reflected light (hereinafter, referred to as “adjusting the tint of the reflected light to be neutral”) in the light absorption filter according to the embodiment of the present invention and the light absorptive portion of the light absorption filter according to the embodiment of the present invention as compared with a case where the coloring agent is not contained, which is preferable.

The dye that is contained in the light absorption filter according to the embodiment of the present invention may be one kind or two or more kinds. Each of the coloring agents of the azo-based coloring agent represented by General Formula (i), the azo-based coloring agent represented by General Formula (ii), the azo-based coloring agent represented by General Formula (iii), the azo-based coloring agent represented by General Formula (iv), and the indoaniline-based coloring agent represented by General Formula (v), which may be contained in the light absorption filter according to the embodiment of the present invention, may be one kind or may be two or more kinds.

In addition, in a case where the light absorption filter according to the embodiment of the present invention contains a squaraine-based coloring agent represented by General Formula (1), the squaraine-based coloring agent represented by General Formula (1) may be one kind or may be two or more kinds.

The light absorption filter according to the embodiment of the present invention may also contain a dye other than the above dye.

In the present invention, in the coloring agent represented by each general formula, a cation is present in a delocalized manner, and thus a plurality of tautomer structures are present. Therefore, in the present invention, in a case where at least one tautomer structure of a certain coloring agent matches with each general formula, the certain coloring agent shall be a coloring agent represented by the general formula. Therefore, a coloring agent represented by a specific general formula can also be said to be a coloring agent having at least one tautomer structure that can be represented by the specific general formula. In the present invention, a coloring agent represented by a general formula may have any tautomer structure as long as at least one tautomer structure of the coloring agent matches with the general formula.

### (1-1) An Azo-Based Coloring Agent Represented by General Formula (i).

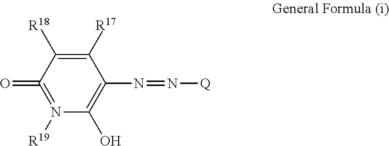

In the formula, R¹⁷ and R¹⁸ each independently represent a hydrogen atom or a monovalent substituent.

R¹⁹ represents a hydrogen atom, an aliphatic group, an aryl group, a heterocyclic group, a carbamoyl group, an alkoxycarbonyl group, an aryloxycarbonyl group, an acyl group, an alkylsulfonyl group, an arylsulfonyl group, or a sulfamoyl group.

Q represents a diazo component residue.

However, R¹⁷ to R¹⁹ and Q do not have a squaraine structure.

The above-described squaraine structure means a structure of a squaraine-based coloring agent. The squaraine-based coloring agent is a coloring agent having a structure that has a skeleton derived from squaric acid in a central part of a π-conjugated system. Examples thereof include a squaraine-based coloring agent represented by General Formula (1) described later.

Examples of the monovalent substituent that can be adopted as R¹⁷ and R¹⁸ include a halogen atom, an aliphatic group, an aryl group, a heterocyclic group, a cyano group, a carboxy group, a carbamoyl group, an aliphatic oxycarbonyl group, an aryloxycarbonyl group, an acyl group, a hydroxy group, an aliphatic oxy group, an aryloxy group, an acyloxy group, a carbamoyloxy group, a heterocyclic oxy group, an amino group (—NH₂), an aliphatic amino group, an arylamino group, a heterocyclic amino group, an acylamino group, a carbamoylamino group, a sulfamoylamino group, an aliphatic oxycarbonylamino group, an aryloxycarbonylamino group, an aliphatic sulfonylamino group, an arylsulfonylamino group, a nitro group, an aliphatic thio group, an arylthio group, an aliphatic sulfonyl group, an arylsulfonyl group, a sulfamoyl group, a sulfo group, an imide group, and a heterocyclic thio group. Among these, an aliphatic group, an aryl group, a heterocyclic group, a cyano group, a carbamoyl group, an aliphatic oxycarbonyl group, an aryloxycarbonyl group, an acyl group, an aliphatic oxy group, an aryloxy group, an aliphatic amino group, or an arylamino group is preferable mainly from the viewpoint of imparting solubility.

The substituents that can be adopted as R¹⁷ and R¹⁸ may be further substituted.

The aliphatic group that can be adopted as R¹⁷ to R¹⁹ may further have a monovalent substituent, may be saturated or unsaturated, and may be cyclic. Specific examples thereof include an alkyl group, a substituted alkyl group, an alkenyl group, a substituted alkenyl group, an alkynyl group, a substituted alkynyl group, an aralkyl group, and a substituted aralkyl group. The total number of carbon atoms in the aliphatic group is preferably 1 to 30 and more preferably 1 to 16. Specific examples of the aliphatic group include a methyl group, an ethyl group, a butyl group, an isopropyl group, a t-butyl group, a hydroxyethyl group, a methoxyethyl group, a cyanoethyl group, a trifluoromethyl group, a 3-sulfopropyl group, a 4-sulfobutyl group, a 2-(2-hydroxyethoxy)ethyl group, a 2-(2-(acetyloxy)ethoxy)ethyl group, a cyclohexyl group, a benzyl group, a 2-phenethyl group, a vinyl group, and an allyl group.

It is noted that Examples of the monovalent substituent which may be contained include the monovalent substituents that can be adopted as R¹⁷ and R¹⁸, and the same applies to the following description regarding the monovalent substituent which may be contained. The monovalent substituent which may be contained is, for example, preferably an alkoxy group, an acyloxy group, or a hydroxy group. In addition, this substituent may further have a substituent, and preferred examples thereof include an alkoxy group, an acyloxy group, and a hydroxy group.

The aryl group that can be adopted as R¹⁷ to R¹⁹ may further have a monovalent substituent, and the aryl group is preferably an aryl group having a total number of carbon atoms of 6 to 30, and more preferably an aryl group having a total number of carbon atoms of 6 to 16. Specific examples thereof include a phenyl group, a 4-tolyl group, a 4-methoxyphenyl group, a 2-chlorophenyl group, a 3-(3-sulfopropylamino)phenyl group, a 4-sulfamoylphenyl group, a 4-(ethoxyethylsulfamoyl)phenyl group, and a 3-(dimethylcarbamoyl)phenyl group.

The heterocyclic group that can be adopted as R¹⁷ to R¹⁹ may be a saturated or unsaturated aliphatic ring group or may be an aromatic ring group, and it is preferably an aromatic heterocyclic group. Examples of the ring-constituting atom constituting the heterocyclic group include those containing at least any one of a heteroatom such as a nitrogen atom, a sulfur atom, or an oxygen atom, where the heterocyclic group may further have a monovalent substituent. The heterocyclic group is preferably a heterocyclic group having a total number of carbon atoms of 1 to 30, and more preferably a heterocyclic group having a total number of carbon atoms of 1 to 15. Specific examples thereof include a 2-pyridyl group, a 2-thienyl group, a 2-thiazolyl group, a 2-benzothiazolyl group, a 2-benzoxazolyl group, and a 2-furyl group.

The carbamoyl group that can be adopted as R¹⁷ to R¹⁹ includes, in addition to an unsubstituted carbamoyl group (—CONH₂), a carbamoyl group substituted with an aliphatic group, an aryl group, or the like.

The carbamoyl group that can be adopted as R¹⁷ to R¹⁹ may further have a monovalent substituent, and the carbamoyl group is preferably a carbamoyl group having a total number of carbon atoms of 1 to 30, and more preferably a carbamoyl group having 1 to 16 carbon atoms. Specific examples thereof include a methylcarbamoyl group, a dimethylcarbamoyl group, a phenylcarbamoyl group, and an N-methyl-N-phenylcarbamoyl group.

To the aliphatic group in the aliphatic oxycarbonyl group that can be adopted as R¹⁷ and R¹⁸, the description of the aliphatic group that can be adopted as R¹⁷ to R¹⁹ can be applied.

The aliphatic oxycarbonyl group that can be adopted as R¹⁷ and R¹⁸ may further have a monovalent substituent, may be saturated or unsaturated, or may be cyclic, and the aliphatic oxycarbonyl group is preferably an aliphatic oxycarbonyl group having a total number of carbon atoms of 2 to 30, and more preferably an aliphatic oxycarbonyl group having a total number of carbon atoms of 2 to 16. Specific examples thereof include a methoxycarbonyl group, an ethoxycarbonyl group, and a 2-methoxyethoxycarbonyl group.

The alkoxycarbonyl group that can be adopted as R¹⁹ may further have a monovalent substituent, may be saturated or unsaturated, or may be cyclic, and the alkoxycarbonyl group is preferably an alkoxycarbonyl group having a total number of carbon atoms of 2 to 30 and more preferably an alkoxycarbonyl group having a total number of carbon atoms of 2 to 16. Specific examples thereof include a methoxycarbonyl group, an ethoxycarbonyl group, and a 2-methoxyethoxycarbonyl group.

The aryloxycarbonyl group that can be adopted as R¹⁷ to R¹⁹ may further have a monovalent substituent, and it is preferably an aryloxycarbonyl group having a total number of carbon atoms of 7 to 30 and more preferably an aryloxycarbonyl group having the number of carbon atoms of 7 to 16. Specific examples thereof include a phenoxycarbonyl group, a 4-methylphenoxycarbonyl group, and a 3-chlorophenoxycarbonyl group.

The acyl group that can be adopted as R¹⁷ to R¹⁹ includes an aliphatic carbonyl group, an arylcarbonyl group, and a heterocyclic carbonyl group, where an aspect in which the total number of carbon atoms is 1 to 30 is preferable, and an aspect in which the total number of carbon atoms is 1 to 16 is more preferable. Specific examples thereof include an acetyl group, a methoxyacetyl group, a thienoyl group, and a benzoyl group.

To the aliphatic group in the aliphatic sulfonyl group that can be adopted as R¹⁷ and R¹⁸, the description of the aliphatic group that can be adopted as R¹⁷ to R¹⁹ can be applied. The aliphatic sulfonyl group that can be adopted as R¹⁷ and R¹⁸ may further have a monovalent substituent, may be saturated or unsaturated, or may be cyclic, where an aspect in which the total number of carbon atoms is 1 to 30 is preferable, and an aspect in which the total number of carbon atoms is 1 to 16 is more preferable. Specific examples thereof include a methanesulfonyl group, a methoxymethanesulfonyl group, and an ethoxyethanesulfonyl group.

The alkylsulfonyl group that can be adopted as R¹⁹ may further have a monovalent substituent, may be saturated or unsaturated, or may be cyclic, where an aspect in which the total number of carbon atoms is 1 to 30 is preferable, and an aspect in which the total number of carbon atoms is 1 to 16 is more preferable. Specific examples thereof include a methanesulfonyl group, a methoxymethanesulfonyl group, and an ethoxyethanesulfonyl group.

The arylsulfonyl group that can be adopted as R¹⁷ to R¹⁹ may further have a monovalent substituent, where an aspect in which the total number of carbon atoms is 6 to 30 is preferable, and an aspect in which the total number of carbon atoms is 6 to 18 is more preferable. Specific examples thereof include a benzenesulfonyl group and a toluenesulfonyl group.

The sulfamoyl group that can be adopted as R¹⁷ to R¹⁹ includes, in addition to an unsubstituted sulfamoyl group (—SO₂NH₂), a carbamoyl group substituted with an aliphatic group, an aryl group, or the like.

The sulfamoyl group that can be adopted as R¹⁷ to R¹⁹ may further have a monovalent substituent, where an aspect in which the total number of carbon atoms is 0 to 30 is preferable, and an aspect in which the total number of carbon atoms is 0 to 16 is more preferable. Specific examples thereof include an unsubstituted sulfamoyl group, a dimethylsulfamoyl group, and a di-(2-hydroxyethyl)sulfamoyl group.

The imide group that can be adopted as R¹⁷ and R¹⁸ may further have a monovalent substituent, and it is preferably an imide group of a 5- or 6-membered ring. In addition, an aspect in which the total number of carbon atoms in the imide group is 4 to 30 is preferable, and an aspect in which the total number of carbon atoms in the imide group is 4 to 20 is more preferable. Specific examples thereof include a succinimide group and a phthalimide group.

To the aliphatic group in the aliphatic oxy group, the aliphatic amino group, the aliphatic oxycarbonylamino group, the aliphatic sulfonylamino group, and the aliphatic thio group, which can be adopted as R¹⁷ and R¹⁸, the description of the aliphatic group that can be adopted as R¹⁷ to R¹⁹ can be applied.

To the aryl group in the aryloxy group, the arylamino group, the aryloxycarbonylamino group, the arylsulfonylamino group, and the arylthio group, which can be adopted as R¹⁷ and R¹⁸, the description of the aryl group that can be adopted as R¹⁷ to R¹⁹ can be applied.

To the acyl group in the acyloxy group and the acylamino group, which can be adopted as R¹⁷ and R¹⁸, the description of the acyl group, which can be adopted as R¹⁷ to R¹⁹, can be applied.

To the carbamoyl group in the carbamoyloxy group and the carbamoylamino group, which can be adopted as R¹⁷ and R¹⁸, the description of the carbamoyl group, which can be adopted as R¹⁷ to R¹⁹, can be applied.

To the heterocyclic group in the heterocyclic oxy group, the heterocyclic amino group, and the heterocyclic thio group, which can be adopted as R¹⁷ and R¹⁸, the description of the heterocyclic group, which can be adopted as R¹⁷ to R¹⁹, can be applied.

To the sulfamoyl group in the sulfamoylamino group that can be adopted as R¹⁷ and R¹⁸, the description of the sulfamoyl group, which can be adopted as R¹⁷ to R¹⁹, can be applied.

The diazo component residue represented by Q means a residue of a diazo component “Q-NH₂”. In particular, from the viewpoint of the color reproducibility to be targeted, Q is preferably an aryl group or an aromatic heterocyclic group.

The aromatic hydrocarbon ring constituting the aryl group that can be adopted as Q may be a monocyclic ring or a fused ring, and it is preferably a monocyclic ring. It is preferably an aryl group having a total number of carbon atoms of 6 to 30, and more preferably an aryl group having a total number of carbon atoms of 6 to 16. Specifically, a phenyl group is preferable. The aryl group that can be adopted as Q may have a substituent, and preferred examples of the substituent that may be contained include a sulfamoyl group (preferably an alkylsulfamoyl group or a dialkylsulfamoyl group), a sulfonyl group (preferably an alkylsulfonyl group), and a cyano group.

The aromatic heterocyclic group that can be adopted as Q is an aromatic ring group containing, as a ring-constituting atom constituting a heterocyclic group, at least any one among heteroatoms such as a nitrogen atom, a sulfur atom, and an oxygen atom, where the aromatic heterocyclic group is preferably composed of a 5- or 6-membered ring. The number of carbon atoms in the aromatic heterocyclic group is preferably 1 to 25 and more preferably 1 to 15. The aromatic heterocyclic ring constituting the aromatic heterocyclic group may be a monocyclic ring or a fused ring, and it is preferably a monocyclic ring.

Specific examples of the aromatic heterocyclic group include a pyrazole group, a 1,2,4-triazole group, an isothiazole group, a benzisothiazole group, a thiazole group, a benzothiazole group, an oxazole group, and a 1,2,4-thiadiazole group.

Examples of the azo-based coloring agent represented by General Formula (i) include the following exemplary compounds (B-12) to (B-16), (B-18), and (B-19). However, the present invention is not limited thereto.

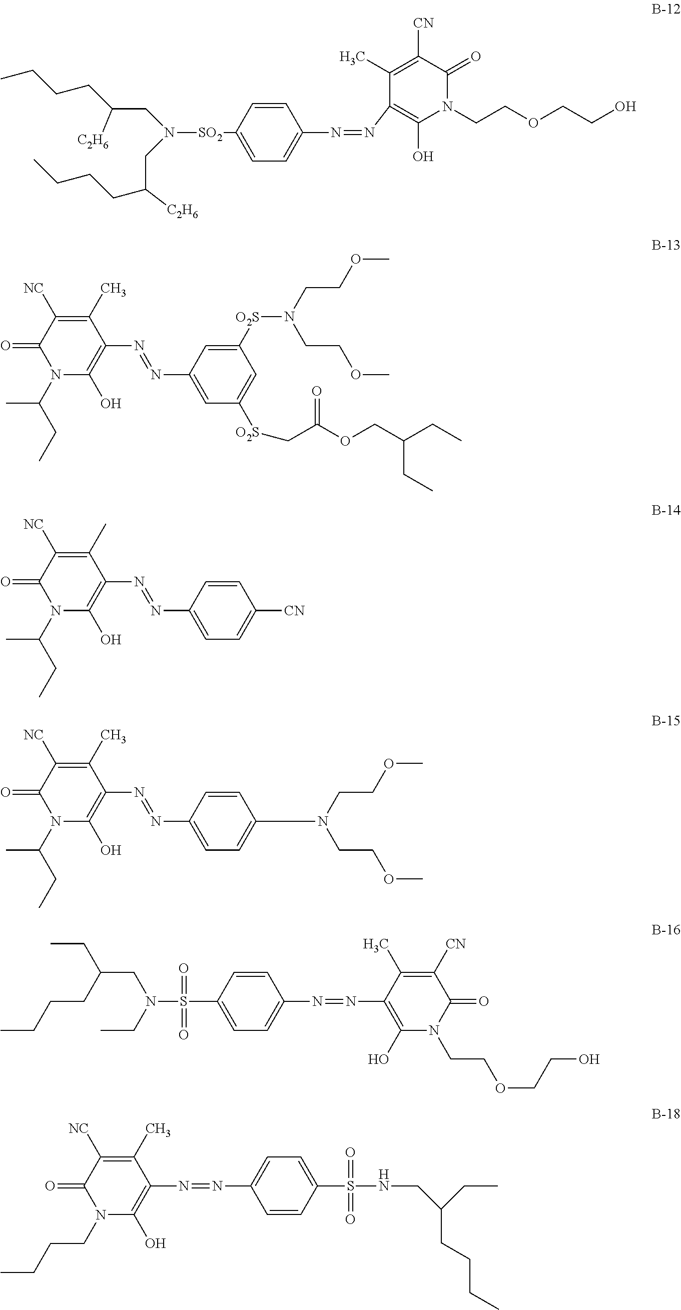

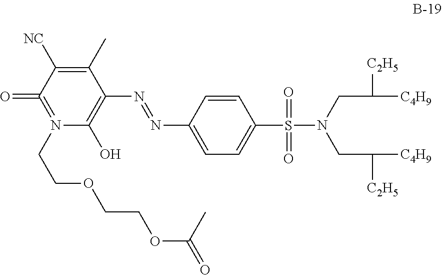

### (1-2) An Azo-Based Coloring Agent Represented by General Formula (ii).

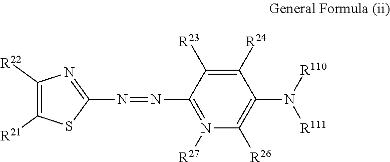

In the formula, R²¹ to R²⁴, R²⁶, and R²⁷ represent a hydrogen atom, a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, or a heterocyclic group.

R¹⁰⁸ to R¹²¹ represent a hydrogen atom, an acyclic hydrocarbon group, a monocyclic hydrocarbon group, a fused polycyclic hydrocarbon group, or a heterocyclic group. n is a positive integer.

It is noted that the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, and a heterocyclic group.

The acyclic hydrocarbon group that can be adopted as R²¹ to R²⁴, R²⁶, R²⁷, and R¹⁰⁸ to R¹²¹ means an acyclic alkyl group in which one hydrogen atom is removed from an acyclic alkane. However, the acyclic alkyl group may have a ring structure as a substituent. The number of carbon atoms in the acyclic alkyl group is preferably 1 to 30, more preferably 1 to 20, still more preferably 1 to 12, particularly preferably 1 to 8, and among these, it is preferably 1 to 6.

The monocyclic hydrocarbon group that can be adopted as R²¹ to R²⁴, R²⁶, R²⁷, and R¹⁰⁸ to R¹²¹ means a monocyclic cycloalkyl group, a monocyclic cycloalkenyl group, a monocyclic cycloalkynyl group, or a monocyclic aryl group, which is a group in which one hydrogen atom is removed from a monocyclic aliphatic hydrocarbon ring (which may be any of a monocyclic cycloalkane, a monocyclic cycloalkene, or a monocyclic cycloalkyne) or a monocyclic aromatic hydrocarbon ring.

The number of carbon atoms in the monocyclic cycloalkyl group, the monocyclic cycloalkenyl group, and the monocyclic cycloalkynyl group is not particularly limited as long as it is allowed in terms of the structure; however, it is more preferably 3 to 30, more preferably 3 to 20, and still more preferably 3 to 16. The number of carbon atoms in the monocyclic aryl group is more preferably 6 to 30, still more preferably 6 to 20, and even still more preferably 6 to 16.

The fused polycyclic hydrocarbon group that can be adopted as R²¹ to R²⁴, R²⁶, R²⁷, and R¹⁰⁸ to R¹²¹ means a fused polycyclic cycloalkyl group, a fused polycyclic cycloalkenyl group, a fused polycyclic cycloalkynyl group, or a fused polycyclic aryl group, which is a group in which one hydrogen atom is removed from a fused polycyclic aliphatic hydrocarbon ring (which may be any of a fused polycyclic cycloalkane, a fused polycyclic cycloalkene, or a fused polycyclic cycloalkyne) or a fused polycyclic aromatic hydrocarbon ring.

The number of carbon atoms in the fused polycyclic cycloalkyl group, the fused polycyclic cycloalkenyl group, and the fused polycyclic cycloalkynyl group is not particularly limited as long as it is allowed in terms of the structure; however, it is more preferably 8 to 30 and more preferably 8 to 20. The number of carbon atoms in the fused polycyclic aryl group is more preferably 12 to 30 and still more preferably 12 to 20.

To the heterocyclic group that can be adopted as R²¹ to R²⁴, R²⁶, R²⁷, and R¹⁰⁸ to R¹²¹, the description of the heterocyclic group that can be adopted as R¹⁷ to R¹⁹ in General Formula (i) can be applied.

n is preferably an integer of 1 to 12, more preferably an integer of 1 to 6, and still more preferably an integer of 1 to 3.

Regarding the specific group of each of the substituents in General Formula (ii), unless otherwise specified, the descriptions regarding R¹ to R⁴, R⁶, R⁷, and R⁸ to R²¹ for the compound represented by General Formula [1] described in JP1993-257180A (JP-H5-257180A) can be applied as they are to R²¹ to R²⁴, R²⁶, R²⁷, and R¹⁰⁸ to R¹²¹, respectively.

R²¹ is preferably a cyano group, a nitro group, —OR¹⁰⁸, an acyclic hydrocarbon group (preferably an acyclic alkyl group or an acyclic alkenyl group), or a heterocyclic group, more preferably a cyano group or a nitro group, or an acyclic alkyl group (preferably an alkyl group substituted with a fluorine atom) substituted with a halogen atom, and still more preferably a cyano group.

R²² is preferably a hydrogen atom, a cyano group, an acyclic hydrocarbon group (preferably an acyclic alkyl group), or a monocyclic hydrocarbon group, more preferably a hydrogen atom or an alkyl group, and still more preferably an alkyl group.

It is noted that at least one of R²¹ or R²² is preferably a cyano group or a nitro group, or an acyclic alkyl group substituted with a halogen atom, a cyano group, or a nitro group.

R²³ is preferably a hydrogen atom, —OR¹⁰⁸, —SR¹⁰⁹, —NR¹¹⁰R¹¹¹, —C(═O)NR¹¹⁴R¹¹⁵, —NHC(═O)R¹¹⁶, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, or an acyclic hydrocarbon group (preferably an acyclic alkyl group), more preferably a hydrogen atom, —OR¹⁰⁸, —SR¹⁰⁹, —NR¹¹⁰R¹¹¹, —NHC(═O)R¹¹⁶, or an acyclic alkyl group, and still more preferably —NHC(═O)R¹¹⁶. Here, R¹⁰⁸ to R¹¹¹, R¹¹⁶, and R¹¹⁸ to R¹²¹ are preferably an acyclic alkyl group.

R²⁴ and R²⁷ are preferably a hydrogen atom.

R²⁶ is preferably a hydrogen atom, —OR¹⁰⁸, —SR¹⁰⁹, —NR¹¹⁰R¹¹¹, —NHC(═O)R¹¹⁶, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, or an acyclic hydrocarbon group (preferably an acyclic alkyl group), more preferably a hydrogen atom, —OR¹⁰⁸, or —SR¹⁰⁹, and still more preferably a hydrogen atom. Here, R¹⁰⁸ to R¹¹¹, R¹¹⁶, and R¹¹⁸ to R¹²¹ are preferably an acyclic alkyl group.

In —NR¹¹⁰R¹¹¹ that is located at the ortho position with respect to R²⁴ and R²⁶, R¹¹⁰ is preferably an acyclic alkyl group, and R¹¹¹ is preferably an acyclic alkyl group and more preferably an unsubstituted acyclic alkyl group or an acyclic alkyl group having —OR¹⁰⁸, a monocyclic hydrocarbon group, or a fused polycyclic hydrocarbon group as a substituent. Here, R¹⁰⁸ is preferably a hydrogen atom or an acyclic alkyl group.

Specific examples of the coloring agent represented by General Formula (ii) include, in addition to the compounds that are used in Examples described later, the compounds described in paragraphs [0023] to [0034] of JP1993-257180A (JP-H5-257180A), and the compounds described in paragraphs [0050] and [0052], the compound D-18 described in paragraph [0055], and the compound described in paragraph [0056] of JP2013-129712A. However, the present invention is not limited thereto.

(1-3) An Azo-Based Coloring Agent Represented by General Formula (iii).

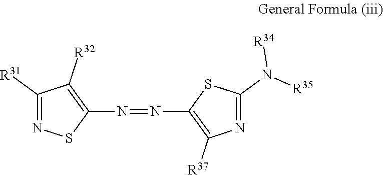

In the formula, R³¹ represents a hydrogen atom, an alkyl group, an alkoxy group, a cyano group, a carbonyl group (an alkyloxycarbonyl group or an aryloxycarbonyl group is preferable), an aromatic group, or a heterocyclic group.

R³² represents a hydrogen atom, an alkyl group, an alkoxy group, a cyano group, a nitro group, a carbonyl group (an alkyloxycarbonyl group or an aryloxycarbonyl group is preferable), an aromatic group, or a heterocyclic group.

R³⁴ and R³⁵ each independently represent a hydrogen atom, an alkyl group, or an aromatic group.

R³⁷ represents a hydrogen atom, an alkyl group, an alkoxy group, a cyano group, a carbonyl group (an alkyloxycarbonyl group or an aryloxycarbonyl group is preferable), an acylamino group, or an aromatic group.

R³⁴ and R³⁵ may be bonded to each other to form a ring.

Regarding the definition and the preferred range of each of the substituents in General Formula (iii), unless otherwise specified, the descriptions regarding R¹ and R² regarding General Formula (1) described in JP2013-129712A can be applied as they are to R³¹ and R³², respectively, and the description regarding R⁴, R⁵, and R⁷ regarding General Formula (3) described in JP2013-129712A can be applied as it is to R³⁴, R³⁵, and R³⁷, respectively.

It is noted that, in the present invention, R³⁷ can adopt the following acylamino group in addition to the hydrogen atom, the alkyl group, the alkoxy group, the cyano group, the carbonyl group, and the aromatic group, which can be adopted by R⁷ regarding General Formula (3) described in JP2013-129712A.

The number of carbon atoms in the acylamino group that can be adopted as R³⁷ is preferably 1 to 12 and more preferably 1 to 6.

In the present invention, the number of carbon atoms in the alkyl group that can be adopted as R³¹, R³², and R³⁷ is more preferably 1 to 20, still more preferably 1 to 12, and particularly preferably 1 to 6.

the number of carbon atoms in the alkoxy group that can be adopted as R³¹, R³², and R³⁷ is more preferably 1 to 20, still more preferably 1 to 12, and particularly preferably 1 to 6.

The number of carbon atoms in the alkyloxycarbonyl group that can be adopted as R³¹, R³², and R³⁷ is preferably 2 to 30, more preferably 2 to 20, still more preferably 2 to 12, and particularly preferably 2 to 7.

The number of carbon atoms in the alkyl group that can be adopted as R³⁴ and R³⁵ is preferably 1 to 30, more preferably 1 to 20, and still more preferably 1 to 12.

R³¹ is preferably an alkyl group or an aryl group, and more preferably an alkyl group.

R³² is preferably an alkyl group or a cyano group, and more preferably a cyano group.

R³⁴ and R³⁵ are preferably a hydrogen atom or an alkyl group, and more preferably an alkyl group.

R³⁷ is preferably a hydrogen atom, an alkyl group, an acylamino group, or an aromatic group, more preferably a hydrogen atom or an alkyl group, and still more preferably an alkyl group.

Specific examples of the coloring agent represented by General Formula (iii) include the following compounds. However, the present invention is not limited thereto.

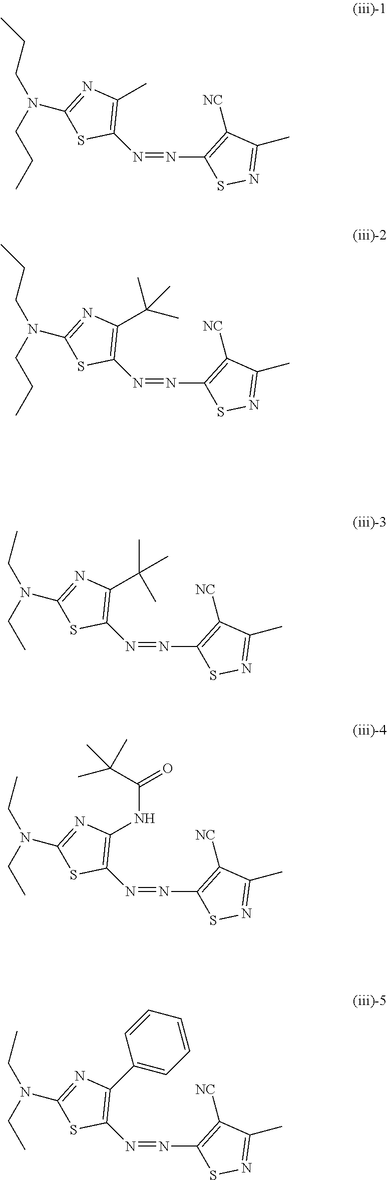

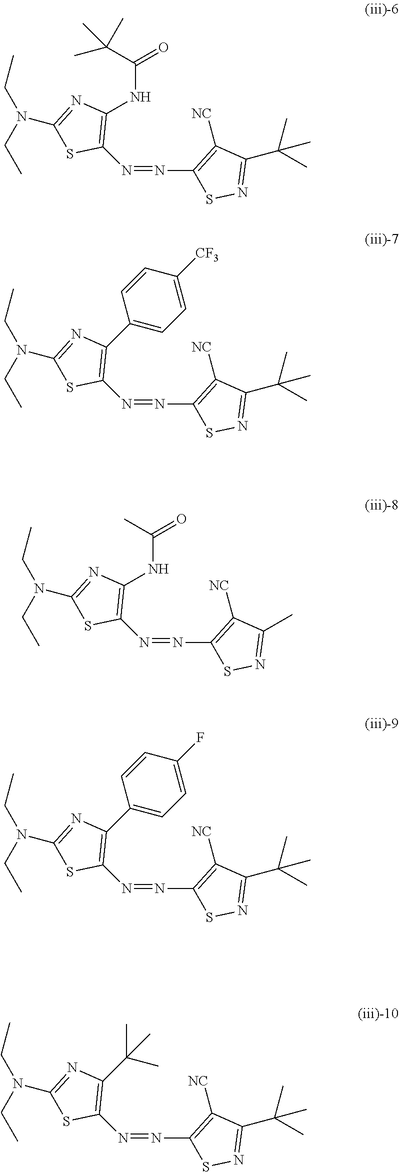

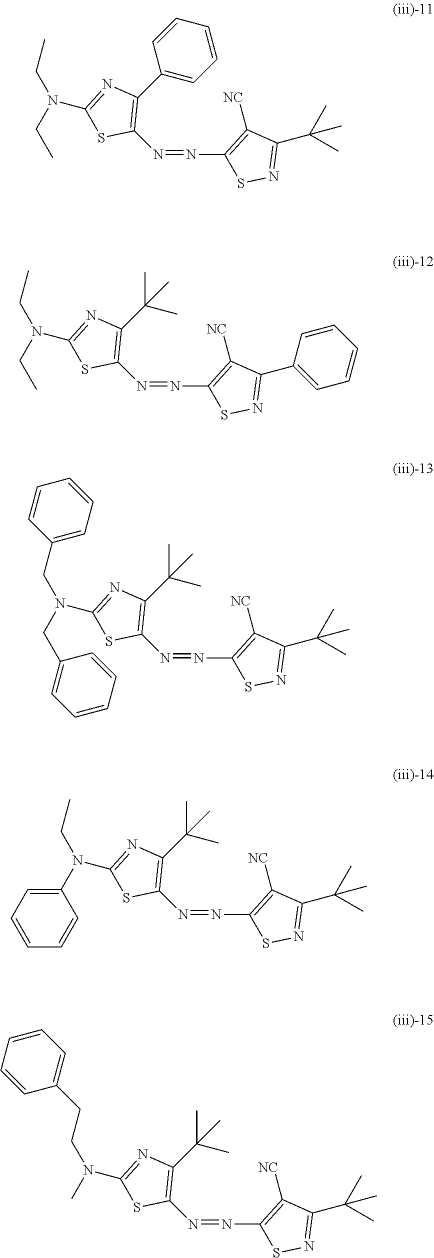

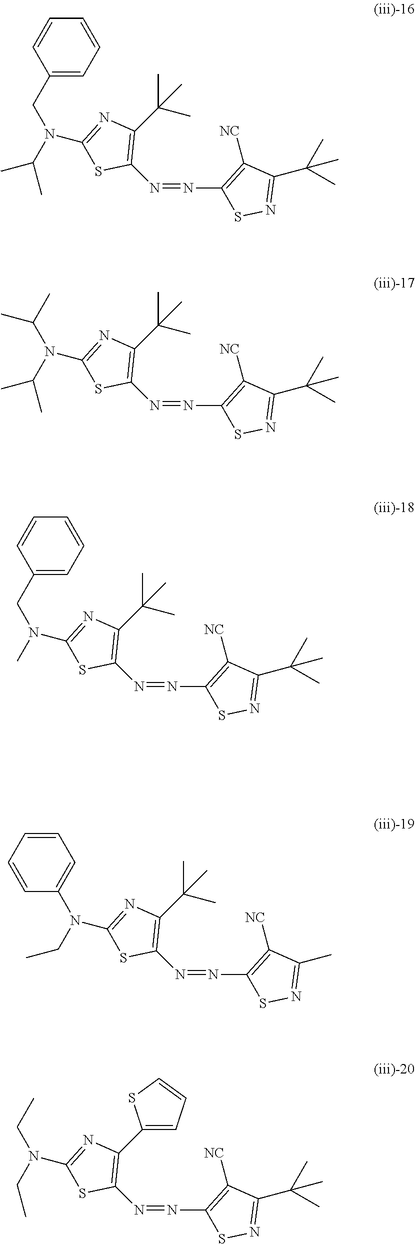

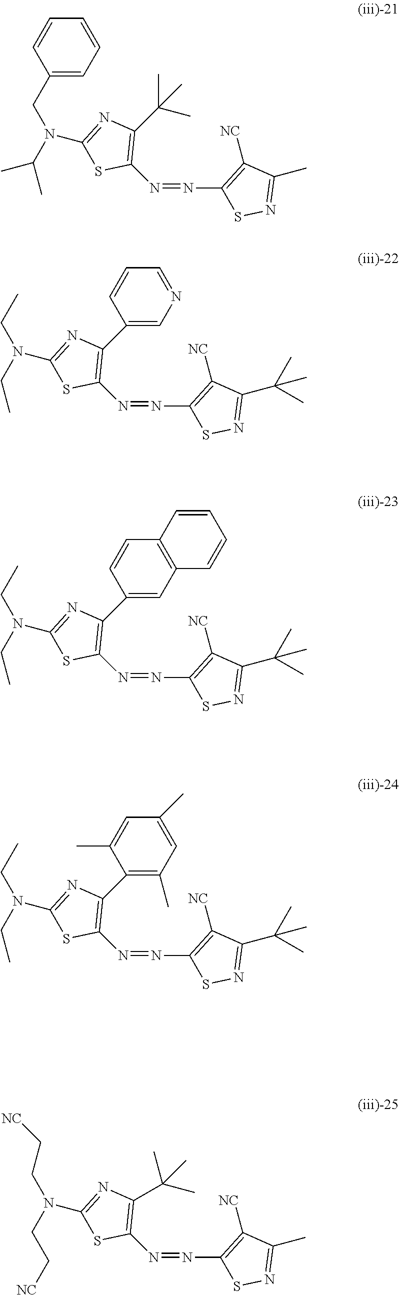

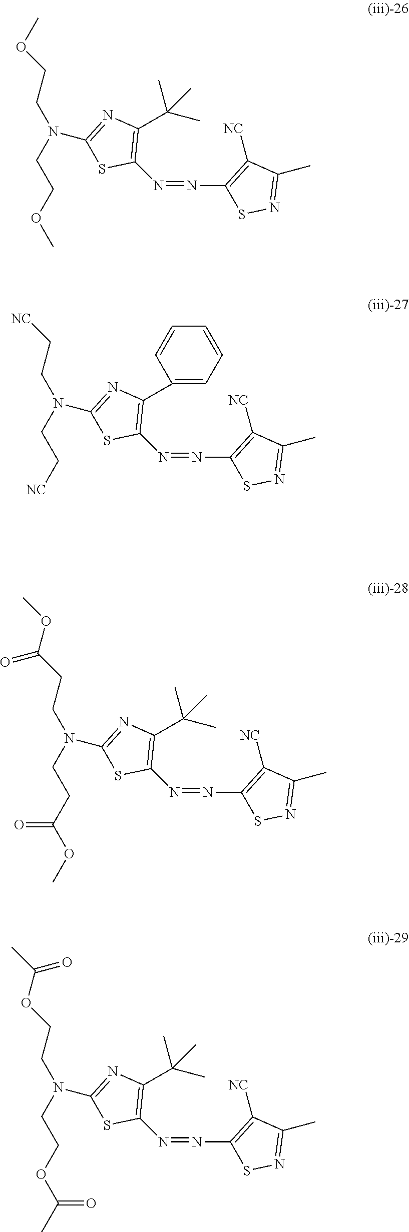

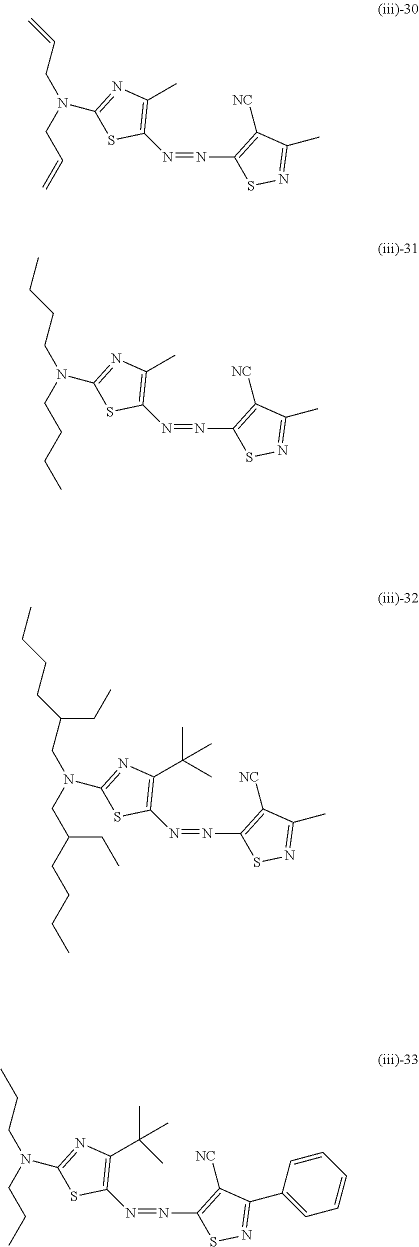

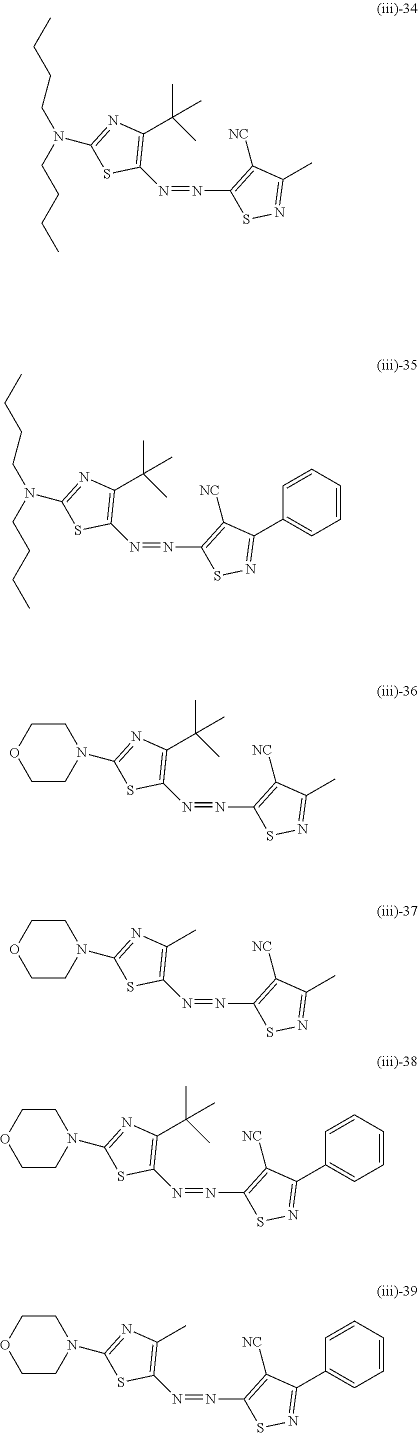

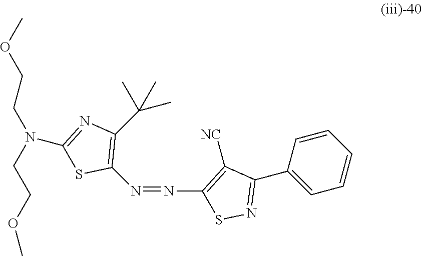

### (1-4) An Azo-Based Coloring Agent Represented by General Formula (iv).

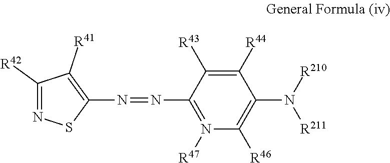

In the formula, R⁴¹ to R⁴⁴, R⁴⁶, and R⁴⁷ represent a hydrogen atom, a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, an acyclic hydrocarbon group, a monocyclic hydrocarbon group, a fused polycyclic hydrocarbon group, or a heterocyclic group.

R²⁰⁸ to R²²¹ represent a hydrogen atom, an acyclic hydrocarbon group, a monocyclic hydrocarbon group, a fused polycyclic hydrocarbon group, or a heterocyclic group. n is a positive integer.

It is noted that the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, —S(CH₂CH₂S)R²²¹, an acyclic hydrocarbon group, a monocyclic hydrocarbon group, a fused polycyclic hydrocarbon group, and a heterocyclic group.

The descriptions of R²¹ to R²⁴, R²⁶, R²⁷, R¹⁰⁸ to R¹²¹, and n in General Formula (ii) can be applied as they are to R⁴¹ to R⁴⁴, R⁴⁶, R⁴⁷, R²⁰⁸ to R²²¹, and n in General Formula (iv) unless otherwise specified.

R⁴³ is preferably a hydrogen atom, —OR²⁰⁸, —SR²⁰⁹, —NR²¹⁰R²¹¹, —NHC(═O)R²¹⁶, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, or an acyclic hydrocarbon group (preferably an acyclic alkyl group), more preferably a hydrogen atom, —OR²⁰⁸, —SR²⁰⁹, —NR²¹⁰R²¹¹, —NHC(═O)R²¹⁶, or an acyclic alkyl group, and still more preferably —NHC(═O)R²¹⁶ or an acyclic alkyl group. Here, R²⁰⁸ to R²¹¹, R²¹⁶, and R²¹⁸ to R²²¹ are preferably an acyclic alkyl group.

In —NR²¹⁰R²¹¹ that is located at the ortho position with respect to R⁴⁴ and R⁴⁶, R²¹⁰ is preferably an acyclic alkyl group, and R²¹¹ is preferably an acyclic alkyl group and more preferably an unsubstituted acyclic alkyl group (including an acyclic alkyl group substituted with an acyclic alkyl group) or an acyclic alkyl group having —OR²⁰⁸, a monocyclic hydrocarbon group, or a fused polycyclic hydrocarbon group as a substituent. Here, R²⁰⁸ is preferably a hydrogen atom or an acyclic alkyl group.

It is noted that R⁴⁴ and/or R⁴⁶ in General Formula (iv) may be bonded to R²¹⁰ and/or R²¹¹ in —NR²¹⁰R²¹¹ located at the ortho position with respect to R⁴⁴ and R⁴⁶ on the benzene ring, thereby forming a ring. The ring which may be formed is preferably a 5- or 6-membered ring and may be saturated or unsaturated, and it is preferably a saturated 6-membered ring. The ring which may be formed may further have a substituent, and for example, it preferably has an alkyl group.

Among these, regarding a form in which a ring is formed, it is preferable that R⁴⁶ and R²¹¹ in —NR²¹⁰R²¹¹ that is located at the ortho position with respect to R⁴⁴ and R⁴⁶ on the benzene ring are bonded to each other to form a saturated 6-membered ring.

Specific examples of the coloring agent represented by General Formula (iv) include, in addition to the compounds that are used in Examples described later, the compounds described in paragraph [0053] of JP2013-129712A. However, the present invention is not limited thereto.

### (1-5) An Indoaniline-Based Coloring Agent Represented by General Formula (v).

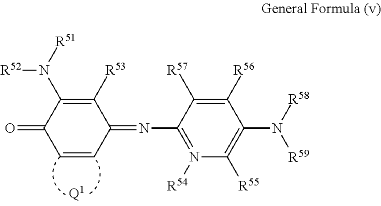

In the formula, Q¹ represents an atomic group that contains at least one nitrogen atom and is necessary for forming a 5- to 7-membered nitrogen-containing heterocyclic ring together with carbon atoms to be bonded.

R⁵¹ represents an acyl group, an alkoxycarbonyl group, an aryloxycarbonyl group, an aminocarbonyl group, or a sulfonyl group, R⁵² represents a hydrogen atom or an alkyl group, R⁵³ to R⁵⁷ represent a hydrogen atom, an alkyl group, an alkoxy group, an acylamino group, an alkylsulfonylamino group, or a halogen atom, and R⁵¹ and R⁵⁹ represent a hydrogen atom, an alkyl group, or an aryl group.

R⁵¹ and R⁵³, R⁵⁴ and R⁵⁵, and/or R⁵⁵ and R⁵⁹, or R⁵⁸ and R⁵⁹ may be bonded to each other to form a ring.

Regarding the definition and the preferred range of each of the substituents in General Formula (v), unless otherwise specified, the descriptions regarding R¹ to R⁶, R⁸, R⁹, and Q¹ in General Formula (I) described in JP1990-92686A (JP-H2-92686A) can be applied as they are to R⁵¹ to R⁵⁶, R⁵⁸, R⁵⁹, and Q¹, respectively.

It is noted that in the present invention, R⁵³ to R⁵⁶ can adopt the following acylamino group and alkylsulfonylamino group, in addition to the hydrogen atom, the alkyl group, the alkoxy group, and the halogen atom, which can be adopted by R³ to R⁶ regarding General Formula (I) described in JP1990-92686A (JP-H02-92686A).

The number of carbon atoms in the acylamino group that can be adopted as R⁵³ to R⁵⁷ is preferably 1 to 12 and more preferably 1 to 6.

The number of carbon atoms in the alkylsulfonylamino group that can be adopted as R⁵³ to R⁵⁷ is preferably 1 to 12 and more preferably 1 to 6.

To the alkyl group, the alkoxy group, and the halogen atom, which can be adopted as R⁵⁷, the descriptions of the alkyl group, the alkoxy group, and the halogen atom, which can be adopted as R⁵³ to R⁵⁶, can be applied as they are.

Q¹ is preferably represented by —NR¹⁶C(═O)-Q²-. Q² represents an atomic group required for forming a 5- to 7-membered nitrogen-containing heterocyclic ring together with a carbon atom to which —NR¹⁶C(═O)-Q²- is bonded and —NR¹⁶C(═O)—, and examples thereof include a divalent amino group, an ether bond, a thioether bond, an alkylene bond, an ethylene bond, an imino bond, a sulfonyl bond, a carbonyl bond, an arylene bond or a divalent heterocyclic group, and a group obtained by combining a plurality of these. R¹⁶ represents a hydrogen atom, an alkyl group, an aryl group, or a heterocyclic group, where a hydrogen atom is preferable. To each of the definition and the preferred range of each substituent of R¹⁶ the description regarding R¹⁶ regarding General Formula (I) described in JP1990-92686A (JP-H2-92686A) can be applied as it is.

R⁵¹ is preferably an acyl group having 2 to 7 carbon atoms or an alkoxycarbonyl group having 2 to 7 carbon atoms.

R⁵² is preferably a hydrogen atom, and R⁵³ to R⁵⁶ are preferably a hydrogen atom. R⁵⁷ is preferably an alkoxy group, an acylamino group, or an alkylsulfonylamino group, and more preferably an alkoxy group or an acylamino group.

R⁵⁸ and R⁵⁹ are preferably an alkyl group having 1 to 6 carbon atoms.

Among the above, the indoaniline-based coloring agent represented by General Formula (v) is preferably represented by General Formula (v-a).

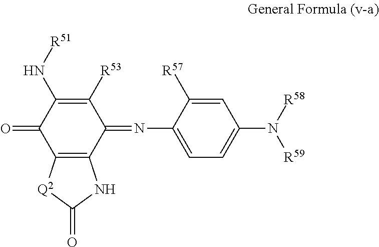

In the formula, R⁵¹, R⁵³, R⁵⁷ to R⁵⁹, and Q² have the same meanings as R⁵¹, R⁵³, R⁵⁷ to R⁵⁹, and Q² in General Formula (v).

Q² is preferably —CR¹¹R¹²CR¹³R¹⁴—, —CR¹¹R¹²—, or —NR¹¹—, and more preferably —CR¹¹R¹²CR¹³R¹⁴—.

R¹¹ to R¹⁴ represent a hydrogen atom or an alkyl group having 1 to 4 carbon atoms, and it is preferable that R¹¹ and R¹² are a hydrogen atom and R¹³ and R¹⁴ are an alkyl group having 1 to 4 carbon atoms.

It is noted that —CR¹¹R¹²CR¹³R¹⁴— is preferably bonded to >C═O on the side of the carbon atom to which R¹¹ and R¹² are bonded.

Specific examples of the coloring agent represented by General Formula (v) include, in addition to the compounds that are used in Examples described later, the compounds of Nos. 1 to 51 on pages 5 and 6 of JP1990-92686A (JP-H2-92686A). However, the present invention is not limited thereto.

### (2) Squaraine-Based Coloring Agent Represented by General Formula (1)

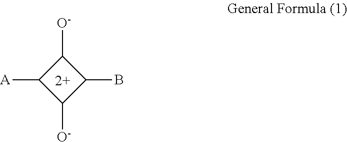

In General Formula (1), A and B each independently represent an aryl group which may have a substituent, a heterocyclic group which may have a substituent, or —CH=G. Here, G represents a heterocyclic group which may have a substituent.

The aryl group that can be adopted as A or B is not particularly limited and may be a group consisting of a monocyclic ring or a group consisting of a fused ring. The aryl group preferably has 6 to 30 carbon atoms, more preferably 6 to 20 carbon atoms, and still more preferably 6 to 12 carbon atoms. Examples of the aryl group include groups respectively consisting of a benzene ring and a naphthalene ring, and a group consisting of a benzene ring is more preferable.

The heterocyclic group that can be adopted as A or B is not particularly limited, and examples thereof include a group consisting of an aliphatic heterocyclic ring or an aromatic heterocyclic ring. A group consisting of an aromatic heterocyclic ring is preferable. Examples of the heteroaryl group that is an aromatic heterocyclic group include a heteroaryl group that can be adopted as a substituent X described below. The aromatic heterocyclic group that can be adopted as A or B is preferably a group of a 5-membered ring or a 6-membered ring and more preferably a group of a nitrogen-containing 5-membered ring. Specific examples thereof suitably include a group consisting of any of a pyrrole ring, a furan ring, a thiophene ring, an imidazole ring, a pyrazole ring, a thiazole ring, an oxazole ring, a triazole ring, an indole ring, an indolenine ring, an indoline ring, a pyridine ring, a pyrimidine ring, a quinoline ring, a benzothiazole ring, a benzoxazole ring, or a pyrazolotriazole ring. Among these, a group consisting of any of a pyrrole ring, a pyrazole ring, a thiazole ring, a pyridine ring, a pyrimidine ring, or a pyrazolotriazole ring is preferable. The pyrazolotriazole ring consists of a fused ring of a pyrazole ring and a triazole ring and may be a fused ring obtained by fusing at least one pyrazole ring and at least one triazole ring. Examples thereof include fused rings in General Formulae (4) and (5) described below.

A and B may be bonded to the squaric acid moiety (the 4-membered ring represented by General Formula (1)) at any moiety (any ring-constituting atom) without particular limitation: however, they are preferably bonded at a carbon atom.

G in —CH=G that can be employed as A or B represents a heterocyclic group which may have a substituent, and examples thereof suitably include examples shown in the heterocyclic group that can be employed as A or B. Among these, a group consisting of any of a benzoxazole ring, a benzothiazole ring, an indoline ring, or the like is preferable.

At least one of A or B may have a hydrogen bonding group that forms an intramolecular hydrogen bond.

Each of A, B, and G may have the substituent X, and, in a case where A, B, or G has the substituent X, adjacent substituents may be bonded to each other to further form a ring structure. In addition, a plurality of substituents X may be present.

Examples of the substituent X include substituents that can be adopted as R¹ in General Formula (2) described below. Specific examples thereof include a halogen atom, a cyano group, a nitro group, an alkyl group (including a cycloalkyl group), an alkenyl group, an alkynyl group, an aryl group, a heteroaryl group, an aralkyl group, and a ferrocenyl group, —OR¹⁰, —C(═O)R¹¹, —C(═O)OR¹², —OC(═O)R¹³, —NR¹⁴R¹⁵, —NHCOR¹⁶, —CONR¹⁷R¹⁸, —NHCONR¹⁹R²⁰, —NHCOOR²¹, —SR²², —SO₂R²³, —SO₃R²⁴, —NHSO₂R²⁵, and SO₂NR²⁶R²⁷. In addition, it is also preferable that the substituent X has a quencher moiety described later, in addition to the ferrocenyl group.

In General Formula (1), R¹⁰ to R²⁷ each independently represent a hydrogen atom, an aliphatic group, an aromatic group, or a heterocyclic group. The aliphatic group and the aromatic group that can be adopted as R¹⁰ to R²⁷ are not particularly limited, and appropriately selected from an alkyl group, a cycloalkyl group, an alkenyl group, and an alkynyl group which are classified as aliphatic groups, and an aryl group which is classified as an aromatic group, in the substituent that can be adopted as R¹ in General Formula (2) described later. The heterocyclic group that can be adopted as R¹⁰ to R²⁷ may be aliphatic or aromatic, and it can be appropriately selected from heteroaryl groups or heterocyclic groups that can be adopted as R¹ in General Formula (2) described below.

It is noted that in a case where R¹² of —COOR¹² is a hydrogen atom (that is, a carboxy group), the hydrogen atom may be dissociated (that is, a carbonate group) or may be in a salt state. In addition, in a case where R²⁴ of —SO₃R²⁴ is a hydrogen atom (that is, a sulfo group), the hydrogen atom may be dissociated (that is, a sulfonate group) or may be in a salt state.

Examples of the halogen atom that can be adopted as the substituent X include a fluorine atom, a chlorine atom, a bromine atom, and an iodine atom.

The alkyl group that can be adopted as the substituent X preferably has 1 to 20 carbon atoms, more preferably 1 to 15 carbon atoms, and still more preferably 1 to 8 carbon atoms. The alkenyl group preferably has 2 to 20 carbon atoms, more preferably 2 to 12 carbon atoms, and still more preferably 2 to 8 carbon atoms. The alkynyl group preferably has 2 to 40 carbon atoms, more preferably 2 to 30 carbon atoms, and particularly preferably 2 to 25 carbon atoms. The alkyl group, the alkenyl group, and the alkynyl group each may be linear, branched, or cyclic, and they are preferably linear or branched.

The aryl group that can be adopted as the substituent X includes a monocyclic group or a fused ring group. The aryl group preferably has 6 to 30 carbon atoms, more preferably 6 to 20 carbon atoms, and still more preferably 6 to 12 carbon atoms.

An alkyl portion in the aralkyl group that can be adopted as the substituent X is the same as that in the alkyl group. An aryl moiety in the aralkyl group is the same as the aryl group described above. The aralkyl group preferably has 7 to 40 carbon atoms, more preferably 7 to 30 carbon atoms, and still more preferably 7 to 25 carbon atoms.

The heteroaryl group that can be adopted as the substituent X includes a group consisting of a single ring or a fused ring, a group consisting of a single ring or a fused ring having 2 to 8 rings is preferable, and a group consisting of a single ring or a fused ring having 2 to 4 rings is more preferable. The number of heteroatoms constituting the ring of the heteroaryl group is preferably 1 to 3. Examples of the heteroatom constituting the ring of the heteroaryl group include a nitrogen atom, an oxygen atom, and a sulfur atom. The heteroaryl group is preferably a group consisting of a 5-membered ring or a 6-membered ring. The number of carbon atoms constituting the ring in the heteroaryl group is preferably 3 to 30, more preferably 3 to 18, and still more preferably 3 to 12. Examples of the heteroaryl group include each group consisting of any of a pyridine ring, a piperidine ring, a furan ring, a furfuran ring, a thiophene ring, a pyrrole ring, a quinoline ring, a morpholine ring, an indole ring, an imidazole ring, a pyrazole ring, a carbazole ring, a phenothiazine ring, a phenoxazine ring, an indoline ring, a thiazole ring, a pyrazine ring, a thiadiazine ring, a benzoquinoline ring, or a thiadiazole ring.

The ferrocenyl group that can be adopted as the substituent X is preferably represented by General Formula (2M).

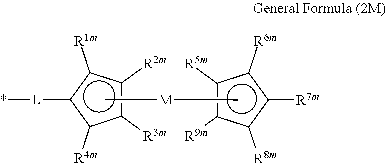

In General Formula (2M), L represents a single bond or a divalent linking group that does not conjugate with A, B, or G in General Formula (1). Rim to R^{9m} each independently represent a hydrogen atom or a substituent. M represents an atom that can constitute a metallocene compound and represents Fe, Co, Ni, Ti, Cu, Zn, Zr, Cr, Mo, Os, Mn, Ru, Sn, Pd, Rh, V, or Pt. * represents a bonding site to A, B, or G.

In the present invention, in a case where L in General Formula (2M) is a single bond, a cyclopentadienyl ring directly bonded to A, B, or G (a ring having R^{1m} in General Formula (2M)) is not included in the conjugated structure which conjugates with A, B, or G.

The divalent linking group that can be adopted as L is not particularly limited as long as it is a linking group that does not conjugate with A, B, or G, and it may have a conjugated structure in the inside thereof or at a cyclopentadiene ring side end part in General Formula (2M). Examples of the divalent linking group include an alkylene group having 1 to 20 carbon atoms, an arylene group having 6 to 20 carbon atoms, a divalent heterocyclic group obtained by removing two hydrogens from the heterocyclic ring, —CH═CH—, —CO—, —CS—, —NR— (R represents a hydrogen atom or a monovalent substituent), —O—, —S—, —SO₂—, or —N═CH—, or a divalent linking group formed by combining a plurality (preferably, 2 to 6) of these groups. The divalent linking group is preferably a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a divalent linking group in which two or more (preferably 2 to 6) selected from the above group are combined, and it is particularly preferably a group selected from the group consisting of an alkylene group having 1 to 4 carbon atoms, a phenylene group, —CO—, —NH—, —O—, and —SO₂—, or a linking group in which two or more (preferably 2 to 6) selected from the above group are combined. The divalent linking group combined is not particularly limited, and it is preferably a group containing —CO—, —NH—, —O—, or —SO₂—, and examples thereof include a linking group formed by combining two or more of —CO—, —NH—, —O—, or —SO₂—, or a linking group formed by combining at least one of —CO—, —NH—, —O—, or —SO₂— and an alkylene group or an arylene group. Examples of the linking group formed by combining two or more of —CO—, —NH—, —O—, or —SO₂— include —COO—, —OCO—, —CONH—, —NHCOO—, —NHCONH—, and —SO₂NH—. Examples of the linking group formed by combining at least one of —CO—, —NH—, —O—, or —SO₂— and an alkylene group or an arylene group include a group in which —CO—, —COO—, or —CONH— and an alkylene group or an arylene group are combined.

The substituent that can be adopted as R is not particularly limited, and it has the same meaning as the substituent X which may be contained in A in General Formula (2).

L is preferably a single bond or a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined.

L may have one or a plurality of substituents. The substituent which may be contained in L is not particularly limited, and for example, it has the same meaning as the substituent X. In a case where L has a plurality of substituents, the substituents bonded to adjacent atoms may be bonded to each other to further form a ring structure.

The alkylene group that can be adopted as L may be linear, branched, or cyclic as long as the group has 1 to 20 carbon atoms, and examples thereof include methylene, ethylene, propylene, methylethylene, methylmethylene, dimethylmethylene, 1,1-dimethylethylene, butylene, 1-methylpropylene, 2-methylpropylene, 1,2-dimethylpropylene, 1,3-dimethylpropylene, 1-methylbutylene, 2-methylbutylene, 3-methylbutylene, 4-methylbutylene, 2,4-dimethylbutylene, 1,3-dimethylbutylene, pentylene, hexylene, heptylene, octylene, ethane-1,1-diyl, propane-2,2-diyl, cyclopropane-1,1-diyl, cyclopropane-1,2-diyl, cyclobutane-1,1-diyl, cyclobutane-1,2-diyl, cyclopentane-1,1-diyl, cyclopentane-1,2-diyl, cyclopentane-1,3-diyl, cyclohexane-1,1-diyl, cyclohexane-1,2-diyl, cyclohexane-1,3-diyl, cyclohexane-1,4-diyl, and methylcyclohexane-1,4-diyl.

In a case where a linking group containing at least one of —CO—, —CS—, —NR— (R is as described above), —O—, —S—, —SO₂—, or —N═CH— in the alkylene group is adopted as L, the group such as —CO— may be incorporated at any position in the alkylene group, and the number of the groups incorporated is not particularly limited.

The arylene group that can be adopted as L is not particularly limited as long as the group has 6 to 20 carbon atoms, and examples thereof include a group obtained by further removing one hydrogen atom from each group exemplified as the aryl group having 6 to 20 carbon atoms that can be adopted as A in General Formula (1).

The heterocyclic group that can be adopted as L is not particularly limited, and examples thereof include a group obtained by further removing one hydrogen atom from each group exemplified as the heterocyclic group that can be adopted as A.

In General Formula (2M), the remaining partial structure excluding the linking group L corresponds to a structure (a metallocene structure portion) in which one hydrogen atom is removed from the metallocene compound. In the present invention, for the metallocene compound serving as the metallocene structure portion, a publicly known metallocene compound can be used without particular limitation, as long as it is a compound conforming to the partial structure defined by General Formula (2M) (a compound in which a hydrogen atom is bonded instead of L). Hereinafter, the metallocene structure portion defined by General Formula (2M) will be specifically described.

In General Formula (2M), R^{1m} to R^{9m} each independently represent a hydrogen atom or a substituent. The substituents that can be adopted as R^{1m} to R^{9m} are not particularly limited, and can be selected from, for example, the substituents that can be adopted as R¹ in General Formula (3). R^{1m} to R^{9m} each are preferably a hydrogen atom, a halogen atom, an alkyl group, an acyl group, an alkoxy group, an amino group, or an amide group, more preferably a hydrogen atom, a halogen atom, an alkyl group, an acyl group, or an alkoxy group, still more preferably a hydrogen atom, a halogen atom, an alkyl group, or an acyl group, particularly preferably a hydrogen atom, a halogen atom, or an alkyl group, and most preferably a hydrogen atom.

As the alkyl group that can be adopted as R^{1m} to R^{9m}, among the alkyl groups that can be adopted as R¹, an alkyl group having 1 to 8 carbon atoms is preferable, and examples thereof include methyl, ethyl, propyl, isopropyl, butyl, sec-butyl, tert-butyl, isobutyl, pentyl, tert-pentyl, hexyl, octyl, and 2-ethylhexyl.

This alkyl group may have a halogen atom as a substituent. Examples of the alkyl group substituted with a halogen atom include chloromethyl, dichloromethyl, trichloromethyl, bromomethyl, dibromomethyl, tribromomethyl, fluoromethyl, difluoromethyl, trifluoromethyl, 2,2,2-trifluoroethyl, perfluoroethyl, perfluoropropyl, and perfluorobutyl.

In addition, in the alkyl group that can be adopted as R^{1m} or the like, at least one methylene group that forms a carbon chain may be substituted with —O— or —CO—. Examples of the alkyl group in which the methylene group is substituted with —O— include, for example, an alkyl group in which the end part methylene group of methoxy, ethoxy, propoxy, isopropoxy, isobutoxy, sec-butoxy, tert-butoxy, 2-methoxyethoxy, chloromethyloxy, dichloromethyloxy, trichloromethyloxy, bromomethyloxy, dibromomethyloxy, tribromomethyloxy, fluoromethyloxy, difluoromethyloxy, trifluoromethyloxy, 2,2,2-trifluoroethyloxy, perfluoroethyloxy, perfluoropropyloxy, or perfluorobutyloxy is substituted, and an alkyl group in which an internal methylene group of the carbon chain such as 2-methoxyethyl or the like is substituted. Examples of the alkyl group in which a methylene group is substituted with —CO— include acetyl, propionyl, monochloroacetyl, dichloroacetyl, trichloroacetyl, trifluoroacetyl, propane-2-one-1-yl, and butane-2-one-1-yl.

In General Formula (2M), M represents an atom that can constitute a metallocene compound, and represents Fe, Co, Ni, Ti, Cu, Zn, Zr, Cr, Mo, Os, Mn, Ru, Sn, Pd, Rh, V, or Pt. Among these, M is preferably Fe, Ti, Co, Ni, Zr, Ru, or Os, more preferably Fe, Ti, Ni, Ru, or Os, still more preferably Fe or Ti, and most preferably Fe.

The group represented by General Formula (2M) is preferably a group formed by combining preferred ones of L, R^{1m} to R^{9m}, and M. Examples thereof include a group formed by combining, as L, a single bond, or a group selected from the group consisting of an alkylene group having 2 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined; as R^{1m} to R^{9m}, a hydrogen atom, a halogen atom, an alkyl group, an acyl group, or an alkoxy group; and as M, Fe.

The alkyl group, the alkenyl group, the alkynyl group, the aralkyl group, the aryl group, and the heteroaryl group that can be adopted as the substituent X and the aliphatic group, the aromatic group, and the heterocyclic group that can be adopted as R¹⁰ to R²⁷ each may further have a substituent or may be unsubstituted. The substituent which may be further contained therein is not particularly limited, and it is preferably a substituent selected from an alkyl group, an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfonylamino group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group, and it is more preferably a substituent selected from an alkyl group, an aryl group, an alkoxy group, an aryloxy group, an aromatic heterocyclic oxy group, an acyl group, an alkoxycarbonyl group, an aryloxycarbonyl group, an acyloxy group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group. This group can be appropriately selected from the substituents that can be adopted as R¹ in General Formula (2) described below.

One preferred embodiment of the coloring agent represented by General Formula (1) includes a coloring agent represented by General Formula (2).

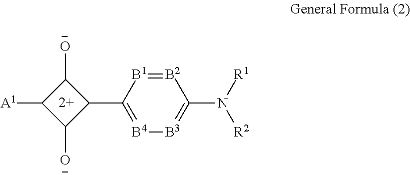

In General Formula (2), A¹ is the same as A in General Formula (1). Among these, a heterocyclic group which is a nitrogen-containing 5-membered ring is preferable.

In General Formula (2), R¹ and R² each independently represent a hydrogen atom or a substituent. R¹ and R² may be the same or different from each other, and they may be bonded together to form a ring.

The substituent that can be adopted as R¹ and R² is not particularly limited, and examples thereof include an alkyl group (a methyl group, an ethyl group, a propyl group, an isopropyl group, a butyl group, a t-butyl group, an isobutyl group, a pentyl group, a hexyl group, an octyl group, a dodecyl group, a trifluoromethyl group, or the like), a cycloalkyl group (a cyclopentyl group, a cyclohexyl group, or the like), an alkenyl group (a vinyl group, an allyl group, or the like), an alkynyl group (an ethynyl group, a propargyl group, or the like), an aryl group (a phenyl group, a naphthyl group, or the like), a heteroaryl group (a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, a phthalazyl group, or the like), a heterocyclic group (also referred to as a heterocyclic group, for example, a pyrrolidyl group, an imidazolidyl group, a morpholyl group, an oxazolidyl group, or the like), an alkoxy group (a methoxy group, an ethoxy group, a propyloxy group, or the like), a cycloalkoxy group (a cyclopentyloxy group, a cyclohexyloxy group, or the like), an aryloxy group (a phenoxy group, a naphthyloxy group, or the like), a heteroaryloxy group (an aromatic heterocyclic oxy group), an alkylthio a group (a methylthio group, an ethylthio group, a propylthio group, or the like), a cycloalkylthio group (a cyclopentylthio group, a cyclohexylthio group, or the like), an arylthio group (a phenylthio group, a naphthylthio group, or the like), a heteroarylthio group (an aromatic heterocyclic thio group), an alkoxycarbonyl group (a methyloxycarbonyl group, an ethyloxycarbonyl group, a butyloxycarbonyl group, an octyloxycarbonyl group, or the like), an aryloxycarbonyl group (a phenyloxycarbonyl group, a naphthyloxycarbonyl group, or the like), a phosphoryl group (dimethoxyphosphonyl or diphenylphosphoryl), a sulfamoyl group (an aminosulfonyl group, a methylaminosulfonyl group, a dimethylaminosulfonyl group, a butylaminosulfonyl group, a cyclohexylaminosulfonyl group, an octylaminosulfonyl group, a phenylaminosulfonyl group, a 2-pyridylaminosulfonyl group, or the like), an acyl group (an acetyl group, an ethylcarbonyl group, a propylcarbonyl group, a cyclohexylcarbonyl group, an octylcarbonyl group, a 2-ethylhexylcarbonyl group, a phenylcarbonyl group, a naphthylcarbonyl group, a pyridylcarbonyl group, or the like), an acyloxy group (an acetyloxy group, an ethylcarbonyloxy group, a butylcarbonyloxy group, an octylcarbonyloxy group, a phenylcarbonyloxy group, or the like), an amide group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, or the like), a sulfonylamide group (a methylsulfonylamino group, an octylsulfonylamino group, a 2-ethylhexylsulfonylamino group, a trifluoromethylsulfonylamino group, or the like), a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, or the like), a ureide group (a methylureide group, an ethylureide group, a pentylureide group, a cyclohexylureide group, an octylureide group, a dodecylureide group, a phenylureide group, a naphthylureide group, a 2-pyridylaminoureide group, or the like), an alkylsulfonyl group (a methylsulfonyl group, an ethylsulfonyl group, a butylsulfonyl group, a cyclohexylsulfonyl group, a 2-ethylhexylsulfonyl group, or the like), an arylsulfonyl group (a phenylsulfonyl group, a naphthylsulfonyl group, a 2-pyridylsulfonyl group, or the like), an amino group (an amino group, an ethylamino group, a dimethylamino group, a butylamino group, a dibutylamino group, a cyclopentylamino group, a 2-ethylhexylamino group, a dodecylamino group, an anilino group, a naphthylamino group, a 2-pyridylamino group, or the like), an alkylsulfonyloxy group (methanesulfonyloxy), a cyano group, a nitro group, halogen atoms (a fluorine atom, a chlorine atom, a bromine atom, or the like), and a hydroxy group.

Among these, an alkyl group, an alkenyl group, an aryl group, or a heteroaryl group is preferable, an alkyl group, an aryl group, or a heteroaryl group is more preferable, and an alkyl group is still more preferable.

The substituent that can be adopted as R¹ and R² may further have a substituent. Examples of the substituent which may be further contained therein include the substituent that can be adopted as R¹ and R², and the substituent X which may be contained in A, B, and G in General Formula (1) described above. In addition, R¹ and R² may be bonded to each other to form a ring, and R¹ or R² and the substituent contained in B² or B³ may be bonded to each other to form a ring.

The ring that is formed in this case is preferably a heterocyclic ring or a heteroaryl ring, and it is preferably a 5-membered ring or a 6-membered ring although the size of the ring to be formed is not particularly limited. In addition, the number of rings to be formed is not particularly limited, and it may be one or may be two or more. Examples of the form in which two or more rings are formed include a form in which the substituents of R¹ and B² and the substituents contained in R² and B³ are respectively bonded to each other to form two rings.

In General Formula (2), B¹, B², B³, and B⁴ each independently represent a carbon atom or a nitrogen atom. The ring including B¹, B², B³, and B⁴ is an aromatic ring. It is preferable that at least two or more of B¹ to B⁴ are a carbon atom, and it is more preferable that all of B¹ to B⁴ are a carbon atom.

The carbon atom that can be adopted as B¹ to B⁴ has a hydrogen atom or a substituent. Among carbon atoms that can be adopted as B¹ to B⁴, the number of carbon atoms having a substituent is not particularly limited; however, it is preferably zero, one, or two, and more preferably one. Particularly, it is preferable that B¹ and B⁴ are a carbon atom and at least one of them has a substituent.

The substituent possessed by the carbon atom that can be adopted as B¹ to B⁴ is not particularly limited, and examples thereof include the above-described substituents that can be adopted as R¹ and R². Among these, it is preferably an alkyl group, an alkoxy group, an alkoxycarbonyl group, an aryl group, an acyl group, an amide group, a sulfonylamide group, a carbamoyl group, an alkylsulfonyl group, an arylsulfonyl group, an amino group, a cyano group, a nitro group, a halogen atom, or a hydroxy group, and it is more preferably an alkyl group, an alkoxy group, an alkoxycarbonyl group, an aryl group, an acyl group, an amide group, a sulfonylamide group, a carbamoyl group, an amino group, a cyano group, a nitro group, a halogen atom, or a hydroxy group.

The substituent possessed by the carbon atom that can be adopted as B¹ to B⁴ may further have a substituent. The substituents that may be further possessed by the carbon atom include the substituent which may be further contained in R¹ and R² in General Formula (2) described above and the substituent X which may be contained in A, B, and G in General Formula (1) described above, where a ferrocenyl group is preferable.

Examples of the substituent that can be possessed by the carbon atom that can be adopted as B¹ and B⁴ still more preferably include an alkyl group, an alkoxy group, a hydroxy group, an amide group, a sulfonylamide group, or a carbamoyl group, and particularly preferably an alkyl group, an alkoxy group, a hydroxy group, an amide group, or a sulfonylamide group, and a hydroxy group, an amide group, or a sulfonylamide group is most preferable. The substituent possessed by the carbon atom that can be adopted as B¹ and B⁴ may further have a ferrocenyl group.

It is still more preferable that the substituent that can be possessed by the carbon atom that can be adopted as B² and B³ is an alkyl group, an alkoxy group, an alkoxycarbonyl group, an acyl group, an amino group, a cyano group, a nitro group, or a halogen atom, and it is particularly preferable that the substituent as any one of B² or B³ is an electron withdrawing group (for example, an alkoxycarbonyl group, an acyl group, a cyano group, a nitro group, or a halogen atom).

The coloring agent represented by General Formula (2) is preferably a coloring agent represented by any of General Formulae (3), (4), or (5).

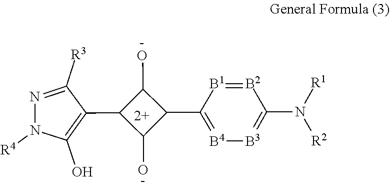

In General Formula (3), R¹ and R² each independently represent a hydrogen atom or a substituent, and they respectively have the same meanings as R¹ and R² in General Formula (2), where the same applies to the preferred ranges thereof.

In General Formula (3), B¹ to B⁴ each independently represent a carbon atom or a nitrogen atom, and they have respectively the same meanings as B¹ to B⁴ in General Formula (2), where the same applies to the preferred ranges thereof.

In General Formula (3), R³ and R⁴ each independently represent a hydrogen atom or a substituent. The substituent that can be adopted as R³ and R⁴ is not particularly limited, and examples thereof include the same ones as the substituents that can be adopted as R¹ and R².

However, the substituent that can be adopted as R³ is preferably an alkyl group, an alkoxy group, an amino group, an amide group, a sulfonylamide group, a cyano group, a nitro group, an aryl group, a heteroaryl group, a heterocyclic group, an alkoxycarbonyl group, a carbamoyl group, or a halogen atom, more preferably an alkyl group, an aryl group, or an amino group, and still more preferably an alkyl group. This substituent that can be adopted as R³ may further have a ferrocenyl group.

The substituent which can be adopted as R⁴ is preferably an alkyl group, an aryl group, a heteroaryl group, a heterocyclic group, an alkoxy group, an alkoxycarbonyl group, an acyl group, an acyloxy group, an amide group, a carbamoyl group, an amino group, or a cyano group, more preferably an alkyl group, an alkoxycarbonyl group, an acyl group, a carbamoyl group, or an aryl group, and still more preferably an alkyl group.

The alkyl group that can be adopted as R³ and R⁴ may be either linear, branched, or cyclic, and it is preferably linear or branched. The alkyl group preferably has 1 to 12 carbon atoms and more preferably 1 to 8 carbon atoms. An example of the alkyl group is preferably a methyl group, an ethyl group, an n-propyl group, an isopropyl group, a t-butyl group, a 2-ethylhexyl group, or a cyclohexyl group, and more preferably a methyl group or a t-butyl group.

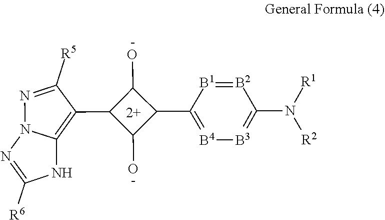

In General Formula (4), R¹ and R² each independently represent a hydrogen atom or a substituent, and they respectively have the same meanings as R¹ and R² in General Formula (2), where the same applies to the preferred ranges thereof.

In General Formula (4), B¹ to B⁴ each independently represent a carbon atom or a nitrogen atom, and they have respectively the same meanings as B¹ to B⁴ in General Formula (2), where the same applies to the preferred ranges thereof.

In General Formula (4), R⁵ and R⁶ each independently represent a hydrogen atom or a substituent. The substituent that can be adopted as R⁵ and R⁶ is not particularly limited, and examples thereof include the same ones as the substituents that can be adopted as R¹ and R².

However, the substituent that can be adopted as R⁵ is preferably an alkyl group, an alkoxy group, an aryloxy group, an amino group, a cyano group, an aryl group, a heteroaryl group, a heterocyclic group, an acyl group, an acyloxy group, an amide group, a sulfonylamide group, an ureide group, or a carbamoyl group, more preferably an alkyl group, an alkoxy group, an acyl group, an amide group, or an amino group, and still more preferably an alkyl group.

The alkyl group that can be adopted as R⁵ has the same meaning as the alkyl group that can be adopted as R³ in General Formula (3), and the same applies to the preferred range thereof.

In General Formula (4), the substituent that can be adopted as R⁶ is preferably an alkyl group, an alkenyl group, an aryl group, a heteroaryl group, a heterocyclic group, an alkoxy group, a cycloalkoxy group, an aryloxy group, an alkoxycarbonyl group, an acyl group, an acyloxy group, an amide group, a sulfonylamide group, an alkylsulfonyl group, an arylsulfonyl group, a carbamoyl group, an amino group, a cyano group, a nitro group, or a halogen atom, more preferably an alkyl group, an aryl group, a heteroaryl group, or a heterocyclic group, and still more preferably an alkyl group or an aryl group.

The alkyl group that can be adopted as R⁶ has the same meaning as the alkyl group that can be adopted as R⁴ in General Formula (3), and the same applies to the preferred range thereof.

The aryl group that can be adopted as R⁶ is preferably an aryl group having 6 to 12 carbon atoms, and more preferably a phenyl group. This aryl group may have a substituent, and examples of such a substituent include a group included in the following substituent group A, and an alkyl group, a sulfonyl group, an amino group, an acylamino group, a sulfonylamino group, or the like, which have 1 to 10 carbon atoms, is particularly preferable. This substituent may further have a substituent. Specifically, the substituent is preferably an alkylsulfonylamino group.

—Substituent group A—

A halogen atom, an alkyl group, an alkenyl group, an alkynyl group, an aryl group, a heterocyclic group, a cyano group, a hydroxy group, a nitro group, a carboxy group, an alkoxy group, an aminooxy group, an aryloxy group, a silyloxy group, a heterocyclic oxy group, an acyloxy group, a carbamoyloxy group, an amino group, an acylamino group, an aminocarbonylamino group, an alkoxycarbonylamino group, an aryloxycarbonylamino group, a sulfamoylamino group, a sulfonylamino group (including an alkyl or arylsulfonylamino group), a mercapto group, an alkylthio group, an arylthio group, a heterocyclic thio group, a sulfamoyl group, a sulfo group, an alkyl or arylsulfonyl group, a sulfonyl group (including an alkyl or arylsulfinyl group), an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a silyl group.

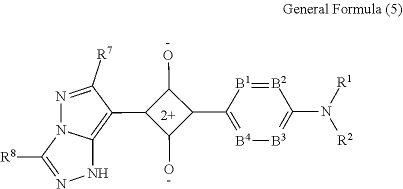

In General Formula (5), R¹ and R² each independently represent a hydrogen atom or a substituent, and they respectively have the same meanings as R¹ and R² in General Formula (2), where the same applies to the preferred ranges thereof.

In General Formula (5), B¹ to B⁴ each independently represent a carbon atom or a nitrogen atom, and they have respectively the same meanings as B¹ to B⁴ in General Formula (2), where the same applies to the preferred ranges thereof.

In General Formula (5), R⁷ and R⁸ each independently represent a hydrogen atom or a substituent. The substituent that can be adopted as R⁷ and R⁸ is not particularly limited, and examples thereof include the same ones as the substituents that can be adopted as R¹ and R².

However, the preferred range, the more preferred range, and the still more preferred range of the substituent that can be adopted as R⁷ are the same as those of the substituent that can be adopted as R⁵ in General Formula (4). The alkyl group that can be employed as R⁵ has the same meaning as the alkyl group that can be employed as R³, and the same applies to the preferred range thereof.

In General Formula (5), the preferred range, the more preferred range, and the still more preferred range of the substituent that can be adopted as R⁸ are the same as those of the substituent that can be adopted as R⁶ in General Formula (4). The preferred ranges of the alkyl group and the aryl group that can be adopted as R⁸ have the same meaning as the alkyl group and the aryl group that can be adopted as R⁶ in General Formula (4), where the same applies to the preferred ranges thereof.

As the squaraine-based coloring agent that is used for the above dye, any squaraine-based coloring agent represented by any of General Formulae (1) to (5) can be used without particular limitation. Examples thereof include compounds described in any of JP2006-160618A, WO2004/005981A, WO2004/007447A, Dyes and Pigment, 2001, 49, p. 161 to 179, WO2008/090757A, WO2005/121098A, and JP2008-275726A.

Specific examples of the coloring agent represented by any of General Formula (1) to General Formula (5) include the compounds described in [0067] to [0070] of WO02021/132674A. However, the present invention is not limited thereto.

In addition, in addition to the above-described specific examples, specific examples of the coloring agent represented by any one of General Formulae (3) to (5) include the compounds described in [0071] to [0080] of WO02021/132674A. However, the present invention is not limited thereto.

In addition, for the one preferred embodiment of the coloring agent represented by General Formula (1), the descriptions of the coloring agent represented by any of General Formulae (6) to (9) described in [0081] to [0095] of WO02021/132674A and the specific examples thereof can be applied as they are.

### (Quencher-Embedded Coloring Agent)

The squaraine-based coloring agent represented by General Formula (1) may be a quencher-embedded coloring agent in which a quencher moiety is linked to a coloring agent by a covalent bond through a linking group. The quencher-embedded coloring agent can also be preferably used as the above dye. That is, the quencher-embedded coloring agent is counted as the above dye according to the wavelength having the main absorption wavelength band.

Examples of the quencher-embedded coloring agent include an electron-donating quencher-embedded coloring agent in which the quencher moiety is an electron-donating quencher moiety, and an electron-accepting quencher moiety in which the quencher moiety is an electron-accepting quencher moiety.

The electron-donating quencher moiety means a structure portion that inactivates a coloring agent in the excited state to the ground state by donating an electron to a SOMO (singly occupied molecular orbital) at a low energy level of two SOMO's of the coloring agent in the excited state and then receiving an electron from a SOMO at a high energy level of the coloring agent. The electron-accepting quencher moiety means a structure portion that inactivates a coloring agent in the excited state to the ground state by accepting an electron from a SOMO at a high energy level of two SOMO's of the coloring agent in the excited state and then donating an electron to a SOMO at a low energy level of the coloring agent.

Examples of the electron-donating quencher moiety include the ferrocenyl group in the substituent X described above, and the quencher moieties in the quencher compounds described in paragraphs [0199] to [0212] and paragraphs [0234] to [0287] of WO02019/066043A, where the ferrocenyl group in the substituent X described above is preferable. In addition, examples of the electron-accepting quencher moiety include the quencher moieties in the quencher compounds described in paragraphs [0288] to [0310] of WO02019/066043A.

In the light absorption filter according to the embodiment of the present invention, from the viewpoint of the light resistance of the light absorptive portion, the dye having a main absorption wavelength band in a wavelength range of 400 to 700 nm preferably includes an electron-donating quencher-embedded coloring agent, and more preferably includes a squaraine-based coloring agent represented by General Formula (1A) described below.

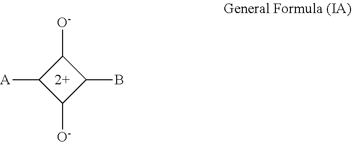

In the formula, A and B each independently represent an aryl group which may have a substituent, a heterocyclic group which may have a substituent, or —CH=G, where G represents a heterocyclic group which may have a substituent. However, at least one of A or B includes an electron-donating quencher moiety.

The coloring agent represented by General Formula (1A) is the same as the coloring agent represented by (1) described later, except that in the coloring agent represented by General Formula (1) described above, at least one of A or B includes an electron-donating quencher moiety. As a result, the description related to A, B, and G in General Formula (1) can be applied to the description related to A, B, and G in General Formula (1A). In addition, as a preferred embodiment of the coloring agent represented by General Formula (1A), a description in which, in the description of the coloring agent represented by any of General Formulae (2) to (9), which is a preferred embodiment of the coloring agent represented General Formula (1), at least one of the structures corresponding to A and B in General Formula (1) is changed to include an electron-donating quencher moiety can be applied.

The electron-donating quencher moiety contained in at least one of A and B is preferably the ferrocenyl group in the substituent X described above.

Hereinafter, among the squaraine-based coloring agents represented by General Formula (1), specific examples of the coloring agent corresponding to the quencher-embedded coloring agent include the compounds described in [0097] to [0114] of WO02021/132674A. However, the present invention is not limited thereto.

The total content of the dye in the light absorption filter according to the embodiment of the present invention is preferably 0.10% by mass or more, more preferably 0.15% by mass or more, still more preferably 0.20% by mass or more, particularly preferably 0.25% by mass or more, and especially preferably 0.30% by mass or more. In a case where the total content of the dye in the light absorption filter according to the embodiment of the present invention is equal to or larger than the above-described preferred lower limit value, a favorable light absorption property such as the antireflection effect can be obtained.

In addition, the total of the content of the dye in the light absorption filter according to the embodiment of the present invention is usually 50% by mass or less, preferably 40% by mass or less, more preferably 30% by mass or less, still more preferably 15% by mass or less, and particularly preferably 10% by mass or less.

That is, the total content of the dye in the light absorption filter according to the embodiment of the present invention is preferably 0.10% to 50% by mass, more preferably 0.15% to 40% by mass, still more preferably 0.20% to 30% by mass, particularly preferably 0.25% to 15% by mass, and especially preferably 0.30% to 10% by mass.

The content of the azo-based coloring agent represented by General Formula (i) in the light absorption filter according to the embodiment of the present invention is preferably 0.01% to 30% by mass and more preferably 0.1% to 10% by mass. In the light absorption filter according to the embodiment of the present invention, the content of each of the coloring agents of the azo-based coloring agent represented by General Formula (ii), the azo-based coloring agent represented by General Formula (iii), the azo-based coloring agent represented by General Formula (iv), and the indoaniline-based coloring agent represented by General Formula (v) is also preferably 0.01% to 30% by mass and more preferably 0.1% to 10% by mass, Similarly to the content of the azo-based coloring agent represented by General Formula (i). It is noted that in the light absorption filter according to the embodiment of the present invention, all of the dyes may be composed of at least one of the azo-based coloring agent represented by any of General Formulae (i) to (iv) or the indoaniline-based coloring agent represented by General Formula (v).

In a case where the light absorption filter according to the embodiment of the present invention contains the squaraine-based coloring agent represented by General Formula (1), the content of the squaraine-based coloring agent represented by General Formula (1) in the light absorption filter according to the embodiment of the present invention is preferably 0.01% to 30% by mass and more preferably 0.1% to 10% by mass. It is noted that in the light absorption filter according to the embodiment of the present invention, all of the dyes excluding the azo-based coloring agent represented by any of General Formulae (i) to (iv) and the indoaniline-based coloring agent represented by General Formula (v) among the above-described dyes may be the squaraine-based coloring agent represented by General Formula (1).

It is noted that in a case where the dye contains the quencher-embedded coloring agent, the content of the quencher-embedded coloring agent in the light absorption filter according to the embodiment of the present invention is preferably 0.10% by mass or more, more preferably 0.15% by mass or more, still more preferably 0.20% by mass or more, particularly preferably 0.25% by mass or more, and especially preferably 0.30% by mass or more, from the viewpoint of imparting light absorptance such as the antireflection effect. The upper limit value thereof is preferably 45% by mass or less, preferably 40% by mass or less, more preferably 30% by mass or less, still more preferably 15% by mass or less, and particularly preferably 10% by mass or less. That is, the total content of the quencher-embedded coloring agent in the light absorption filter is preferably 0.10% to 45% by mass, more preferably 0.15% to 40% by mass, still more preferably 0.20% to 30% by mass, particularly preferably 0.25% to 15% by mass, and especially preferably 0.30% to 10% by mass.

<Compound that Generates Radical Upon Ultraviolet Irradiation>

The light absorption filter according to the embodiment of the present invention contains a compound that generates a radical upon ultraviolet irradiation (also simply referred to as a “radical generator” in the present invention).

The radical generator is not particularly limited as long as it is a compound that generates a radical upon ultraviolet irradiation, where the compound has a function of decolorizing the above-described dye. As the radical generator, it is possible to use, for example, a photoradical generator which may be used in combination with a compound B, will be described later.

The radical generator also preferably includes a combination of two or more compounds, where the combination is such that two or more compounds interact with each other to form a complex in the light absorption filter, and as a result, a radical is generated upon ultraviolet irradiation. Regarding the kind of the compound to be combined, two or more kinds of compounds exhibiting functions different from each other need only to be used in a mechanism by which a radical is generated upon ultraviolet irradiation, and the kind of the compound to be combined is preferably two kinds. Preferred examples of such a combination include a combination of a compound A having an acid group and a compound B having a structure that is capable of forming a hydrogen bond with an acid group contained in the compound A.

In a case where the light absorption filter according to the embodiment of the present invention contains the compound A having an acid group and the compound B having a structure that is capable of forming a hydrogen bond with the acid group contained in the compound A, the efficiency of generating radical species upon ultraviolet irradiation is improved as compared with a case where the photoradical generator is used. As a result, even in a case where the ultraviolet irradiation is carried out under a mild temperature condition such as room temperature, sufficient radical species are generated, the radical species directly or indirectly react with the dye, and then the dye is decomposed, whereby the dye is faded and decolorized. In particular, the azo-based coloring agent represented by any of General Formulae (ii) to (iv) described above and the indoaniline-based coloring agent represented by General Formula (v) described above, which are contained in the light absorption filter according to the embodiment of the present invention, as well as the squaraine-based coloring agent represented by General Formula (1) described above, which may be contained therein, are decolorized without causing secondary absorption associated with the decomposition of the dye.

Hereinafter, the compound A having an acid group and the compound B having a structure that is capable of forming a hydrogen bond with the acid group contained in the compound A will be described in detail.

### (1) Compound a Having Acid Group

It is preferable that the light absorption filter according to the embodiment of the present invention contains a compound A having an acid group (also simply referred to as a “compound A” in the present invention) as the radical generator, and a compound B having a structure that is capable of forming a hydrogen bond, together with a compound B having a structure that is capable of forming a hydrogen bond with the acid group contained in the compound A, where the compound B will be described later.

The acid group contained in the compound A is preferably a proton dissociable group having a pKa of 12 or less. Specific examples of the acid group include a carboxy group, a sulfonamide group, a phosphonate group (—P(═O)(OH)₂), a phosphate group (—OP(═O)(OH)₂), a sulfo group, a phenolic hydroxyl group, and a sulfonyl imide group, where a carboxy group is preferable. It is noted that pKa means a negative common logarithm (−log Ka) of the acid dissociation constant (Ka) in water at 25° C., and it can be calculated in the same manner, except that in a calculation of the pKa of the compound B described later, a mixed solvent of water/methanol=50/50 (in terms of volume ratio) is changed to water.

The compound A may be a low-molecular-weight compound or a high-molecular-weight compound (hereinafter, also referred to as a “polymer”), where a polymer is preferable.

That is, the description that the compound A is a polymer means that the compound A is chemically bonded to a polymer that constitutes the resin contained in the light absorption filter according to the embodiment of the present invention.

In a case where the compound A is a low-molecular-weight compound, the molecular weight of the compound A is less than 5,000, and it is preferably 2,000 or less, more preferably 1,000 or less, still more preferably 500 or less, and particularly preferably 400 or less. The lower limit value thereof is not particularly limited. However, it is practically 100 or more, and it is preferably 200 or more. That is, it is practically 100 or more and less than 5,000, preferably 200 to 2,000, more preferably 200 to 1,000, still more preferably 200 to 500, and particularly preferably 200 to 400.

In a case where the compound A is a polymer, the lower limit value of the weight-average molecular weight of the compound A is 5,000 or more, and it is preferably 10,000 or more and more preferably 15,000 or more from the viewpoint of physical properties of the optical filter. The upper limit value thereof is not particularly limited; however, it is preferably 500,000 or less, more preferably 200,000 or less, and still more preferably 150,000 or less from the viewpoint of solubility in a solvent. That is, 5,000 to 500,000 is practical and preferable, 10,000 to 200,000 is more preferable, and 15,000 to 15,000 is still more preferable.

In addition, a part or all of the acid groups contained in the compound A may or may not be anionized in the light absorption filter, and in the present invention, both an anionized acid group and a non-anionized acid group are also referred to as an acid group. That is, the compound A may or may not be anionized in the light absorption filter.

The compound A is preferably a compound having a carboxy group from the viewpoint of excellent film-forming properties of the light absorption filter.

The above-described compound having a carboxy group is more preferably a monomer containing a carboxy group (hereinafter, also referred to as a “carboxy group-containing monomer”) or a polymer containing a carboxy group (hereinafter, also referred to as a “carboxy group-containing polymer”), and it is more preferably a carboxy group-containing polymer from the viewpoint of the film-forming properties of the light absorption filter.

It is noted that a part or all of the carboxy groups (—COOH) contained in the carboxy group-containing monomer and the carboxy group-containing polymer may or may not be anionized in the light absorption filter, and both an anionized carboxy group (—COO—) and a non-anionized carboxy group are also referred to as a carboxy group.

That is, the carboxy group-containing polymer may or may not be anionized in the light absorption filter, and both an anionized carboxy group-containing polymer and a non-anionized carboxy group-containing polymer are also referred to as a polymer.

The content of the compound A in the light absorption filter is preferably 1% by mass or more, more preferably 25% by mass or more, still more preferably 30% by mass or more, particularly preferably 45% by mass or more, and especially preferably 50% by mass or more. The upper limit value of the content of the compound A is preferably less than 100% by mass, more preferably 99% by mass or less, and still more preferably 97% by mass or less. That is, it is preferably 1% by mass or more and less than 100% by mass, more preferably 25% to 99% by mass, still more preferably 30% to 97% by mass, particularly preferably 45% to 97% by mass, and especially preferably 50% to 97% by mass.

Among the above, in a case where the compound A is a polymer, the content of the compound Ain the light absorption filter is preferably 50% by mass or more and less than 100% by mass, more preferably 60% by mass or more and less than 100% by mass, and still more preferably 70% by mass or more and less than 100% by mass. The upper limit value thereof is also preferably 99% by mass or less, more preferably 97% by mass or less, still more preferably 95% by mass or less, and particularly preferably 90% by mass or less.

One kind of the compound A may be used alone, or two or more kinds thereof may be used in combination.

### (Carboxy Group-Containing Monomer)

Examples of the carboxy group-containing monomer include a polymerizable compound which contains a carboxy group and contains one or more (for example, 1 to 15) ethylenically unsaturated groups.

Examples of the ethylenically unsaturated group include a (meth)acryloyl group, a vinyl group, and a styryl group, and a (meth)acryloyl group is preferable.

It is noted that in a case where the ethylenically unsaturated group is a (meth)acryloyl group, a carbonyl bond in the (meth)acryloyl group and a carbonyl bond in the carboxy group may share one carbonyl bond.

From the viewpoint of more excellent film-forming properties, the carboxy group-containing monomer is preferably a bi- or higher functional monomer containing a carboxy group. The bi- or higher functional monomer means a polymerizable compound having 2 or more (for example, 2 to 15) ethylenically unsaturated groups in one molecule.

It suffices that the number of carboxy groups contained in the carboxy group-containing monomer is 1 or more, and the number thereof is, for example, preferably 1 to 8, more preferably 1 to 4, and still more preferably 1 or 2.

The carboxy group-containing monomer may further have, as an acid group, an acid group other than the carboxy group. Examples of the acid group other than the carboxy group include a phenolic hydroxyl group, a phosphate group, and a sulfonate group.

The bi- or higher functional monomer containing a carboxy group is not particularly limited and can be appropriately selected from known compounds.

Examples of the bi- or higher functional monomer containing a carboxy group include, as product names, ARONIX M-520 and ARONIX M-510 (both manufactured by Toagosei Co., Ltd.).

In addition, examples of the bi- or higher functional monomer containing a carboxy group include a tri- or tetra-functional polymerizable compound having a carboxy group (a compound obtained by introducing a carboxy group into a pentaerythritol triacrylate and pentaerythritol tetraacrylate [PETA] skeleton (acid value=80 to 120 mgKOH/g)) and a penta- or hexa-functional polymerizable compound having a carboxy group (a compound obtained by introducing a carboxy group into a dipentaerythritol pentaacrylate and dipentaerythritol hexaacrylate [DPHA] skeleton (acid value=25 to 70 mgKOH/g)). In a case where the above-described tri- or higher functional monomer containing a carboxy group is used, from the viewpoint of more excellent film-forming properties, it is also preferable to use the bi- or higher functional monomer containing a carboxy group in combination.

Examples of the bi- or higher functional monomer containing a carboxy group and the bi- or higher functional monomer containing an acid group also include the polymerizable compounds having a carboxy group, which are described in paragraphs 0025 to 0030 of JP2004-239942A. The contents of this patent publication are incorporated in the present specification by reference.

### (Carboxy Group-Containing Polymer)

The carboxy group-containing polymer may further have, as an acid group, an acid group other than the carboxy group. Examples of the acid group other than the carboxy group include a phenolic hydroxyl group, a phosphate group, and a sulfonate group.

In a case where the carboxy group-containing polymer is a copolymer, the structure of the polymer may be a random polymer or a regular polymer such as a block.

### <<Constitutional Unit Having Carboxy Group>>

The carboxy group-containing polymer preferably has a constitutional unit having a carboxy group.

Examples of the constitutional unit having a carboxy group include a constitutional unit derived from (meth)acrylic acid, crotonic acid, itaconic acid, maleic acid, or fumaric acid. Among the above, a constitutional unit derived from (meth)acrylic acid is preferable from the viewpoint of high decolorizing properties of the dye.

In the carboxy group-containing polymer, the content of the constitutional unit having a carboxy group is preferably 1% to 100% by mole, more preferably 3% to 65% by mole, still more preferably 5% to 45% by mole, and particularly preferably 10% to 45% by mole in a case where the total of all the constitutional units of the carboxy group-containing polymer is set to 100% by mole.

One kind of the constitutional unit having a carboxy group may be used alone, or two or more kinds thereof may be used in combination.

### <<Constitutional Unit Having Aromatic Ring>>

It is also preferable that the carboxy group-containing polymer has a constitutional unit having an aromatic ring (preferably, an aromatic hydrocarbon ring) in addition to the above-described constitutional unit. Examples thereof include a constitutional unit derived from a (meth)acrylate having an aromatic ring (specifically, benzyl (meth)acrylate, phenethyl (meth)acrylate, phenoxyethyl (meth)acrylate, or the like).

In the carboxy group-containing polymer, the content of the constitutional unit having an aromatic ring is preferably 0% to 97% by mole, more preferably 0% to 95% by mole, and still more preferably 0% to 90% by mole in a case where the total of all the constitutional units of the carboxy group-containing polymer is set to 100% by mole.

One kind of the constitutional unit having an aromatic ring may be used alone, or two or more kinds thereof may be used in combination.

### <<Constitutional Unit Having Alicyclic Structure>>

It is also preferable that the carboxy group-containing polymer has a constitutional unit having an alicyclic structure in addition to the above-described constitutional unit.

Examples of the alicyclic structure include a tricyclo[5.2.1.0^{2,6}]decane ring structure (also referred to as tetrahydrodicyclopentadiene, where a monovalent group is dicyclopentanyl), a tricyclo[5.2.1.0^{2,6}]decane-3-ene ring structure (also referred to as 5,6-dihydrodicyclopentadiene, where a monovalent group is dicyclopentenyl), an isobornane ring structure (where a monovalent group is isobornyl), an adamantane ring structure (where a monovalent group is adamantyl), and a cyclohexane ring structure (where a monovalent group is cyclohexyl).

Examples of the constitutional unit having an alicyclic structure include a constitutional unit derived from a (meth)acrylate having an alicyclic structure (specifically, dicyclopentanyl (meth)acrylate, dicyclopentenyl (meth)acrylate, isobornyl (meth)acrylate, adamantyl (meth)acrylate, cyclohexyl (meth)acrylate, or the like).

In the carboxy group-containing polymer, the content of the constitutional unit having an alicyclic structure is preferably 0% to 97% by mole, more preferably 0% to 95% by mole, and still more preferably 0% to 90% by mole in a case where the total of all the constitutional units of the carboxy group-containing polymer is set to 100% by mole.

One kind of the constitutional unit having an alicyclic structure may be used alone, or two or more kinds thereof may be used in combination.

### <<Another Constitutional Unit>>

The carboxy group-containing polymer may have another constitutional unit in addition to the above-described constitutional units.

Examples of the other constitutional unit include a constitutional unit derived from methyl (meth)acrylate.

In the carboxy group-containing polymer, the content of the other constitutional unit is preferably 0% to 70% by mole, more preferably 0% to 50% by mole, and still more preferably 0% to 20% by mole in a case where the total of all the constitutional units of the carboxy group-containing polymer is set to 100% by mole.

One kind of the other constitutional unit may be used alone, or two or more kinds thereof may be used in combination.

### (2) Compound B

It is preferable that the light absorption filter according to the embodiment of the present invention contains together with the above-described compound A as the radical generator, a compound B having a structure that is capable of forming a hydrogen bond with the acid group contained in the compound A (also simply referred to as a “compound B” in the present invention).

The compound B is preferably a compound having such a structure that absorbs ultraviolet rays to be in an excited state, thereby having an increased basicity. In a case where the basicity of the compound B is increased in the excited state, it is possible to form a complex in which the acid group contained in the compound A interacts more strongly with the compound B, and it is possible to increase the efficiency of generating radicals.

A structure contained in the compound B, the structure that is capable of forming a hydrogen bond with the acid group contained in the compound A, may be a whole structure of the compound B or may be a partial structure that constitutes a part of the compound B.

The compound B may be a high-molecular-weight compound (which means a compound having a molecular weight of 5,000 or more) or a low-molecular-weight compound (which means a compound having a molecular weight of less than 5,000), and it is preferably a low-molecular-weight compound.

The molecular weight of the compound B as a low-molecular-weight compound is less than 5,000, and it is preferably less than 1,000, more preferably 500 or less, and still more preferably 350 or less. The lower limit value thereof is not particularly limited; however, it is preferably 65 or more and more preferably 75 or more. Examples of the preferred range of the molecular weight of the compound B which is a low-molecular-weight compound include 65 to 500 and more preferably 75 to 350.

From the viewpoint that the molar absorption coefficient with respect to ultraviolet rays is large, the compound B is preferably an aromatic compound.

Here, the aromatic compound is a compound having one or more aromatic rings.

Only one aromatic ring may be present in the compound B, or a plurality of aromatic rings may be present therein. In a case where a plurality of aromatic rings is present, the aromatic rings may be present, for example, in the side chain or the like of the polymer that constitutes the resin.

The aromatic ring may be any of an aromatic hydrocarbon ring or an aromatic heterocyclic ring. In a case of being an aromatic heterocyclic ring (also referred to as a heteroaromatic ring), it is a compound having one or more (for example, 1 to 4) heteroatoms (at least one among nitrogen atoms, oxygen atoms, sulfur atoms, and the like) as a ring member atom (ring-constituting atom) and preferably has one or more (for example, 1 to 4) nitrogen atoms as a ring member atom.

It is noted that since the unsubstituted aromatic hydrocarbon does not have a structure that is capable of forming a hydrogen bond with the acid group contained in the compound A, the unsubstituted aromatic hydrocarbon does not have a function of generating a radical upon ultraviolet irradiation and does not correspond to the compound B. In addition, since an unsubstituted aromatic hydrocarbon ring in a form in which the unsubstituted aromatic hydrocarbon ring is bonded to the side chain of the polymer that constitutes the resin does not have a structure that is capable of forming a hydrogen bond with the acid group contained in the compound A, the unsubstituted aromatic hydrocarbon ring does not have a function of generating a radical upon ultraviolet irradiation and does not correspond to the compound B.

The number of ring member atoms in the above-described aromatic ring is preferably 5 to 15.

Examples of the above-described aromatic ring include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a phenanthridine ring, a phenanthroline ring, and a phenazine ring.

The above-described aromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, and a nitro group. In addition, in a case where the above-described aromatic ring has two or more substituents, a plurality of substituents may be bonded to each other to form a non-aromatic ring.

In a case where a plurality of aromatic rings (for example, 2 to 5 aromatic rings) forms a series of aromatic ring structures bonded with a structure selected from a single bond, a carbonyl bond, and a multiple bond (for example, a vinylene group which may have a substituent, —C≡C—, —N═N—, and the like), the entire series of aromatic ring structures is regarded as one specific structure.

In addition, it is preferable that one or more of the aromatic rings constituting the series of aromatic ring structures are the above-described heteroaromatic rings.

Specific examples of the compound B include monocyclic aromatic compound such as a pyridine compound (pyridine or a pyridine derivative), a pyrazine compound (pyrazine or a pyrazine derivative), a pyrimidine compound (pyrimidine or a pyrimidine derivative), and a triazine compound (triazine or a triazine derivative); compounds in which two rings are fused to form an aromatic ring, such as a quinoline compound (quinoline or a quinoline derivative), an isoquinoline compound (isoquinoline or an isoquinoline derivative), a quinoxaline compound (quinoxaline or a quinoxaline derivative), and a quinazoline compound (quinazoline or a quinazoline derivative); and compounds in which three or more rings are fused to form an aromatic ring, such as an acridine compound (acridine or an acridine derivative), a phenanthridine compound (phenanthridine or a phenanthridine derivative), a phenanthroline compounds (phenanthroline or a phenanthroline derivative), and a phenazine compounds (phenazine or a phenazine derivative). In the specific examples of the compound B, the compound is used to have a meaning including not only the compound itself but a compound having a substituent (referred to as a “derivative”), including an unsubstituted compound in which a part of the structure has been changed, within a range where the effect of the present invention is not impaired.

It is presumed that this compound B forms a complex with the compound A and generates two molecules of radicals by the following mechanism upon ultraviolet irradiation.
1) The compound B in an excited state is generated by absorbing ultraviolet rays.
2) Positive holes move from the compound B in the excited state to the compound A in the ground state (the electrons of the compound A move to an orbital with lower energy in the two semi occupied molecular orbitals of the compound B in the excited state).
3) The movement of a proton from the compound A to the compound B generates a radical in which a hydrogen radical is loaded on the compound B and a radical in which a hydrogen radical is eliminated from the compound A.

In a case where the compound A is a compound having a carboxy group, the following reaction further occurs, and a radical is generated by a photodecarboxylation reaction.
4) Carbon dioxide is eliminated from the radical in which the hydrogen radical has been eliminated from the compound A.

Among the above, the compound B is preferably one or more among quinoline compounds (quinoline and a quinoline derivative) and isoquinoline compounds (isoquinoline and an isoquinoline derivative).

The substituent which may be contained in these compounds is preferably an alkyl group, an aryl group, a halogen atom, an acyl group, an alkoxycarbonyl group, an arylcarbonyl group, a carbamoyl group, a hydroxy group, a cyano group, or a nitro group.

In a case where the compound B is a polymer, the compound B may be a polymer in which the above-described specific structure is bonded to a polymer main chain through a single bond or a linking group.

The compound B as a polymer is obtained by, for example, polymerizing a monomer having a heteroaromatic ring (specifically, a (meth)acrylate monomer having a heteroaromatic ring having a vinyl group and/or a specific structure (preferably, a heteroaromatic ring)). As necessary, copolymerization with another monomer may be carried out.

Specific examples of the compound B include quinoline, 2-methylquinoline, 4-methylquinoline, 2,4-dimethylquinoline, 2-methyl-4-phenylquinoline, isoquinoline, 1-methylisoquinoline, 3-methylisoquinoline, and 1-phenylisoquinoline.

From the viewpoint of achieving both the decolorizing properties of the ultraviolet irradiated portion and the durability of the dye in the ultraviolet non-irradiated portion, the content of the compound B is preferably 0.1% to 50% by mass, more preferably 2.0% to 40% by mass, still more preferably 4% to 35% by mass, and particularly preferably 8% to 30% by mass, with respect to the total mass of the light absorption filter.

In addition, similarly, from the viewpoint of achieving both the decolorizing properties of the ultraviolet irradiated portion and the durability of the dye in the ultraviolet non-irradiated portion, the pKaH (the pKa of the conjugate acid), which is an index of the basicity of the compound B, is preferably 2.0 or more and 7.0 or less, more preferably 3.0 or more and 6.0 or less, and still more preferably 4.3 or more and 5.5 or less.

In the present invention, the pKa means a negative common logarithm (−log Ka) of the acid dissociation constant (Ka) in a mixed solvent of water/methanol=50/50 (in terms of volume ratio) at 25° C. The pKa can be calculated by dropwise adding a 0.01 mol/L sodium hydroxide aqueous solution to a mixed solution of water/methanol=50/50 (in terms of volume ratio) of a measurement sample (a conjugate acid of the compound B) and reading the amount of the sodium hydroxide aqueous solution that has been dropwise added up to the half-equivalent point.

One kind of the compound B may be used alone, or two or more kinds thereof may be used in combination.

The light absorption filter according to the embodiment of the present invention may contain a compound that generates a radical upon ultraviolet irradiation (also referred to as a “photoradical generator” in the present invention) in addition to the compound B. The photoradical generator is not particularly limited as long as it is a compound that generates a radical upon ultraviolet irradiation and has a function of decolorizing the above-described dye. It is noted that the radical generated may be a biradical in addition to the typical radical.

As the photoradical generator, a compound commonly used as a photoradical polymerization initiator a photoradical generator can be used without particular limitation, and examples thereof include an acetophenone generator, a benzoin generator, a benzophenone generator, a phosphine oxide generator, an oxime generator, a ketal generator, an anthraquinone generator, a thioxanthone generator, an azo compound generator, a peroxide generator, a disulfide generator, a lophine dimer generator, an onium salt generator, a borate salt generator, an active ester generator, an active halogen generator, an inorganic complex generator, and a coumarin generator. It is noted that an “XX generator” as the specific example of the photoradical generator may be individually referred to as an “XX compound” or “XX compounds”, and hereinafter, it is referred to as an “XX compound”.

Specific examples, preferred forms, commercially available products, and the like of the photoradical generator are respectively described as the specific examples, preferred forms, commercially available products, and the like of the photo-radical initiator in paragraphs [0133] to [0151] of JP2009-098658A, and these can be similarly used suitably in the present invention.

The photoradical generator is preferably a compound that generates a radical upon intramolecular cleavage or a compound that abstracts a hydrogen atom from a compound present in the vicinity thereof to generate a radical, and it is more preferably a compound that abstracts a hydrogen atom from a compound present in the vicinity thereof to generate a radical, from the viewpoint of further improving the decolorization rate.

The above-described compound that generates a radical upon intramolecular cleavage (hereinafter, also referred to as an “intramolecular cleavage type photoradical generator”) means a compound that generates a radical, where the compound absorbing light undergoes bonding cleavage in a homolytic manner.

Examples of the intramolecular cleavage type photoradical generator include an acetophenone compound, a benzoin compound, a phosphine oxide compound, an oxime compound, a ketal compound, an azo compound, a peroxide compound, a disulfide compound, an onium salt compound, a borate salt compound, an active ester compounds, an active halogen compound, an inorganic complex compound, and a coumarin compound. Among these, an acetophenone compound, a benzoin compound, or a phosphine oxide compound, which is a carbonyl compound, is preferable. The Norrish type I reaction is known as a photodecomposition reaction of an intramolecular cleavage type carbonyl compound, and this reaction can be referenced as a radical generation mechanism.

The above-described compound that abstracts a hydrogen atom from a compound present in the vicinity thereof to generate a radical (hereinafter, also referred to as a “hydrogen abstraction type photoradical generator”) means a carbonyl compound in an excited triplet state obtained upon light absorption that abstracts a hydrogen atom from a compound present in the vicinity thereof to generate a radical.

A carbonyl compound is known as the hydrogen abstraction type photoradical generator, and examples thereof include a benzophenone compound, an anthraquinone compound, and a thioxanthone compound. The Norrish type II reaction is known as a photodecomposition reaction of a hydrogen abstraction type carbonyl compound, and this reaction can be referenced as a radical generation mechanism.

Examples of the compound present in the vicinity include various components present in the light absorption filter, such as a resin, a dye, and a radical generator.

The compound present in the vicinity becomes a compound having a radical by a hydrogen atom being abstracted therefrom. Since a dye from which a hydrogen atom has been abstracted by the hydrogen abstraction type photoradical generator becomes an active compound having a radical, the dye may be faded or decolorized through a reaction such as the decomposition of the dye having the radical.

In addition, in a case where the hydrogen abstraction type photoradical generator abstracts a hydrogen atom in the molecule, a biradical is generated.

The hydrogen abstraction type photoradical generator is preferably a benzophenone compound from the viewpoint of the quantum yield of the hydrogen abstraction reaction.

Various examples of the photoradical generator are also described in “Latest UV Curing Technology”, TECHNICAL INFORMATION INSTITUTE CO. LTD., 1991, p. 159, and “Ultraviolet Curing System”, written by Kiyomi Kato, 1989, published by SOGO GIJUTSU CENTER, p. 65 to 148, which can be also suitably used in the present invention.

In the photoradical generator, the maximal absorption wavelength of the ultraviolet ray to be absorbed is preferably in a range of 250 to 400 nm, more preferably in a range of 240 to 400 nm, and still more preferably in a range of 270 to 400 nm.

In a case where the photoradical generator is a benzophenone compound, the wavelength of the absorption maximum attributed to the n-π* transition, which is located on the longest wavelength side, is preferably in a range of 260 to 400 nm and more preferably in a range of 285 to 345 nm. The wavelength of the absorption maximum attributed to 7-7*, which is located on the second longest wavelength side, is preferably in a range of 240 to 380 nm and more preferably in a range of 270 to 330 nm. In a case where the absorption maximum wavelength is set in the above range, the light of a light source used at the time of exposure, such as a metal halide lamp, is absorbed well. On the other hand, in a case of being incorporated into a display device, the light absorption filter becomes difficult to absorb an ultraviolet ray incident from the outside, and thus it becomes possible to achieve both the light resistance of the unexposed portion and the decolorizing properties of the exposed portion.

Among the benzophenone compounds, examples of the photoradical generator having absorption in a longer wavelength range include an alkoxybenzophenone compound.

In general, the maximal absorption wavelength of the ultraviolet ray absorbed by the photoradical generator is preferably separated by 30 nm or more from the main absorption wavelength band of the dye that has a main absorption wavelength band in a wavelength range of 400 to 700 nm. The upper limit value thereof is not particularly limited.

Examples of the commercially available photocleavage type photoradical generator include “Irgacure 651”, “Irgacure 184”, “Irgacure 819”, “Irgacure 907”, “Irgacure 1870” (a mixed initiator of CGI-403/Irgacure 184=7/3), “Irgacure 500”, “Irgacure 369”, “Irgacure 1173”, “Irgacure 2959”, “Irgacure 4265”, “Irgacure 4263”, “Irgacure 127”, or “OXE01”, all of which are product names, manufactured by BASF SE (formerly Ciba Specialty Chemicals Inc.); additionally, “Kayacure DETX-S”, “Kayacure BP-100”, “Kayacure BDMK”, “Kayacure CTX”, “Kayacure BMS”, “Kayacure 2-EAQ”, “Kayacure ABQ”, “Kayacure CPTX”, “Kayacure EPD”, “Kayacure ITX”, “Kayacure QTX”, “Kayacure BTC”, and “Kayacure MCA”, manufactured by Nippon Kayaku Co., Ltd.; and more additionally “Esacure (KIP100F, KB1, EB3, BP, X33, KT046, KT37, KIP150, and TZT)” manufactured by Sartomer Company Inc. In addition, preferred examples thereof include a combination of two or more of these.

In a case where the light absorption filter according to the embodiment of the present invention contains a photoradical generator, the content of the photoradical generator in the light absorption filter according to the embodiment of the present invention is preferably 0.01% to 30% by mass and more preferably 0.1% to 20% by mass.

From the viewpoint of further improving the decolorization rate, the blending amount of the radical generator in the light absorption filter according to the embodiment of the present invention is preferably 0.1 to 20 mol with respect to 1 mol of the dye that has a main absorption wavelength band in a wavelength range of 400 to 700 nm. The lower limit value thereof is more preferably 0.25 mole or more and still more preferably 0.50 mole or more. The upper limit value thereof is more preferably 17.5 mol or less and still more preferably 15 mol or less. The blending amount of the radical generator referred to herein means the blending amount of the photoradical generator or the blending amount of the compound B described above, and does not include the blending amount of the compound A.

The light absorption filter according to the embodiment of the present invention may contain one kind of the radical generator or may contain two or more kinds thereof.

### <Resin>

The resin contained in the light absorption filter according to the embodiment of the present invention (hereinafter, also referred to as a “matrix resin”) is not limited as long as it can disperse (preferably dissolve) the above-described dye, can exhibit the decolorization action of the dye due to the radical generated from a compound (preferably, the compound B that has been hydrogen-bonded to the acid group contained in the compound A) that generates a radical upon ultraviolet irradiation, and has desired light transmittance (the light transmittance is preferably 80% or more in the visible range in a wavelength range of 400 to 800 nm).

As a polymer that constitutes the above-described resin, various polymers can be used. However, from the viewpoint that the molecular weight of the resin is not easily reduced upon ultraviolet irradiation, a polymer having an aromatic ring or an alicyclic structure in the side chain is preferable, and a (meth)acrylic polymer containing a constitutional unit having an aromatic ring or an alicyclic structure is more preferable. Among the above, from the viewpoint of further improving the decolorization rate and further improving the heat resistance and the light resistance as well, a (meth)acrylic polymer containing a constitutional unit having an alicyclic structure in the side chain is still more preferable.

Here, the (meth)acrylic polymer refers to a polymer containing at least one of a constitutional unit derived from (meth)acrylic acid or a constitutional unit derived from (meth)acrylic acid ester. It is noted that the constitutional unit derived from (meth)acrylic acid is a constitutional unit having a carboxy group as the acid group in the compound A, in a case where the polymer contains a constitutional unit derived from (meth)acrylic acid, and the polymer corresponds to a polymer in which the compound A is chemically bonded to the above-described polymer that constitutes the resin.

In addition, in the present disclosure, the “main chain” represents a relatively longest bonding chain in a molecule of a high-molecular-weight compound, and the “side chain” represents an atomic group branched from the main chain.

Examples of the monomer from which a constitutional unit having an aromatic ring is derived include benzyl acrylate, benzyl methacrylate, naphthyl acrylate, naphthyl methacrylate, naphthyl methyl acrylate, and naphthyl methyl methacrylate. In a case where the polymer does not contain a constitutional unit derived from (meth)acrylic acid, the content of the constitutional unit having an aromatic ring is preferably 5% to 100% by mass, more preferably 10% to 100% by mass, and still more preferably 20% to 100% by mass, with respect to the total mass of the polymer.

Examples of the monomer from which a constitutional unit having an alicyclic structure is derived include dicyclopentanyl (meth)acrylate, cyclohexyl (meth)acrylate, and isobornyl (meth)acrylate.

In a case where the polymer contains a constitutional unit having an alicyclic structure, the content of the constitutional unit having an alicyclic structure is preferably 1% to 90% by mass, more preferably 5% to 90% by mass, and still more preferably 5% to 80% by mass, with respect to the total mass of the polymer.

In addition, in the light absorption filter according to the embodiment of the present invention, the polymer that constitutes the resin may contain a constitutional unit bonded to the compound A having an acid group. The constitutional unit bonded to the compound A having an acid group is preferably a constitutional unit derived from (meth)acrylic acid. The content of the constitutional unit derived from (meth)acrylic acid is preferably 1% to 70% by mass and more preferably 1% to 60% by mass with respect to the total mass of the polymer. More preferably, the description of the content of the constitutional unit having the carboxy group of the carboxy group-containing polymer as the compound A is applied.

In a case where the polymer that constitutes the resin contains a constitutional unit bonded to the compound A having an acid group, the descriptions regarding the content of the constitutional unit having the carboxy group of the carboxy group-containing polymer as the compound A and the content of the constitutional unit having an aromatic ring and the content of the constitutional unit having an alicyclic structure are applied to the content of the constitutional unit bonded to the compound A having an acid group, the content of the constitutional unit having an aromatic ring, and the content of the constitutional unit having an alicyclic structure.

From the viewpoint of adjusting the glass transition temperature and the like, the polymer that constitutes the resin may contain a constitutional unit that has an alkyl group having 1 to 14 carbon atoms. Examples of the constitutional unit having an alkyl group having 1 to 14 carbon atoms include a constitutional unit derived from an alkyl (meth)acrylate, such as methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethylbutyl (meth)acrylate, n-octyl (meth)acrylate, isooctyl (meth)acrylate, isononyl (meth)acrylate, lauryl (meth)acrylate, or tetradecyl (meth)acrylate. In the present invention, one kind of the constitutional unit having an alkyl group having 1 to 14 carbon atoms may be used alone, or two or more kinds thereof may be used in combination. The content of the constitutional unit having an alkyl group having 1 to 14 carbon atoms is preferably such that an amount of 0% by mass to 95% by mass is contained with respect to the total mass of the polymer that constitutes the resin.

The weight-average molecular weight (Mw) of the polymer that constitutes the resin is preferably 10,000 or more, more preferably 10,000 to 200,000, and still more preferably 15,000 to 150,000.

### <Other Components>

In addition to the above-described dye, the above-described compound that generates a radical upon ultraviolet irradiation, and the above-described resin (matrix polymer), the absorption filter according to the embodiment of the present invention may contain an antifading agent, a matting agent, a leveling agent (a surfactant), and the like.

### <Antifading Agent>

In the light absorption filter according to the embodiment of the present invention, it is preferable that the antifading agent does not inhibit the decolorization due to ultraviolet irradiation but has an effect of suppressing the dye decomposition due to visible light.

The compound represented by General Formula (IV) below can be preferably used as the antifading agent.

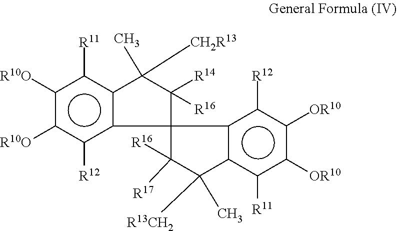

In Formula (IV), R¹⁰ represents an alkyl group, an alkenyl group, an aryl group, a heterocyclic group, or a group represented by R¹⁸CO—, R¹⁹SO₂—, or R²⁰NHCO—. Here, R¹⁸, R¹⁹, and R²⁰ each independently represent an alkyl group, an alkenyl group, an aryl group, or a heterocyclic group. R¹¹ and R¹² each independently represent a hydrogen atom, a halogen atom, an alkyl group, an alkenyl group, an alkoxy group, or an alkenyloxy group, and R¹³, R¹⁴, R¹⁵, R¹⁶, and R¹⁷ each independently represent a hydrogen atom, an alkyl group, an alkenyl group, or an aryl group.

However, the alkyl group in R¹⁰ to R²⁰ includes an aralkyl group.

The compound represented by General Formula (IV) is the same as the compound represented by General Formula (IV) described in [0215] to [0221] of WO02021/221122A. Therefore, for the description of each substituent in General Formula (IV) and the specific examples of the compound represented by General Formula (IV), the description of [0217] to [0221] of WO02021/221122A can be applied as it is.

As the antifading agent, the compound represented by General Formula [III] can also be preferably used.

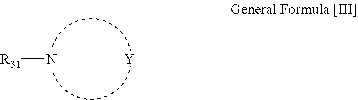

In General Formula [III], R₃₁ represents an aliphatic group or an aromatic group, and Y represents a non-metal atomic group necessary for forming a 5- to 7-membered ring with a nitrogen atom.

The compound represented by General Formula [III] is the same as the compound represented by General Formula [III] described in [0223] to [0227] of WO02021/221122A. Therefore, for the description of each substituent in General Formula [III] and the specific examples of the compound represented by General Formula [III], the description of [0225] to [0227] of WO02021/221122A can be applied as it is.

In addition, in addition to the above-described specific examples, specific examples of the compound represented by General Formula [III] above include exemplary compounds B-1 to B-65 described on pages 8 to 11 of JP1990-167543A (JP-H2-167543A), and exemplary compounds (1) to (120) described on pages 4 to 7 of JP1988-95439A (JP-S63-95439A).

The content of the antifading agent in the light absorption filter according to the embodiment of the present invention is preferably 1% to 15% by mass, more preferably 5% to 15% by mass, still more preferably 5% to 12.5% by mass, and particularly preferably 10% to 12.5% by mass.

In a case where the antifading agent is contained within the above-described preferred range, it is possible to improve the light resistance of the dye (the coloring agent) without causing side effects such as discoloration.

### (Matting Agent)

In order to impart sliding properties and prevent blocking, fine particles may be added to the surface of the light absorption filter according to the embodiment of the present invention as long as the effect of the present invention is not impaired. As the fine particles, silica (silicon dioxide, SiO₂) of which the surface is coated with a hydrophobic group and which has an aspect of secondary particles is preferably used. As the fine particles, in addition to or instead of silica, fine particles of titanium dioxide, aluminum oxide, zirconium oxide, calcium carbonate, talc, clay, calcined kaolin, calcined calcium silicate, hydrated calcium silicate, aluminum silicate, magnesium silicate, and calcium phosphate may be used. Examples of the commercially available product of the fine particles include the R972 or NX90S (product name, both manufactured by Nippon Aerosil Co., Ltd.).

The fine particles function as a so-called matting agent, and the addition of the fine particles forms minute unevenness on the surface of the light absorption filter according to the embodiment of the present invention. Due to the unevenness, even in a case where the light absorption filters according to the embodiment of the present invention overlap with each other or the light absorption filter according to the embodiment of the present invention and other films overlap with each other, the films do not stick to each other and sliding properties are secured.

In a case where the light absorption filter according to the embodiment of the present invention contains a matting agent as fine particles, the effect of improving sliding properties and blocking properties is particularly large in the fine unevenness due to the protrusions in which fine particles protrude from the filter surface in a case where there are 10⁴/mm² or more of protrusions having a height of 30 nm or more.

It is preferable to apply the matting agent (fine particles) particularly onto the surface layer in order to improve the blocking properties and the sliding properties. Examples of the method of applying fine particles onto the surface layer include methods such as multilayer casting and coating.

The content of the matting agent in the light absorption filter according to the embodiment of the present invention is appropriately adjusted depending on the intended purpose.

However, in a case where a gas barrier layer described later is provided in the light absorption filter according to the embodiment of the present invention, the above-described matting agent fine particles are preferably applied onto the surface of the light absorption filter in contact with the gas barrier layer as long as the effect of the present invention is not impaired.

### (Leveling Agent)

A leveling agent (surfactant) can be appropriately mixed with the light absorption filter according to the embodiment of the present invention. As the leveling agent, a commonly used compound can be used, and a fluorine-containing surfactant is particularly preferable. Specific examples thereof include the compounds described in paragraphs [0028] to [0056] of JP2001-330725A. In addition, as the commercially available product, MEGAFACE F (product name) series manufactured by DIC Corporation can also be used.

The content of the leveling agent in the light absorption filter according to the embodiment of the present invention is appropriately adjusted depending on the intended purpose.

The light absorption filter according to the embodiment of the present invention may contain, in addition to the above components, a low-molecular plasticizer, an oligomer-based plasticizer, a retardation modifier, a deterioration preventing agent, a peeling accelerating agent, an infrared absorbing agent, an antioxidant, a filler, a compatibilizer.

In addition, the light absorption filter according to the embodiment of the present invention may contain the reaction accelerating agent or the reaction retarder described in paragraphs [0020] and [0021] of JP1997-286979A (JP-H09-286979A).

### <Manufacturing Method for Light Absorption Filter>

The light absorption filter according to the embodiment of the present invention can be produced by a solution film-forming method, a melt extrusion method, or a method of forming a coating layer on a base material film (support film) (coating method) according to any method, according to a conventional method, and stretching can also be appropriately combined. The light absorption filter according to the embodiment of the present invention is preferably produced by a coating method.

For the solution film-forming method and melt extrusion method described above, the descriptions regarding the solution film-forming method and the melt extrusion method in [0189] to [0203] of WO02021/132674A can be applied as they are.

### (Coating Method)

In the coating method, a solution of a material of the light absorption filter is applied to a support film to form a coating layer. A release agent or the like may be appropriately applied to the surface of the support film in advance in order to control the adhesiveness to the coating layer. The coating layer can be used by peeling off the support film after being laminated with another member while interposing an adhesive layer in a later step. Any adhesive can be appropriately used as the adhesive constituting the adhesive layer. The whole support film can be appropriately stretched in a state where a solution of the material of the light absorption filter is applied on the support film or in a state where a coating layer is laminated on the support film.

A solvent that is used for the solution of the material of the light absorption filter can be appropriately selected from the viewpoints that the material of the light absorption filter can be dissolved or dispersed, that a uniform surface shape can be easily achieved during the coating step and drying step, liquid storability can be secured, and that a proper saturated vapor pressure is provided.

### —Addition of Dye (Coloring Agent) and Radical Generator—

The timing of adding the dye and the radical generator to the material of the light absorption filter is not particularly limited as long as they are added at the time of film formation. For example, the dye may be added at the time of synthesizing the matrix polymer or may be mixed with the material of the light absorption filter at the time of preparing the coating liquid for the material of the light absorption filter. It is noted that in a case where the radical generator includes a combination of the compound A and the compound B, and the compound A is bonded to the polymer that constitutes the resin, the compound A is added at the time of adding the polymer that constitutes the resin.

### —Support Film—

The support film that is used for forming the light absorption filter according to the embodiment of the present invention by a coating method or the like preferably has a film thickness of 5 to 100 μm, more preferably 10 to 75 μm, and still more preferably 15 to 55 μm. In a case where the film thickness is equal to or larger than the above-described preferred lower limit value, sufficient mechanical strength can be easily secured, and failures such as curling, wrinkling, and buckling are less likely to occur. In addition, in a case where the film thickness is equal to or smaller than the above-described preferred upper limit value, in the storage of a multi-layer film of the support film and the light absorption filter according to the embodiment of the present invention, for example, in the form of a long roll, the surface pressure applied to the multi-layer film is easily adjusted to be in an appropriate range, and adhesion defect is less likely to occur.

The surface energy of the support film is not particularly limited, and by adjusting the relationship between the surface energy of the material of the light absorption filter according to the embodiment of the present invention or the coating solution and the surface energy of the surface of the support film on which the light absorption filter according to the embodiment of the present invention is to be formed, the adhesive force between the light absorption filter according to the embodiment of the present invention and the support film can be adjusted. In a case where the surface energy difference is reduced, the adhesive force tends to increase, and in a case where the surface energy difference is increased, the adhesive force tends to decrease, and thus the surface energy can be set appropriately.

The surface unevenness of the support film is not particularly limited, and depending on the relationship between the surface energy of the light absorption filter according to the embodiment of the present invention surface, the hardness, and the surface unevenness, and the surface energy and hardness of the surface of the support film opposite to the side on which the light absorption filter according to the embodiment of the present invention is formed, for example, in order to prevent adhesion defect in a case where the multi-layer film of the support film and the light absorption filter according to the embodiment of the present invention is stored in the form of a long roll, the surface unevenness of the support film can be adjusted. In a case where the surface unevenness is increased, adhesion defect tends to be suppressed, and in a case where the surface unevenness is reduced, the surface unevenness of the light absorption filter according to the embodiment of the present invention tends to be decreased and the haze of the light absorption filter according to the embodiment of the present invention tends to be small. Thus, the surface unevenness can be set appropriately.

For such a support film, any material and film can be appropriately used. Specific examples of the material include a polyester-based polymer (including a polyethylene terephthalate-based polymer), an olefin-based polymer, a cycloolefin-based polymer, a (meth)acrylic polymer, a cellulose-based polymer, and a polyamide-based polymer. In addition, a surface treatment can be appropriately carried out for the intended purpose of adjusting the surface properties of the support film. For example, a corona treatment, a room temperature plasma treatment, or a saponification treatment can be carried out to decrease the surface energy, and a silicone treatment, a fluorine treatment, an olefin treatment, or the like can be carried out to raise the surface energy.

### <Film Thickness of Light Absorption Filter According to Embodiment of Present Invention>

The film thickness of the light absorption filter according to the embodiment of the present invention is not particularly limited, and it is preferably 1 to 18 μm, more preferably 1 to 12 μm, and still more preferably 2 to 8 μm. In a case where the film thickness is equal to or smaller than the above-described preferred upper limit value, the decrease in the degree of polarization due to the fluorescence emitted by a dye (a coloring agent) can be suppressed by adding the dye to the thin film at a high concentration. In addition, the effect of the quencher is likely to be exhibited. On the other hand, in a case where the film thickness is equal to or larger than the above-described preferred lower limit value, it becomes easy to maintain the evenness of the in-plane absorbance.

In the present invention, the film thickness of 1 to 18 μm means that the thickness of the light absorption filter according to the embodiment of the present invention is within a range of 1 to 18 μm in a case of being measured at any portion. The same applies to the film thicknesses of 1 to 12 μm and 2 to 8 μm. The film thickness can be measured with an electronic micrometer manufactured by Anritsu Corporation.

### <Absorbance of Light Absorption Filter of According to Embodiment According to Embodiment of Present Invention>

In the light absorption filter according to the embodiment of the present invention, the absorbance at the maximal absorption wavelength at which the highest absorbance is exhibited at a wavelength of 400 to 700 nm (hereinafter, also simply referred to as “Ab (λₘₐₓ)”) is preferably 0.3 or more, more preferably 0.5 or more, and still more preferably 0.7 or more.

However, the absorbance of the light absorption filter according to the embodiment of the present invention can be adjusted by the kind, adding amount, or film thickness of the dye.

In the light absorption filter according to the embodiment of the present invention, a decolorization rate upon ultraviolet irradiation at 25° C. is preferably 85% or more, more preferably 87% or more, and still more preferably 90% or more. The upper limit value thereof is not particularly limited, and it is preferably 100%.

The decolorization rate is calculated according to the following expression using the values of Ab (λₘₐₓ) before and after the ultraviolet irradiation test.

$$Decolorization rate ( \% ) = 100 - ( Ab ( {λ}_{max} ) after ultraviolet irradiation / Ab ( {λ}_{max} ) before ultraviolet irradiation ) \times 100 \%$$

Here, in the ultraviolet irradiation test, an ultra-high pressure mercury lamp (manufactured by HOYA Corporation, product name: UL750) is used under atmospheric pressure (101.33 kPa) to irradiate the light absorption filter with ultraviolet rays at an illuminance of 100 mW/cm² and an irradiation amount of 750 to 1,500 mJ/cm² at room temperature (25° C.).

The absorbance, the ultraviolet irradiation test, and the decolorization rate can be measured and calculated according to the methods described in Examples.

In addition, it is preferable that the light absorption filter according to the embodiment of the present invention hardly causes absorption (secondary absorption) derived from a new coloration structure associated with the decomposition of the coloring agent.

For example, the presence or absence of the absorption derived from the new coloration structure associated with the decomposition of the coloring agent can be checked based on the ratio of the absorbance at a specific wavelength to the above Ab (λₘₐₓ). As the specific wavelength, a wavelength at which the coloring agent before ultraviolet irradiation seldom exhibits absorption but new absorption due to the decomposition of the coloring agent is observed is selected.

As a specific example, as described in Examples described later, the presence or absence of the absorption derived from the new coloration structure associated with the decomposition of the coloring agent can be checked based on the ratio of the absorbance at a specific wavelength to the above Ab (λₘₐₓ). As the specific wavelength, a wavelength at which the coloring agent before ultraviolet irradiation seldom exhibits absorption but new absorption due to the decomposition of the coloring agent is observed is selected.

As a specific example, as described in Examples described later, the presence or absence of the absorption derived from a new coloration structure associated with the decomposition of the coloring agent can be checked based on the ratio of the absorbance at a wavelength of 450 nm to the above Ab (λₘₐₓ) (hereinafter, also simply referred to as “Ab (450)”). That is, it is meant that the smaller the value obtained by subtracting the ratio of the following (I) from the ratio of the following (II), the less frequently the absorption derived from the new coloration structure associated with the decomposition of the coloring agent occurs. This value is preferably less than 8.5%, more preferably 7.0% or less, still more preferably 5.0% or less, particularly preferably 3.0% or less, among which 1.0% or less is preferable. The lower limit value thereof is not particularly limited; however, it is practically −10% or more and preferably −6% or more from the viewpoint of making valid the evaluation related to the presence or absence of the secondary absorption associated with the decomposition of the coloring agent.

Ab (450) before ultraviolet irradiation/Ab (λₘₐₓ)×100% before ultraviolet irradiation (I)

Ab (450) after ultraviolet irradiation/Ab (λₘₐₓ) before ultraviolet irradiation×100% (II)

The checking of the presence or absence of the absorption derived from the new coloration structure associated with the decomposition of the coloring agent can be carried out by the measurement and the calculation according to the method described in Examples.

Further, as described in Examples described later, the value of the absorbance at a wavelength of 650 nm (hereinafter, also simply referred to as “Ab (650)”) is used instead of the absorbance at a wavelength of 450 nm to obtain a value obtained by subtracting the ratio of the following (III) from the ratio of the following (IV), whereby the evaluation can be carried out. The preferred range of the value obtained by subtracting the ratio of the following (III) from the ratio of the following (IV) has the same meaning as the value obtained by subtracting the ratio of the above expression (I) from the ratio of the above expression (II).

Ab (650) before ultraviolet irradiation/Ab (λₘₐₓ) before ultraviolet irradiation×100% (III)

Ab (650) after ultraviolet irradiation/Ab (λₘₐₓ) before ultraviolet irradiation×100% (IV)

Here, the description of the ultraviolet irradiation test regarding the above quenching rate can be preferably applied to the ultraviolet irradiation test.

The checking of the presence or absence of the absorption derived from the new coloration structure associated with the decomposition of the coloring agent can be carried out by the measurement and the calculation according to the method described in Examples.

The light absorption filter according to the embodiment of the present invention can exhibit high decolorizing properties in a case where both the above-described decolorization rate and the above-described value for checking the presence or absence of the absorption derived from the new coloration structure associated with the decomposition of the coloring agent satisfy a preferred range.

The light absorptive portion having a light absorption effect in the optical filter according to the embodiment of the present invention preferably satisfies the above description of Ab (λₘₐₓ) related to the light absorption filter according to the embodiment of the present invention.

### <Treatment of Light Absorption Filter According to Embodiment of Present Invention>

The light absorption filter according to the embodiment of the present invention may be subjected to a hydrophilic treatment by any of glow discharge treatment, corona discharge treatment, or alkali saponification treatment, and a corona discharge treatment is preferably used. It is also preferable to apply the method disclosed in JP1994-94915A (JP-H6-94915A) and JP1994-118232A (JP-H6-118232A).

As necessary, the obtained film may be subjected to a heat treatment step, a superheated steam contact step, an organic solvent contact step, or the like. In addition, a surface treatment may be appropriately carried out.

In addition, as a pressure-sensitive adhesive layer, a layer consisting of a pressure-sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description regarding the pressure-sensitive adhesive layer in the OLED display device described later can be applied.

### <Gas Barrier Layer>

The light absorption filter according to the embodiment of the present invention may have a gas barrier layer on at least one surface. In a case where the light absorption filter according to the embodiment of the present invention has a gas barrier layer, the light absorption filter according to the embodiment of the present invention can be made to be a light absorption filter that achieves both high decolorizing properties and excellent light resistance and can be suitably used in the production of an optical filter described later.

The material that forms the gas barrier layer is not particularly limited, and examples thereof include an organic material (preferably a crystalline resin) such as polyvinyl alcohol or polyvinylidene chloride, an organic-inorganic hybrid material such as a sol-gel material, and an inorganic material such as SiO₂, SiOₓ, or SiON, SiNₓ, or Al₂O₃. The gas barrier layer may be a single layer or a multi-layer. In the case of a multi-layer, examples thereof include configurations such as an inorganic dielectric multi-layer film and a multi-layer film obtained by alternately laminating organic materials and inorganic materials.

In a case where the light absorption filter according to the embodiment of the present invention includes the gas barrier layer at least on a surface that comes into contact with air in a case where the light absorption filter according to the embodiment of the present invention is used, it is possible to suppress a decrease in the absorption intensity of the dye in the light absorption filter according to the embodiment of the present invention. As long as the gas barrier layer is provided at an interface of the light absorption filter according to the embodiment of the present invention in contact with air, the gas barrier layer may be provided on only one surface of the light absorption filter according to the embodiment of the present invention, or may be provided on both surfaces.

Among the above, in a case of a configuration in which the gas barrier layer contains a crystalline resin, the gas barrier layer contains a crystalline resin, and it is preferable that the thickness of the layer is 0.1 μm to 10 μm and the oxygen permeability of the layer is 60 cc/m²·day·atm or less.

In the gas barrier layer, the “crystalline resin” is a resin having a melting point that undergoes a phase transition from a crystal to a liquid in a case where the temperature is raised, and it can impart gas barrier properties related to oxygen gas to the gas barrier layer.

“The gas barrier layer containing a crystalline resin, where the thickness of the layer is 0.1 μm to 10 μm and the oxygen permeability of the layer is 60 cc/m²·day·atm or less” described above is the same as the gas barrier layers described in [0180] to [0184] of WO02022/149510A, and the descriptions regarding the gas barrier layer which is described in [0180] to [0184] of WO02022/149510A, can be applied as they are.

### <Manufacturing Method for Gas Barrier Layer>

The method of forming the gas barrier layer is not particularly limited, and examples thereof include a producing method according to a conventional method according to a casting method such as spin coating or slit coating, for example, in a case of an organic material. In addition, examples thereof can include a method of bonding a commercially available resin gas barrier film or a resin gas barrier film produced in advance to the light absorption filter according to the embodiment of the present invention. In addition, examples thereof include a plasma enhanced chemical vapor deposition (PECVD) method, a sputtering method and a vapor deposition method in a case of an inorganic material.

In a case where the above-described gas barrier layer is provided in the light absorption filter according to the embodiment of the present invention, for example, a method of directly producing the above-described gas barrier layer on the light absorption filter according to the embodiment of the present invention produced according to the above-described production method is included. In this case, it is also preferable to apply a corona treatment to the surface of the light absorption filter according to the embodiment of the present invention to which the gas barrier layer is provided.

In addition, in a case where the above-described optional optical functional film is provided, it is also preferable to carry out bonding while interposing a pressure-sensitive adhesive layer. For example, it is also preferable that a gas barrier layer is provided on the light absorption filter according to the embodiment of the present invention and then bonded to an optical functional film while interposing a pressure-sensitive adhesive layer.

### <Optical Functional Film>

The light absorption filter according to the embodiment of the present invention may appropriately have the gas barrier layer or any optical functional film as long as the effect of the present invention is not impaired.

The optional optical functional film is not particularly limited in terms of any of the optical properties and the materials, and a film containing (or containing as a main component) at least any of a cellulose ester resin, an acrylic resin, a cyclic olefin resin, or a polyethylene terephthalate resin can be preferably used. It is noted that an optically isotropic film or an optically anisotropic phase difference film may be used.

For the above optional optical functional films, for example, Fujitac TD80UL (manufactured by FUJIFILM Corporation) or the like can be used as a film containing a cellulose ester resin.

Regarding the optional optical functional film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical functional film containing a (meth)acrylic resin having a glutaric anhydride unit described in JP2009-139754A can be used. In addition, regarding the optional optical functional films, as those containing a cyclic olefin resin, cyclic olefin-based resin film described in paragraphs [0029] and subsequent paragraphs of JP2009-237376A, and cyclic olefin resin film containing an additive reducing Rth described in JP4881827B, and JP2008-063536A can be used.

### [Optical Filter]

The optical filter according to the embodiment of the present invention is obtained by subjecting the light absorption filter according to the embodiment of the present invention to mask exposure by ultraviolet irradiation.

The optical filter according to the embodiment of the present invention has a light absorptive portion having a light absorption effect and a portion in which light absorption properties have been eliminated (a light absorption property-eliminated portion) in response to a mask exposure pattern (hereinafter, also referred to as a “mask pattern”).

That is, in a case where the light absorption filter according to the embodiment of the present invention is subjected to mask exposure by ultraviolet irradiation, the masked portion of the light absorption filter according to the embodiment of the present invention is not exposed and present as a light absorptive portion having a light absorption effect, whereas the unmasked portion is exposed and becomes a light absorption property-eliminated portion.

The light absorptive portion can exhibit a desired absorbance.

In addition, the light absorption property-eliminated portion can exhibit optical characteristics close to colorlessness since the light absorption filter according to the embodiment of the present invention exhibits an excellent decolorization rate and secondary absorption seldom occurs in association with the dye decomposition.

### <Manufacturing Method for Optical Filter>

The optical filter according to the embodiment of the present invention can be obtained by irradiating the light absorption filter according to the embodiment of the present invention with an ultraviolet ray to carry out mask exposure.

The mask pattern can be appropriately adjusted so that the optical filter according to the embodiment of the present invention having a desired pattern consisting of a light absorptive portion and a light absorption property-eliminated portion can be obtained.

The conditions of ultraviolet irradiation can be appropriately adjusted so that the optical filter according to the embodiment of the present invention having a light absorption property-eliminated portion can be obtained. For example, the ultraviolet irradiation can be carried out under atmospheric pressure (101.33 kPa) regarding the pressure condition and can be carried out under a mild temperature condition regarding the temperature condition without carrying out heating at room temperature (10° C. to 30° C.) or the like, the lamp output can be set to 10 to 320 W/cm, and an air-cooled metal halide lamp, a mercury lamp such as an ultra-high pressure mercury lamp, or the like can be used as a lamp to be used. In addition, the irradiation amount can be set to 200 to 2,000 mJ/cm².

The optical filter according to the embodiment of the present invention may have an optical functional film described in the light absorption filter according to the embodiment of the present invention.

In addition, the optical filter according to the embodiment of the present invention may have a layer containing an ultraviolet absorbing agent. As the ultraviolet absorbing agent, a commonly used compound can be used without particular limitation, and examples thereof include an ultraviolet absorbing agent in the ultraviolet absorbing layer described later. The resin constituting the layer containing the ultraviolet absorbing agent is also not particularly limited, and examples thereof include a resin in the ultraviolet absorbing layer described later.

The content of the ultraviolet absorbing agent in the layer containing the ultraviolet absorbing agent is appropriately adjusted according to the intended purpose.

### [OLED Display Device]

The organic electroluminescent display device according to the embodiment of the present invention (referred to as an organic electroluminescence (EL) display device or an organic light emitting diode (OLED) display device, and abbreviated as an OLED display device in the present invention) includes the optical filter according to the embodiment of the present invention.

As another configuration of the OLED display device according to the embodiment of the present invention, the configuration of the generally used OLED display device can be used without particular limitation, as long as the optical filter according to the embodiment of the present invention is included. The configuration example of the OLED display device according to the embodiment of the present invention is not particularly limited, and examples thereof include a display device including glass, a layer containing a thin film transistor (TFT), an OLED display element, a barrier film, a color filter, glass, a pressure-sensitive adhesive layer, the optical filter according to the embodiment of the present invention, and a surface film, in order from the opposite side to external light.

The OLED display element has a configuration in which an anode electrode, a light emitting layer, and a cathode electrode are laminated in this order. In addition to the light emitting layer, a hole injection layer, a hole transport layer, an electron transport layer, an electron injection layer, and the like are included between the anode electrode and the cathode electrode. In addition, for example, the description in JP2014-132522A can also be referenced.

In addition, as the color filter, in addition to a typical color filter, a color filter in which quantum dots are laminated can also be used.

A resin film can be used instead of the above glass.

### <Pressure-Sensitive Adhesive Layer>

In the OLED display device according to the embodiment of the present invention, a surface of the optical filter according to the embodiment of the present invention on the external light side may be bonded to an optical functional film having an antireflection layer or the like, or a polarizing plate including a polarizer and a polarizing plate protective film while interposing a pressure-sensitive adhesive layer. In addition, it is preferable that a surface of the optical filter according to the embodiment of the present invention, which is positioned opposite to the side of the external light, is bonded to the glass (the base material) with a pressure-sensitive adhesive layer being interposed.

For the pressure-sensitive adhesive layer, the descriptions related to the pressure-sensitive adhesive layer and the forming method in the OLED display device, which are described in [0239] to [0290] of WO02021/132674A, can be applied as they are.

It is noted that the pressure-sensitive adhesive composition described in WO02021/132674A preferably contains the above-described ultraviolet absorbing agent from the viewpoint of the light resistance of the optical filter.

### <Base Material>

In the OLED display device according to the embodiment of the present invention, a surface of the optical filter according to the embodiment of the present invention, which is positioned on the external light side, may be bonded to an optical functional film with an adhesive layer being interposed. In addition, it is preferable that a surface of the optical filter according to the embodiment of the present invention, which is positioned opposite to the side of the external light, is bonded to the glass (the base material) with a pressure-sensitive adhesive layer being interposed.

The method of forming the adhesive layer is not particularly limited, and for example, a method of applying the pressure-sensitive adhesive composition to the light absorption filter or optical filter according to the embodiment of the present invention by a usual means such as a bar coater, drying, and curing the pressure-sensitive adhesive composition; a method of applying the pressure-sensitive adhesive composition first to the surface of a peelable base material, and drying the composition, and then transferring the pressure-sensitive adhesive layer using the peelable base material to the light absorption filter according to the embodiment of the present invention and then aging and curing the composition is used.

The peelable base material is not particularly limited, and a predetermined peelable base material can be used. Examples thereof include the support film in the manufacturing method for the light absorption filter according to the embodiment of the present invention described above.

In addition, the conditions of application, drying, aging, and curing can be appropriately adjusted based on a conventional method.

### [Inorganic Electroluminescent Display Device]

An inorganic electroluminescent display device (referred to as an inorganic EL (electroluminescence) display device and also simply referred to as an inorganic EL display device in the present invention) according to an embodiment of the present invention includes the optical filter according to the embodiment of the present invention.

As another configuration of the inorganic EL display device according to the embodiment of the present invention, a configuration of a generally used inorganic EL display device can be used without particular limitation as long as the optical filter according to the embodiment of the present invention is included. For example, the descriptions regarding the inorganic EL element and the inorganic electroluminescent display device, which are described in JP2005-338640A can be preferably applied.

### [Liquid Crystal Display Device]

The liquid crystal display device according to the embodiment of the present invention includes the optical filter according to the embodiment of the present invention.

The optical filter according to the embodiment of the present invention may be used as at least one of a polarizing plate-protective film or a pressure-sensitive adhesive layer as described later, or it may be included in a backlight unit that is used in the liquid crystal display device.

It is preferable that the liquid crystal display device includes the optical filter according to the embodiment of the present invention, a polarizing plate including a polarizer and a polarizing plate-protective film, a pressure-sensitive adhesive layer, and a liquid crystal cell, where it is preferable that the polarizing plate is bonded to the liquid crystal cell with a pressure-sensitive adhesive layer being interposed. In the liquid crystal display device, the optical filter according to the embodiment of the present invention may also serve as the polarizing plate-protective film or the pressure-sensitive adhesive layer. That is, the liquid crystal display device is divided into a case where the liquid crystal display device includes a polarizing plate including a polarizer and the optical filter (polarizing plate-protective film) according to the embodiment of the present invention, a pressure-sensitive adhesive layer, and a liquid crystal cell, and a case where the liquid crystal display device includes a polarizing plate including a polarizer and a polarizing plate-protective film, the optical filter (pressure-sensitive adhesive layer) according to the embodiment of the present invention, and a liquid crystal cell.

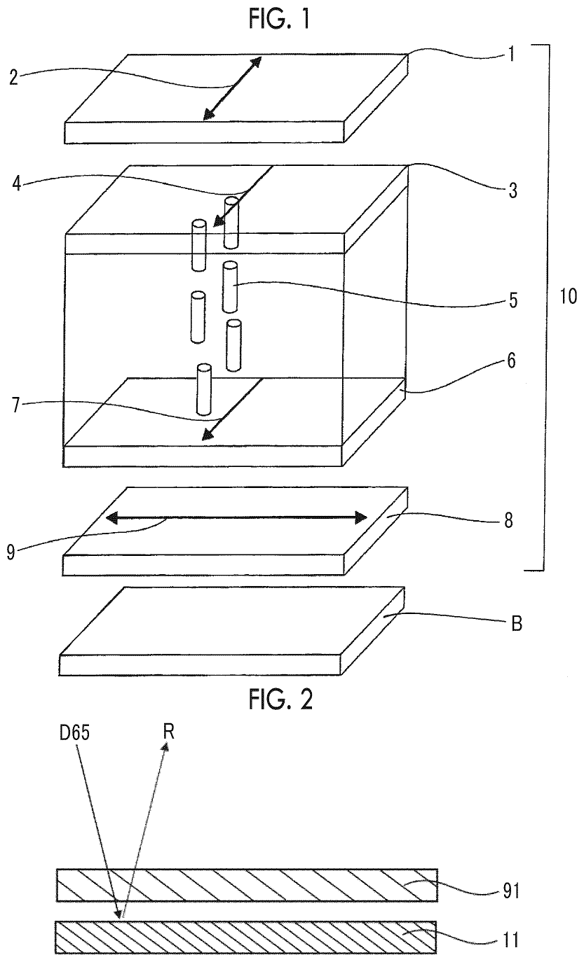

FIG. 1 is a schematic view illustrating an example of the liquid crystal display device according to the embodiment of the present invention. In FIG. 1, a liquid crystal display device 10 consists of a liquid crystal cell having a liquid crystal layer 5 and having a liquid crystal cell upper electrode substrate 3 and a liquid crystal cell lower electrode substrate 6, which are respectively disposed above and below the liquid crystal layer 5, and an upper polarizing plate 1 and a lower polarizing plate 8, which are respectively disposed on both sides of the liquid crystal cell. A color filter layer may be laminated on the upper electrode substrate 3 or the lower electrode substrate 6. On the rear surface of the liquid crystal display device 10, a backlight is disposed. As a light source of the backlight, those described in the above backlight unit can be used.

Each of the upper polarizing plate 1 and the lower polarizing plate 8 has a configuration in which each of them is laminated such that a polarizer is sandwiched between two polarizing plate protective films, and in the liquid crystal display device 10, at least one polarizing plate is preferably a polarizing plate including the optical filter according to the embodiment of the present invention.

In addition, in the liquid crystal display device 10, the liquid crystal cell may be bonded to the polarizing plates (the upper polarizing plate 1 and/or the lower polarizing plate 8) with a pressure-sensitive adhesive layer (not illustrated in the drawing) being interposed. In this case, the optical filter according to the embodiment of the present invention may also serve as the above-described pressure-sensitive adhesive layer.

The liquid crystal display device 10 includes an image direct vision-type liquid crystal display, an image projection-type liquid crystal display device, and a light modulation-type liquid crystal display device. The present invention is effective for an active matrix liquid crystal display device that uses a three-terminal or two-terminal semiconductor element such as a thin film transistor (TFT) or a metal insulator metal (MIM). Of course, it is also effective for a passive matrix liquid crystal display device represented by a super twisted nematic (STN) mode which is called as the time division driving.

In a case where the optical filter according to the embodiment of the present invention is included in the backlight unit, the polarizing plate of the liquid crystal display device may be a general polarizing plate (a polarizing plate that does not include the optical filter according to the embodiment of the present invention) or may be a polarizing plate that includes the optical filter according to the embodiment of the present invention. In addition, the pressure-sensitive adhesive layer may be a typical pressure-sensitive adhesive layer (not the optical filter according to the embodiment of the present invention) or may be a pressure-sensitive adhesive layer formed of the optical filter according to the embodiment of the present invention.

The in plane switching (IPS) mode liquid crystal display device described in paragraphs 0128 to 0136 of JP2010-102296A is preferable as the liquid crystal display device according to the embodiment of the present invention except that the optical filter according to the embodiment of the present invention is used.

### <Polarizing Plate>

The polarizing plate that is used in the present invention includes a polarizer and at least one polarizing plate-protective film.

The polarizing plate that is used in the present invention is preferably a polarizing plate having a polarizer and polarizing plate-protective films on both surfaces of the polarizer, and it is preferable that at least one surface of the polarizer includes the optical filter according to the embodiment of the present invention as the polarizing plate-protective film. The surface of the polarizer opposite to the surface having the optical filter according to the embodiment of the present invention (the polarizing plate-protective film according to the embodiment of the present invention) may have a general polarizing plate-protective film.

The film thickness of the polarizing plate protective film is preferably 5 to 120 μm and more preferably 10 to 100 μm. A thinner film is preferable since in a case of being incorporated in the liquid crystal display device, the display unevenness after elapse of time in high temperature and high humidity is less likely to occur. On the other hand, in a case where the film is too thin, it is difficult to transport the film stably at the time of producing the film and producing the polarizing plate. In a case where the optical filter according to the embodiment of the present invention also serves as the polarizing plate-protective film, it is preferable that the thickness of the optical filter satisfies the above-described range.

For the polarizing plate that is used in the present invention, the descriptions related to the performance, the shape, the configuration, the polarizer, the method of laminating the polarizer and the polarizing plate-protective film, the functionalization of the polarizing plate, and the like regarding the polarizing plate described in [0299] to [0309] of WO2021/132674A can be applied as they are.

### <Pressure-Sensitive Adhesive Layer>

In the liquid crystal display device according to the embodiment of the present invention, the polarizing plate is preferably bonded to the liquid crystal cell with a pressure-sensitive adhesive layer being interposed. The optical filter according to the embodiment of the present invention may also serve as the pressure-sensitive adhesive layer. In a case where the optical filter according to the embodiment of the present invention does not serve as the pressure-sensitive adhesive layer, a typical pressure-sensitive adhesive layer can be used as the pressure-sensitive adhesive layer.

The pressure-sensitive adhesive layer is not particularly limited as long as the polarizing plate can be bonded to the liquid crystal cell, and for example, an acrylic type, a urethane type, polyisobutylene, or the like is preferable.

In a case where the optical filter according to the embodiment of the present invention also serves as an adhesive layer, the adhesive layer includes the dye and the base polymer, and further contains a crosslinking agent, a coupling agent, or the like to impart adhesiveness.

In a case where the optical filter according to the embodiment of the present invention also serves as a pressure-sensitive adhesive layer, the pressure-sensitive adhesive layer preferably contains 90% to 100% by mass of the base polymer, and preferably contains 95% to 100% by mass of the base polymer. The content of the coloring agent is as described above.

The thickness of the pressure-sensitive adhesive layer is not particularly limited; however, it is preferably 1 to 50 μm and more preferably 3 to 30 μm.

### <Liquid Crystal Cell>

The liquid crystal cell is not particularly limited, and a typical liquid crystal cell can be used.

### <Ultraviolet Absorbing Layer>

The organic electroluminescent display device, inorganic electroluminescent display device, or liquid crystal display device including the optical filter according to the embodiment of the present invention preferably has a layer (hereinafter, also referred to as an “ultraviolet absorbing layer”) that inhibits the light absorption (the ultraviolet absorption) of the compound that generates a radical upon ultraviolet irradiation, on the viewer side with respect to the optical filter according to the embodiment of the present invention. In a case where the ultraviolet absorbing layer is provided, it is possible to prevent the fading of the optical filter according to the embodiment of the present invention due to external light.

Hereinafter, the ultraviolet absorbing layer that is used in the present invention will be described.

### (Ultraviolet Absorbing Agent)

The ultraviolet absorbing layer usually contains a resin and an ultraviolet absorbing agent.

Specific examples of the ultraviolet absorbing agent preferably used in the present invention include a hindered phenol-based compound, a benzophenone-based compound such as a hydroxybenzophenone-based compound, a benzotriazole-based compound, a salicylic acid ester-based compound, a cyanoacrylate-based compound, and a nickel complex salt-based compound.

Examples of the hindered phenol-based compound include 2,6-di-tert-butyl-p-cresol, pentaerythrityl-tetrakis[3-(3,5-di-tert-butyl-4-hydroxyphenyl)propionate], N,N′-hexamethylene bis(3,5-di-tert-butyl-4-hydroxy-hydrocinnamide), 1,3,5-trimethyl-2,4,6-tris(3,5-di-tert-butyl-4-hydroxybenzyl)benzene, and tris-(3,5-di-tert-butyl-4-hydroxybenzyl)-isocyanurate.

Examples of the benzotriazole-based compound include 2-(2′-hydroxy-5′-methylphenyl) benzotriazole, 2,2-methylene bis(4-(1,1,3,3-tetramethylbutyl)-6-(2H-benzotriazole-2-yl) phenol), 2,4-bis(n-octylthio)-6-(4-hydroxy-3,5-di-tert-butylanilino)-1,3,5-triazine, triethyleneglycol-bis[3-(3-tert-butyl-5-methyl-4-hydroxyphenyl)propionate], N,N′-hexamethylene bis(3,5-di-tert-butyl-4-hydroxy-hydrocinnamide), 1,3,5-trimethyl-2,4,6-tris(3,5-di-tert-butyl-4-hydroxybenzyl)benzene, 2-(2′-hydroxy-3′, 5′-Di-tert-butylphenyl)-5-chlorbenzotriazole, (2-(2′-hydroxy-3′, 5′-di-tert-amylphenyl)-5-chlorbenzotriazole, 2,6-di-tert-butyl-p-cresol, and pentaerythrityl-tetrakis[3-(3,5-di-tert-butyl-4-hydroxyphenyl)propionate].

The adding amount of this ultraviolet absorbing agent is preferably 0.1 parts by mass to 30.0 parts by mass with respect to 100 parts by mass of the resin.

In addition, a compound (1) represented by Formula (1) is particularly preferably used as an ultraviolet absorbing agent from the viewpoint of further improving the light resistance of the optical filter according to the embodiment of the present invention.

### <<Compound Represented by Formula (1) (Compound (1))>>

A resin composition for forming the ultraviolet absorbing layer preferably contains a compound represented by Formula (1) (hereinafter, also referred to as a compound (1)).

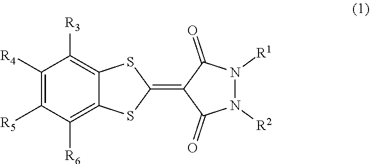

In Formula (1), R¹ and R² each independently represent an alkyl group, an aryl group, or a heterocyclic group, where
R³ and R⁶ each independently represent an alkoxy group, an acyloxy group, a carbamoyloxy group, or an alkoxycarbonyloxy group,
R⁴ represents an alkyl group, an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group, and
R⁵ represents a hydrogen atom, an alkyl group, an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group.

R¹ and R² may be bonded to each other to form a ring, R³ and R⁴ may be bonded to each other to form a ring, R⁴ and R⁵ may be bonded to each other to form a ring, and R⁵ and R⁶ may be bonded to each other to form a ring. These rings to be formed may be aromatic or may not exhibit aromaticity.

However, in a case where R³ and R⁶ each independently represent an acyloxy group or a carbamoyloxy group, at least one of R⁴ or R⁵ represents an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group.

In Formula (1), R¹ and R² each independently represent an alkyl group, an aryl group, or a heterocyclic group, where an alkyl group or an aryl group is preferable. From the viewpoint of light resistance, it is preferable that R¹ and R² are each independently an alkyl group. In addition, from the viewpoint of the absorbability of ultraviolet rays in the vicinity of a wavelength of 400 nm, it is preferable that R¹ and R² are each independently an aryl group.

The alkyl group represented by R¹ and R² preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl group may be linear, branched, or cyclic and preferably linear or branched. The alkyl group may have a substituent. Examples of the substituent include the groups described regarding the substituent T described later, and preferred examples thereof include a halogen atom, an alkoxy group, an alkenyl group, and an aryl group.

The aryl group represented by R¹ and R² preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The above-described aryl group is preferably a phenyl group or a naphthyl group, and more preferably a phenyl group. The aryl group may have a substituent. Examples of the substituent include the groups described regarding the substituent T described later, and preferred examples thereof include an alkoxy group.

It is preferable that the heterocyclic ring in the heterocyclic group represented by R¹ and R² includes a 5- or 6-membered saturated or unsaturated heterocyclic ring. The heterocyclic ring may be fused with an aliphatic ring, an aromatic ring, or another heterocyclic ring. Examples of the heteroatom constituting the ring of the heterocyclic ring include B, N, O, S, Se, and Te, and the heteroatom is preferably at least one of N, O, or S. It is preferable that the carbon atom that constitutes the ring has a free valence (monovalent) (the heterocyclic group is bonded at the carbon atom). The heterocyclic group preferably has 1 to 40 carbon atoms, more preferably has 1 to 30, and still more preferably has 1 to 20 carbon atoms. Examples of the saturated heterocyclic ring in the heterocyclic group include a pyrrolidine ring, a morpholine ring, a 2-bora-1,3-dioxolane ring, and a 1,3-thiazolidine ring. Examples of the unsaturated heterocyclic ring in the heterocyclic group include an imidazole ring, a thiazole ring, a benzothiazole ring, a benzoxazole ring, a benzotriazole ring, a benzoselenazole ring, a pyridine ring, a pyrimidine ring, and a quinoline ring. The heterocyclic group may have a substituent. Examples of the substituent include groups described in the section of the substituent T described below.

R¹ and R² may be bonded to each other to form a ring. The ring formed by bonding R¹ and R² to each other is preferably a 5-membered or 6-membered ring, which preferably does not exhibit aromaticity. The ring formed by bonding R¹ and R² to each other may have a substituent. Examples of the substituent include groups described in the section of the substituent T described below.

In Formula (1), R³ and R⁶ each independently represent an alkoxy group, an acyloxy group, a carbamoyloxy group, or an alkoxycarbonyloxy group and are preferably an alkoxy group or an acyloxy group. Due to the reason that it is easier to enhance the absorbability of ultraviolet rays in the vicinity of 400 nm while suppressing coloration, it is still more preferable that at least one of R³ or R⁶ is an alkoxy group. From the studies by the inventors of the present invention, it was found that as the substituent on the benzene ring of benzodithiol is a group that exhibits a higher electron donating ability (electron donating property), the maximal absorption wavelength of the compound is more easily shifted to the longer wavelength side. Since the alkoxy group is a substituent having a higher electron donating ability, it is presumed that the maximal absorption wavelength of the compound can be shifted to a longer wavelength side. It is particularly preferable that both R³ and R⁶ represent an alkoxy group.

The alkoxy group represented by R³ and R⁶ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkoxy group may be linear or branched. The alkoxy group may have a substituent. Examples of the substituent include groups described in the section of the substituent T described below.

The alkoxy group represented by R³ and R⁶ preferably has 2 to 30 carbon atoms, more preferably has 2 to 20 carbon atoms, still more preferably has 2 to 15 carbon atoms, and particularly preferably has 2 to 10 carbon atoms. The acyloxy group may have a substituent. Examples of the substituent include groups described in the section of the substituent T described below.

The carbamoyloxy group represented by R³ and R⁶ preferably has 2 to 30 carbon atoms, more preferably has 2 to 20 carbon atoms, still more preferably has 2 to 15 carbon atoms, particularly preferably has 2 to 10 carbon atoms, and most preferably has 2 to 8 carbon atoms. The carbamoyloxy group may be linear or branched. The carbamoyloxy group may have a substituent. Examples of the substituent include groups described in the section of the substituent T described below.

The alkoxycarbonyloxy group represented by R³ and R⁶ preferably has 2 to 30 carbon atoms, more preferably has 2 to 20 carbon atoms, still more preferably has 2 to 15 carbon atoms, particularly preferably has 2 to 10 carbon atoms, and most preferably has 2 to 8 carbon atoms. The alkoxycarbonyloxy group may be linear or branched. The alkoxycarbonyloxy group may have a substituent. Examples of the substituent include groups described in the section of the substituent T described below.

In Formula (1), R⁴ represents an alkyl group, an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group, and R⁵ represents a hydrogen atom, an alkyl group, an aryl group, an alkoxy group, an aryloxy group, an acyloxy group, an alkylamino group, an anilino group, an acylamino group, an alkylsulfonylamino group, an arylsulfonylamino group, an alkylthio group, or an arylthio group.

The alkyl group represented by R⁴ and R⁵ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl group may be linear, branched, or cyclic and preferably linear or branched. The alkyl group may have a substituent. Examples of the substituent include the groups described regarding the substituent T described later, and preferred examples thereof include an alkenyl group.

The aryl group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The above-described aryl group is preferably a phenyl group or a naphthyl group, and more preferably a phenyl group. The aryl group may have a substituent. Examples of the substituent include groups described in the section of the substituent T described below.

The alkoxy group represented by R⁴ and R⁵ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkoxy group may be linear or branched. The alkoxy group may have a substituent. Examples of the substituent include groups described in the section of the substituent T described below.

The aryloxy group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The aryloxy group may have a substituent. Examples of the substituent include groups described in the section of the substituent T described below.

The alkoxy group represented by R⁴ and R⁵ preferably has 2 to 30 carbon atoms, more preferably has 2 to 20 carbon atoms, still more preferably has 2 to 15 carbon atoms, and particularly preferably has 2 to 10 carbon atoms. The acyloxy group may have a substituent. Examples of the substituent include groups described in the section of the substituent T described below.

The alkylamino group represented by R⁴ and R⁵ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl moiety in the alkylamino group may be linear or branched. The alkylamino group may have a substituent. Examples of the substituent include groups described in the section of the substituent T described below.

The anilino group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The anilino group may have a substituent. Examples of the substituent include the groups described regarding the substituent T described later, and preferred examples thereof include an alkyl group.

The acylamino group represented by R⁴ and R⁵ preferably has 2 to 30 carbon atoms, more preferably has 2 to 20 carbon atoms, still more preferably has 2 to 15 carbon atoms, and particularly preferably has 2 to 10 carbon atoms. The acylamino group may have a substituent. Examples of the substituent include groups described in the section of the substituent T described below.

The alkylsulfonylamino group represented by R⁴ and R⁵ preferably has 2 to 30 carbon atoms, more preferably has 2 to 20 carbon atoms, still more preferably has 2 to 15 carbon atoms, and particularly preferably has 2 to 10 carbon atoms. The alkylsulfonylamino group may have a substituent. Examples of the substituent include groups described in the section of the substituent T described below.

The arylsulfonylamino group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The arylsulfonylamino group may have a substituent. Examples of the substituent include groups described in the section of the substituent T described below.

The alkylthio group represented by R⁴ and R⁵ preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkylthio group may be linear or branched. The alkylthio group may have a substituent. Examples of the substituent include groups described in the section of the substituent T described below.

The arylthio group represented by R⁴ and R⁵ preferably has 6 to 40 carbon atoms, more preferably has 6 to 30 carbon atoms, still more preferably has 6 to 20 carbon atoms, particularly preferably has 6 to 15 carbon atoms, and most preferably has 6 to 12 carbon atoms. The arylthio group may have a substituent. Examples of the substituent include groups described in the section of the substituent T described below.

In Formula (1), R³ and R⁴ may be bonded to each other to form a ring, R⁴ and R⁵ may be bonded to each other to form a ring, and R⁵ and R⁶ may be bonded to each other to form a ring. It is preferable that the ring formed by bonding these groups to each other is a 5- or 6-membered ring. The ring formed by bonding these groups to each other may have a substituent. Examples of the substituent include groups described in the section of the substituent T described below.

Due to the reason that it is easier to enhance the absorbability of ultraviolet rays in the vicinity of 400 nm while suppressing coloration, it is preferable that R⁴ is an alkyl group, an aryl group, an alkoxy group, or an aryloxy group, and R⁵ is a hydrogen atom, an alkyl group, an aryl group, an alkoxy group, or an aryloxy group, and it is more preferable that R⁴ is an alkyl group or an alkoxy group, and R⁵ is a hydrogen atom, an alkyl group, or an alkoxy group.

In addition, from the viewpoint of ease of synthesis, it is preferable that R⁴ is an alkyl group, an aryl group, an alkoxy group, or an aryloxy group, and R⁵ is a hydrogen atom, and it is more preferable that R⁴ is an alkyl group or an alkoxy group, and R⁵ is a hydrogen atom.

In addition, from the viewpoint of lengthening the absorption spectrum, it is preferable that R⁴ and R⁵ are each independently an alkyl group, an aryl group, an alkoxy group, or an aryloxy group, where an alkyl group or an alkoxy group is more preferable, and it is still more preferable that both R⁴ and R⁵ are an alkyl group, or both R⁴ and R⁵ are an alkoxy group.

In addition, it is preferable that R⁴ and R⁵ are bonded to each other to form a ring.

It is preferable that the compound represented by Formula (1) (the compound (1)) is a compound represented by Formula (1a).

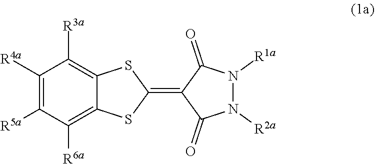

In Formula (1a), R^{1a} and R^{2a} each independently represent an alkyl group,
R^{3a} and R^{6a} each independently represent an alkoxy group or an acyloxy group,
R^{4a} represents an alkyl group or an alkoxy group, and
R^{5a} represents a hydrogen atom, an alkyl group, or an alkoxy group.

R^{1a} and R^{2a} may be bonded to each other to form a ring, R^{3a} and R^{4a} may be bonded to each other to form a ring, R^{4a} and R^{5a} are bonded to each other to form a ring, and R^{5a} and R^{6a} may be bonded to each other to form a ring.

However, in a case where R^{3a} and R^{6a} represent an acyloxy group, at least one of R^{4a} or R^{5a} represents an alkoxy group.

The alkyl group represented by R^{1a} and R^{2a} preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl group may be linear, branched, or cyclic and preferably linear or branched. The alkyl group may have a substituent. Examples of the substituent include groups described in the section of the substituent T described below.

R^{1a} and R^{2a} may be bonded to each other to form a ring. It is preferable that the ring formed by bonding R^{1a} and R^{2a} to each other is a 5- or 6-membered ring. The ring formed by bonding R^{1a} and R^{2a} to each other may have a substituent. Examples of the substituent include groups described in the section of the substituent T described below.

In Formula (1a), R^{3a} and R^{6a} each independently represent an alkoxy group or an acyloxy group. Due to the reason that it is easier to enhance the absorbability of ultraviolet rays in the vicinity of 400 nm while suppressing coloration, it is preferable that at least one of R^{3a} or R^{6a} is an alkoxy group, and it is more preferable that both R^{3a} and R^{6a} represent an alkoxy group.

The alkoxy group represented by R^{3a} and R^{6a} preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkoxy group may be linear or branched. The alkoxy group may have a substituent. Examples of the substituent include groups described in the section of the substituent T described below.

The alkoxy group represented by R^{3a} and R^{6a} preferably has 2 to 30 carbon atoms, more preferably has 2 to 20 carbon atoms, still more preferably has 2 to 15 carbon atoms, and particularly preferably has 2 to 10 carbon atoms. The acyloxy group may have a substituent. Examples of the substituent include groups described in the section of the substituent T described below.

In Formula (1a), R^{4a} represents an alkyl group or an alkoxy group, and R^{5a} represents a hydrogen atom, an alkyl group, or an alkoxy group.

The alkyl group represented by R^{4a} and R^{5a} preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkyl group may be linear, branched, or cyclic and preferably linear or branched. The alkyl group may have a substituent. Examples of the substituent include groups described in the section of the substituent T described below.

The alkoxy group represented by R^{4a} and R^{5a} preferably has 1 to 30 carbon atoms, more preferably has 1 to 20 carbon atoms, still more preferably has 1 to 15 carbon atoms, particularly preferably has 1 to 10 carbon atoms, and most preferably has 1 to 8 carbon atoms. The alkoxy group may be linear or branched. The alkoxy group may have a substituent. Examples of the substituent include groups described in the section of the substituent T described below.

In Formula (1a), R^{3a} and R^{4a} may be bonded to each other to form a ring, R^{4a} and R^{5a} are bonded to each other to form a ring, and R^{5a} and R^{6a} may be bonded to each other to form a ring. It is preferable that the ring formed by bonding these groups to each other is a 5- or 6-membered ring. The ring formed by bonding these groups to each other may have a substituent. Examples of the substituent include groups described in the section of the substituent T described below.

### (Substituent T)

Examples of the substituent T include the following groups:
a halogen atom (for example, a chlorine atom, a bromine atom, or an iodine atom);
an alkyl group [a linear, branched, or cyclic alkyl group, specific examples thereof include a linear or branched alkyl group (preferably a linear or branched alkyl group having 1 to 30 carbon atoms, examples thereof include a methyl group, an ethyl group, an n-propyl group, an isopropyl group, a t-butyl group, an n-octyl group, an eicosyl group, a 2-chloroethyl group, a 2-cyanoethyl group, and a 2-ethylhexyl group), a cycloalkyl group (preferably a cycloalkyl group having 3 to 30 carbon atoms, examples thereof include a cyclohexyl group, a cyclopentyl group, and a 4-n-dodecylcyclohexyl group), a bicycloalkyl group (preferably a bicycloalkyl group having 5 to 30 carbon atoms, that is, a monovalent group obtained by removing one hydrogen atom from a bicycloalkane having 5 to 30 carbon atoms, examples thereof include a bicyclo[1,2,2]heptane-2-yl group and a bicyclo[2,2,2]octane-3-yl group), and further, a group obtained by removing one hydrogen atom from a tricycloalkane structure having a large number of ring structures, an alkyl group in a substituent described below (for example, an alkyl group in an alkylthio group) also represents an alkyl group having such a concept];
an alkenyl group [linear, branched, or cyclic alkenyl group, specific examples thereof include a linear or branched alkenyl group (preferably a linear or branched alkenyl group having 2 to 30 carbon atoms, examples thereof include a vinyl group, an allyl group, a prenyl group, a geranyl group, and an oleyl group), a cycloalkenyl group (preferably a cycloalkenyl group having 3 to 30 carbon atoms, that is, a monovalent group obtained by removing one hydrogen atom from a cycloalkene having 3 to 30 carbon atoms, examples thereof include a 2-cyclopentene-1-yl group and a 2-cyclohexene-1-yl group) and a bicycloalkenyl group (preferably a bicycloalkenyl group having 5 to 30 carbon atoms, that is, a monovalent group obtained by removing one hydrogen atom from a bicycloalkene having one double bond, examples thereof include a bicyclo[2,2,1]hepto-2-en-1-yl group and a bicyclo[2,2,2]octo-2-en-4-yl group)];
an alkynyl group (preferably a linear or branched alkynyl group having 2 to 30 carbon atoms, examples thereof include an ethynyl group and a propargyl group);
an aryl group (preferably an aryl group having 6 to 30 carbon atoms, examples thereof include a phenyl group, a p-tolyl group, a naphthyl group, an m-chlorophenyl group, an o-hexadecanoylaminophenyl group);
a heterocyclic group (preferably a monovalent group obtained by removing one hydrogen atom from a 5- or 6-membered aromatic or non-aromatic heterocyclic compound, and more preferably a 5- or 6-membered aromatic heterocyclic group having 3 to 30 carbon atoms, examples thereof include a 2-furyl group, a 2-thienyl group, a 2-pyrimidinyl group, and a 2-benzothiazolyl group);
a cyano group;
a hydroxy group;
a nitro group;
a carboxy group;
an alkoxy group (preferably a linear or branched alkoxy group having 1 to 30 carbon atoms, examples thereof include a methoxy group, an ethoxy group, an isopropoxy group, a t-butoxy group, an n-octyloxy group, and a 2-methoxyethoxy group);
an aryloxy group (preferably an aryloxy group having 6 to 30 carbon atoms, examples thereof include a phenoxy group, a 2-methylphenoxy group, a 4-t-butylphenoxy group, a 3-nitrophenoxy group, and a 2-tetradecanoylaminophenoxy group);
a heterocyclic oxy group (preferably a heterocyclic oxy group having 2 to 30 carbon atoms, examples thereof include a 1-phenyltetrazole-5-oxy group and a 2-tetrahydropyranyloxy group);
an acyloxy group (preferably a formyloxy group, an alkylcarbonyloxy group having 2 to 30 carbon atoms, or an arylcarbonyloxy group having 6 to 30 carbon atoms, examples thereof include a formyloxy group, an acetyloxy group, a pivaloyloxy group, a stearoyloxy group, a benzoyloxy group, and a p-methoxyphenylcarbonyloxy group);
a carbamoyloxy group (preferably a carbamoyloxy group having 1 to 30 carbon atoms, examples thereof include a N,N-dimethylcarbamoyloxy group, a N,N-diethylcarbamoyloxy group, a morpholinocarbonyloxy group, a N,N-di-n-octylaminocarbonyloxy group, and a N-n-octylcarbamoyloxy group);
an alkoxycarbonyloxy group (preferably an alkoxycarbonyloxy group having 2 to 30 carbon atoms, examples thereof include a methoxycarbonyloxy group, an ethoxycarbonyloxy group, a t-butoxycarbonyloxy group, and an n-octylcarbonyloxy group);
an aryloxycarbonyloxy group (preferably an aryloxycarbonyloxy group having 7 to 30 carbon atoms, examples thereof include a phenoxycarbonyloxy group, a p-methoxyphenoxycarbonyloxy group, and a p-n-hexadecyloxyphenoxycarbonyloxy group);
an amino group (preferably an unsubstituted amino group (—NH₂), an alkylamino group having 1 to 30 carbon atoms, or an anilino group having 6 to 30 carbon atoms, examples thereof include an unsubstituted amino group (—NH₂), a methylamino group, a dimethylamino group, an anilino group, a N-methyl-anilino group, and a diphenylamino group);
an acylamino group (preferably a formylamino group, an alkylcarbonylamino group having 2 to 30 carbon atoms, or an arylcarbonylamino group having 6 to 30 carbon atoms, examples thereof include a formylamino group, an acetylamino group, a pivaloylamino group, a lauroylamino group, a benzoylamino group, and a 3,4,5-tri-n-octyloxyphenylcarbonylamino group);
an aminocarbonylamino group (preferably an aminocarbonylamino group having 1 to 30 carbon atoms, examples thereof include a carbamoylamino group, a N,N-dimethylaminocarbonylamino group, a N,N-diethylaminocarbonylamino group, and a morpholinocarbonylamino group);
an alkoxycarbonylamino group (preferably an alkoxycarbonylamino group having 2 to 30 carbon atoms, examples thereof include a methoxycarbonylamino group, an ethoxycarbonylamino group, a t-butoxycarbonylamino group, an n-octadecyloxycarbonylamino group, and a N-methyl-methoxycarbonylamino group);
an aryloxycarbonylamino group (preferably an aryloxycarbonylamino group having 7 to 30 carbon atoms, examples thereof include a phenoxycarbonylamino group, a p-chlorophenoxycarbonylamino group, and an m-n-octyloxyphenoxycarbonylamino group);
a sulfamoylamino group (preferably a sulfamoylamino group having 0 to 30 carbon atoms, examples thereof include a sulfamoylamino group, a N,N-dimethylaminosulfonylamino group, and a N-n-octylaminosulfonylamino group);
an alkyl or arylsulfonylamino group (preferably an alkyl sulfonylamino group having 1 to 30 carbon atoms or an arylsulfonylamino group having 6 to 30 carbon atoms, examples thereof include a methylsulfonylamino group, a butylsulfonylamino group, a phenylsulfonylamino group, a 2,3,5-trichlorophenylsulfonylamino group, and a p-methylphenylsulfonylamino group);
a mercapto group;
an alkylthio group (preferably an alkylthio group having 1 to 30 carbon atoms, examples thereof include a methylthio group, an ethylthio group, and an n-hexadecylthio group);
an arylthio group (preferably an arylthio group having 6 to 30 carbon atoms, examples thereof include a phenylthio group, a p-chlorophenylthio group, and an m-methoxyphenylthio group);
a heterocyclic thio group (preferably a heterocyclic thio group having 2 to 30 carbon atoms, examples thereof include a 2-benzothiazolylthio group and a 1-phenyltetrazole-5-ylthio group);
a sulfamoyl group (preferably a sulfamoyl group having 0 to 30 carbon atoms, examples thereof include a N-ethylsulfamoyl group, a N-(3-dodecyloxypropyl)sulfamoyl group, a N,N-dimethylsulfamoyl group, a N-acetylsulfamoyl group, a N-benzoylsulfamoyl group, a N—(N′-phenylcarbamoyl)sulfamoyl group);
a sulfo group;
an alkyl or arylsulfinyl group (preferably an alkyl sulfinyl group having 1 to 30 carbon atoms or an arylsulfinyl group having 6 to 30 carbon atoms, examples thereof include a methylsulfinyl group, an ethylsulfinyl group, a phenylsulfinyl group, and a p-methylphenylsulfinyl group);
an alkyl or arylsulfonyl group (preferably an alkylsulfonyl group having 1 to 30 carbon atoms or an arylsulfonyl group having 6 to 30 carbon atoms, examples thereof include a methylsulfonyl group, an ethylsulfonyl group, a phenylsulfonyl group, and a p-methylphenylsulfonyl group);
an acyl group (preferably a formyl group, an alkylcarbonyl group having 2 to 30 carbon atoms, an arylcarbonyl group having 7 to 30 carbon atoms, or a heterocyclic carbonyl group having 4 to 30 carbon atoms and bonded to a carbonyl group, examples thereof include an acetyl group, a pivaloyl group, a 2-chloroacetyl group, a stearoyl group, a benzoyl group, a p-n-octyloxyphenylcarbonyl group, a 2-pyridylcarbonyl group, and a 2-furylcarbonyl group);
an aryloxycarbonyl group (preferably an aryloxycarbonyl group having 7 to 30 carbon atoms, examples thereof include a phenoxycarbonyl group, an o-chlorophenoxycarbonyl group, an m-nitrophenoxycarbonyl group, and a p-t-butylphenoxycarbonyl group);
an alkoxycarbonyl group (preferably an alkoxycarbonyl group having 2 to 30 carbon atoms, examples thereof include a methoxycarbonyl group, an ethoxycarbonyl group, a t-butoxycarbonyl group, and an n-octadecyloxycarbonyl group);
a carbamoyl group (preferably a carbamoyl group having 1 to 30 carbon atoms, examples thereof include a carbamoyl group, a N-methylcarbamoyl group, a N,N-dimethylcarbamoyl group, a N,N-di-n-octylcarbamoyl group, and a N-(methylsulfonyl)carbamoyl group);
an aryl or heterocyclic azo group (preferably an arylazo group having 6 to 30 carbon atoms or a heterocyclic azo group having 3 to 30 carbon atoms, examples thereof include a phenylazo group, a p-chlorophenylazo group, and a 5-ethylthio-1,3,4-thiadiazole-2-ylazo group);
an imide group (preferably an N-succinimide group or an N-phthalimide group);
a phosphino group (preferably a phosphino group having 2 to 30 carbon atoms, examples thereof include a dimethylphosphino group, a diphenylphosphino group, and a methylphenoxyphosphino group);
a phosphinyl group (preferably a phosphinyl group having 2 to 30 carbon atoms, examples thereof include a phosphinyl group, a dioctyloxyphosphinyl group, and a diethoxyphosphinyl group);
a phosphinyloxy group (preferably a phosphinyloxy group having 2 to 30 carbon atoms, examples thereof include a diphenoxyphosphinyloxy group and a dioctyloxyphosphinyloxy group); and
a phosphinylamino group (preferably a phosphinylamino group having 2 to 30 carbon atoms, examples thereof include a dimethoxyphosphinylamino group and a dimethylaminophosphinylamino group).

Among the groups described above, one or more hydrogen atoms of groups having hydrogen atoms may be substituted with the above-described substituent T. Examples of such substituents include an alkylcarbonylaminosulfonyl group, an arylcarbonylaminosulfonyl group, an alkylsulfonylaminocarbonyl group, and an arylsulfonylaminocarbonyl group. Specific examples include a methylsulfonylaminocarbonyl group, a p-methylphenylsulfonylaminocarbonyl group, an acetylaminosulfonyl group, and a benzoylaminosulfonyl group.

Specific examples of the compound (1) include compounds having the following structures. However, the liquid crystal cell is not limited thereto. In the structural formulae shown below, Me represents a methyl group, Et represents an ethyl group, Bu represents a butyl group, tBu represents a tert-butyl group, Pr represents a propyl group, and Ph represents a phenyl group.

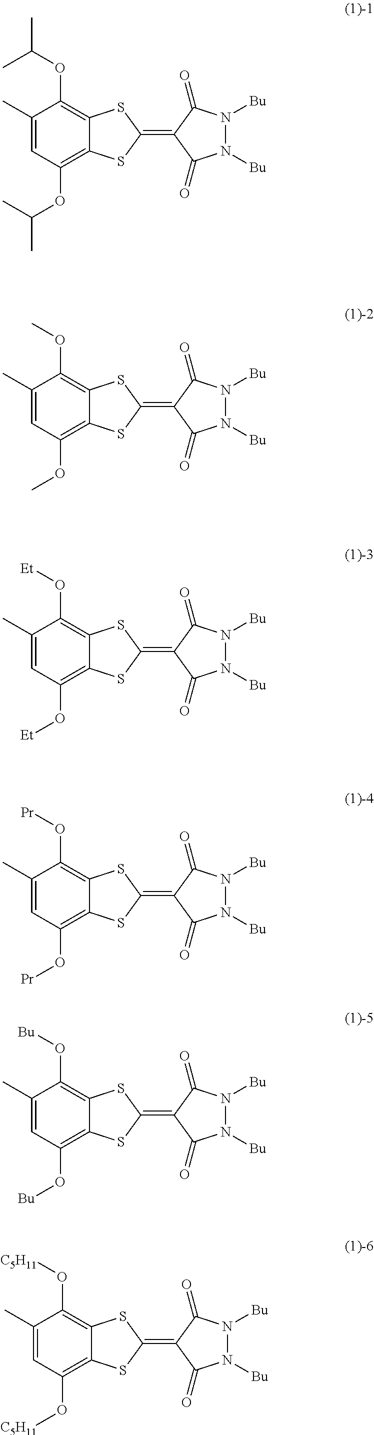

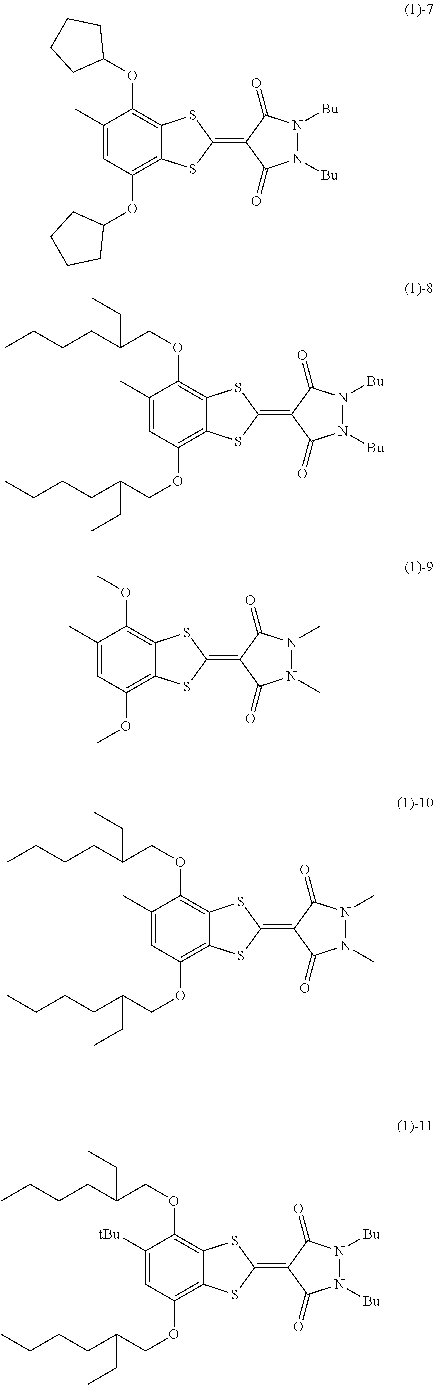

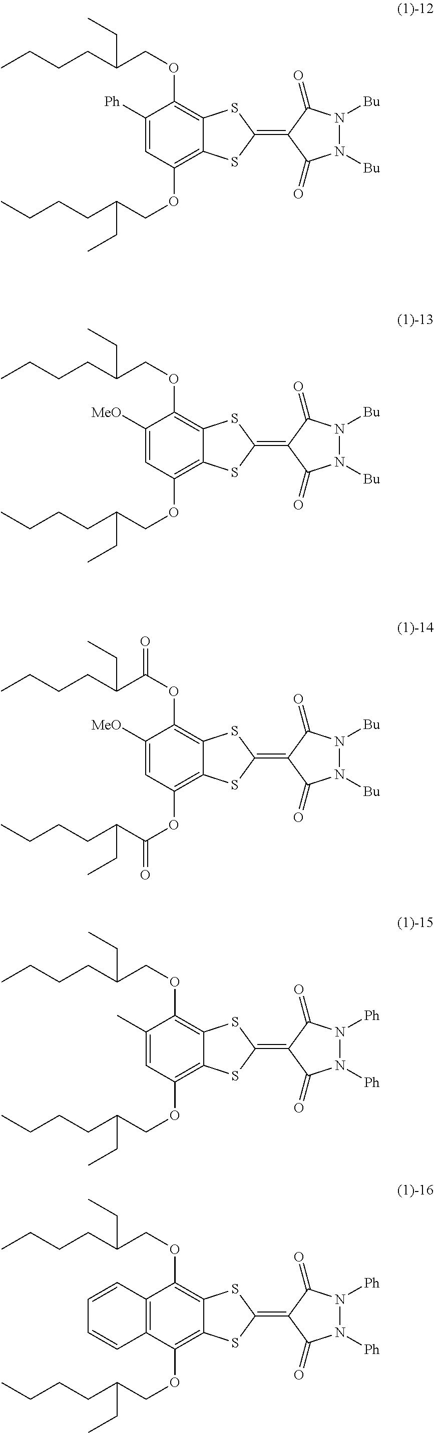

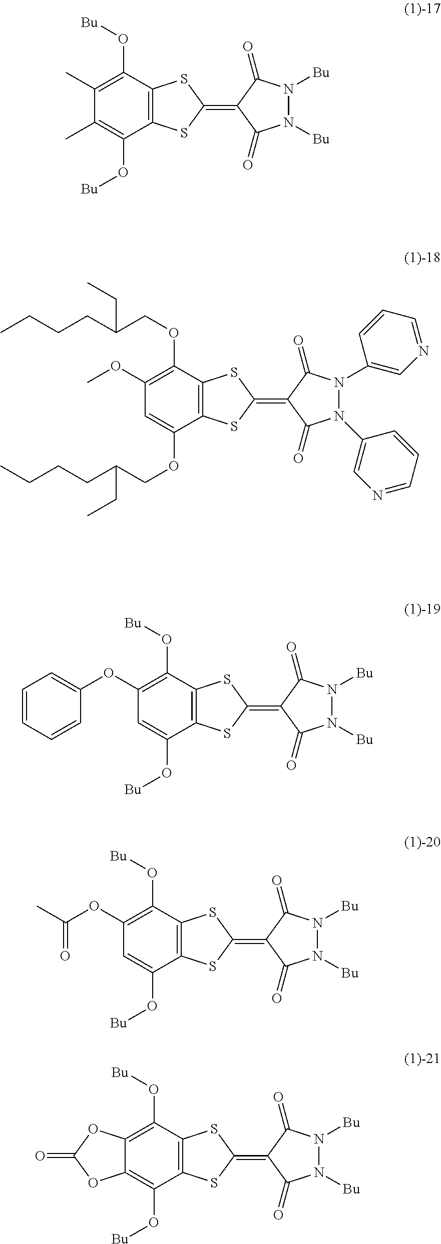

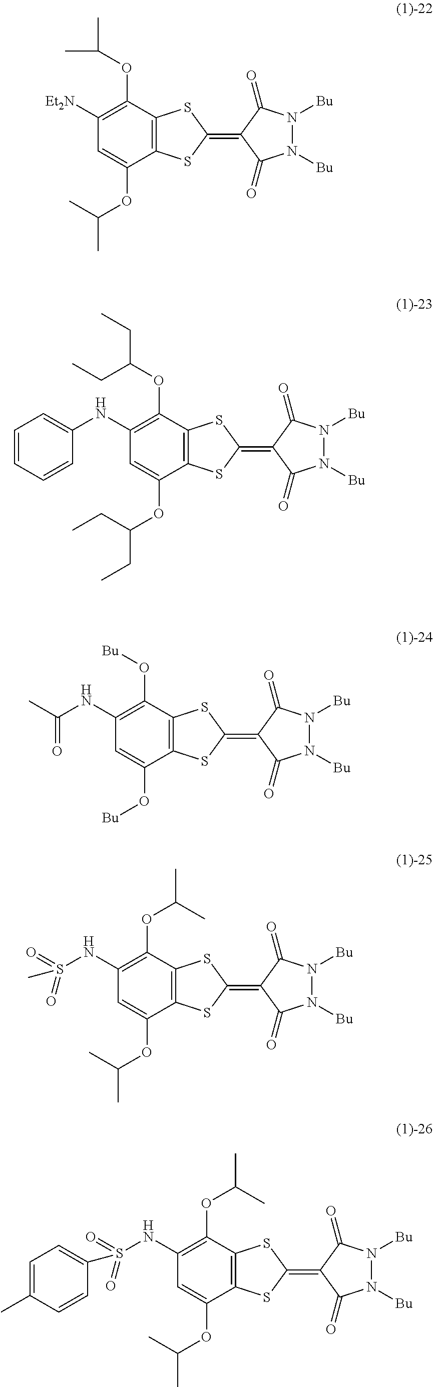

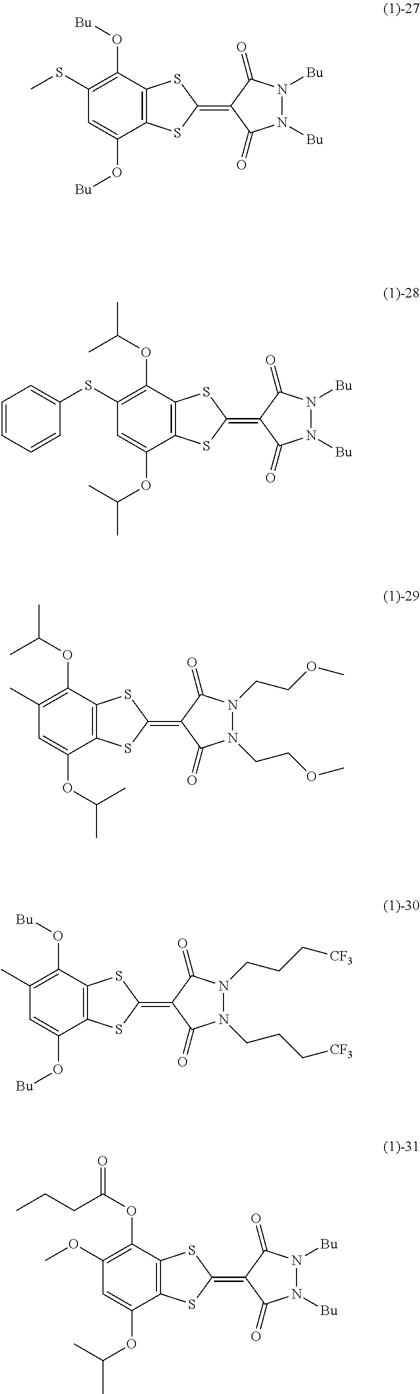

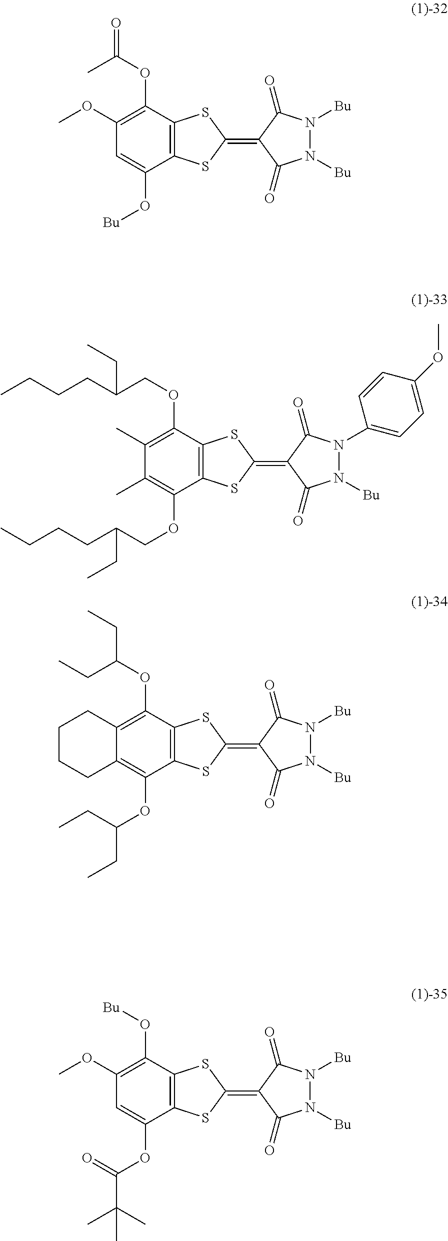

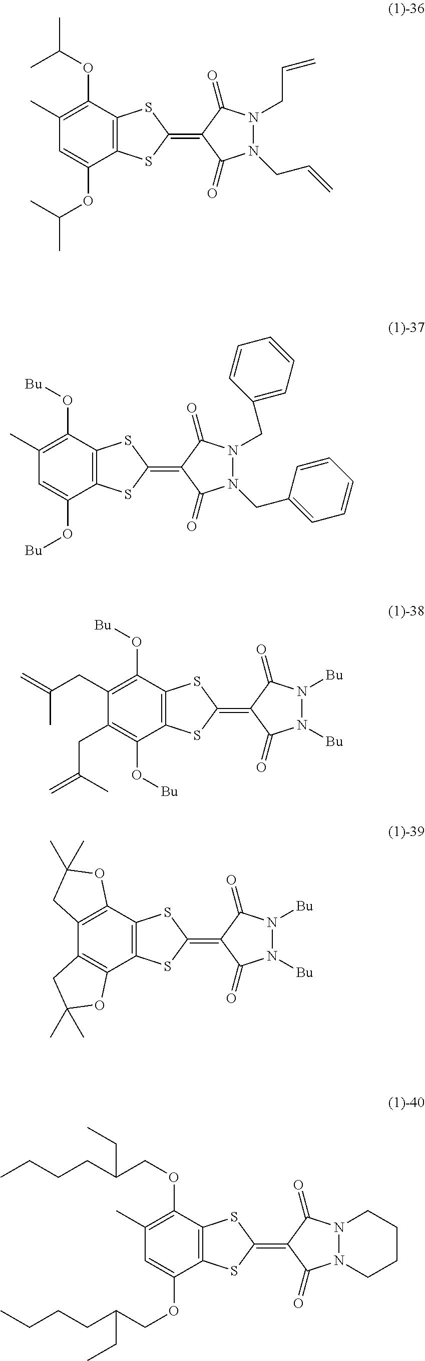

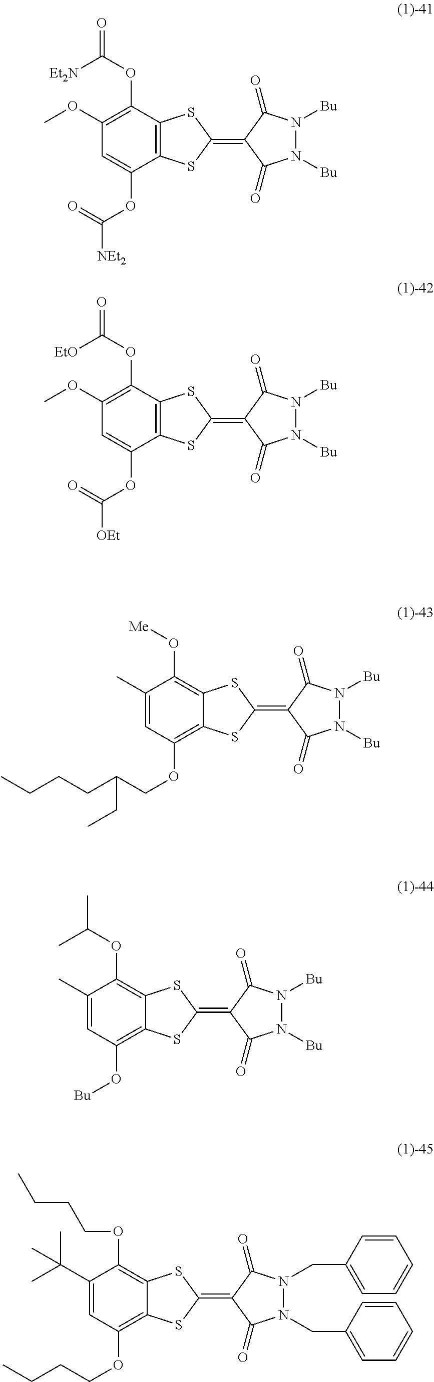

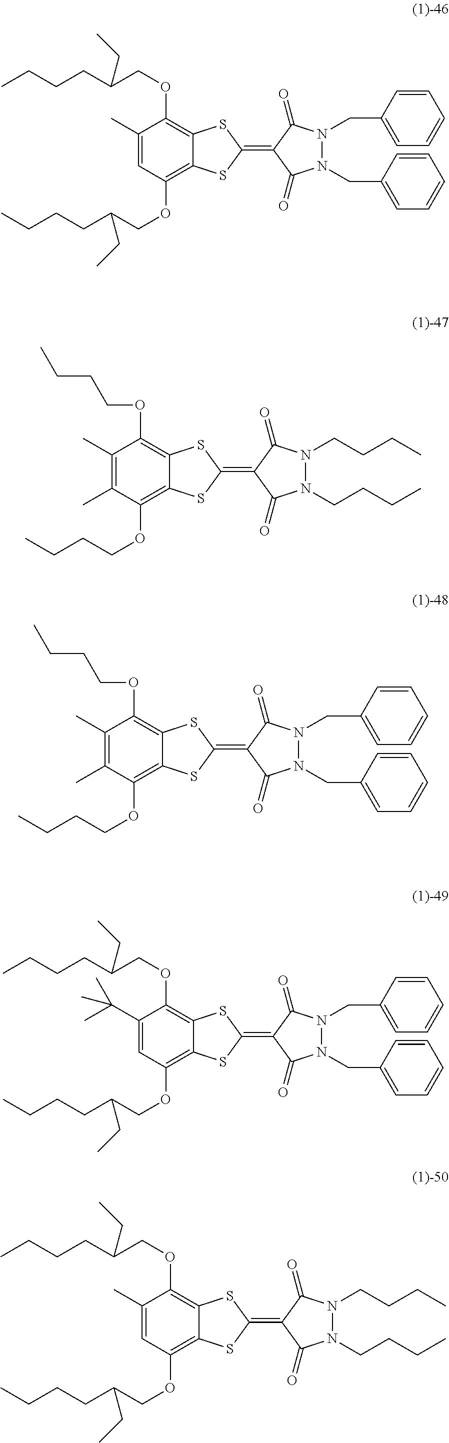

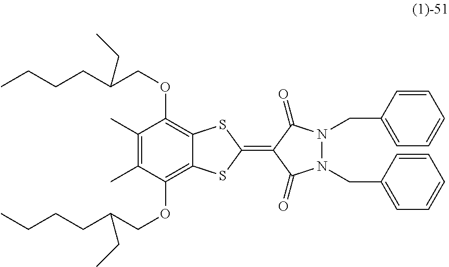 [SMILES: CCCCC(CC)COc1c(C)c(C)c(OCC(CC)CCCC)c2c1SC(=C1C(=O)N(Cc3ccccc3)N(Cc3ccccc3)C1=O)S2]

The compound (1) is preferably used as an ultraviolet absorbing agent. The maximal absorption wavelength of the compound (1) is present preferably in a wavelength range of 370 to 420 nm and more preferably in a wavelength range of 380 to 400 nm.

The molar absorption coefficient F₄₀₅ of the compound (1) at a wavelength of 405 nm, which is calculated from the following expression, is preferably 500 or more, more preferably 1,000 or more, still more preferably 2,000 or more, and particularly preferably 3,000 or more.

$${ε}_{405} = {ε}_{max} \times ( {A}_{405} / {A}_{max} )$$

ε₄₀₅ is a molar absorption coefficient of the compound (1) at a wavelength of 405 nm, Fₘₐₓ is a molar absorption coefficient of the compound (1) at the maximal absorption wavelength, A₄₀₅ is an absorbance of the compound (1) at a wavelength of 405 nm, and Aₘₐₓ is an absorbance of the compound (1) at the maximal absorption wavelength. It is noted that the unit of the molar absorption coefficient described above is L/(mol·cm). A₄₀₅ and Aₘₐₓ shall be an absorbance in a spectral absorption spectrum of the compound (1), which is measured in ethyl acetate.

In the spectral absorption spectrum of the compound (1), which is measured in ethyl acetate, a ratio (A₄₃₀/A₄₀₅) of the absorbance A₄₀₅ at a wavelength 405 nm to the absorbance A₄₃₀ at a wavelength 430 nm is preferably less than 0.13 and more preferably 0.10 or less. The lower limit of the ratio is not particularly limited; however, it can be set to 0 or more. Since a compound having such an absorbance ratio is excellent in light transmittance in a visible range in the vicinity of the ultraviolet range despite high absorption in the vicinity of a wavelength of 405 nm, it has excellent absorbability of ultraviolet rays on the longer wavelength side and has excellent visible transparency. It is noted that in a case where an attempt is made to shift the absorption range of ultraviolet rays in the compound to a longer wavelength side, the transmittance of light in the visible range (in particular, the transmittance of light in the visible range in the vicinity of the ultraviolet range) also tends to decrease; however, according to the compound (1), it is possible to exhibit an excellent effect of improving the absorbability of ultraviolet rays on a longer wavelength side while maintaining the transmittance of light in the visible range at a high level.

The compound (1) can be synthesized with reference to the synthetic methods described in JP2016-081035A, JP5376885B, and the like.

The content of the compound (1) in the total solid content of the resin composition for forming the ultraviolet absorbing layer is preferably in a range of 0.01% to 50% by mass. The lower limit thereof is preferably 0.05% by mass or more and more preferably 0.10% by mass or more. The upper limit value thereof is more preferably 40% by mass or less, still more preferably 30% by mass or less, and particularly preferably 20% by mass or less.

The content of the compound (1) is preferably 0.01 to 50 parts by mass with respect to 100 parts by mass of the resin. The lower limit thereof is preferably 0.05 parts by mass or more and more preferably 0.10 parts by mass or more. The upper limit thereof is more preferably 40 parts by mass or less, still more preferably 30 parts by mass or less, and particularly preferably 20 parts by mass or less.

The resin composition may contain only one kind of the compound (1) or may contain two or more kinds thereof. In a case where the resin composition contains two or more kinds of the compounds (1), it is preferable that the total amount thereof is in the above-described range.

### (Resin)

As the resin that is used for the ultraviolet absorbing layer, a known resin can be used, which is not particularly limited as long as it does not contradict the gist of the present invention. Examples of the resin include a cellulose acylate resin, an acrylic resin, a cycloolefin-based resin, a polyester-based resin, and an epoxy resin.

### (Installation Position of Ultraviolet Absorbing Layer)

The disposition of the ultraviolet absorbing layer is not particularly limited as long as it is on the viewer side with respect to the optical filter according to the embodiment of the present invention, and the ultraviolet absorbing layer can be installed at any position. For example, it is also possible to add an ultraviolet absorbing agent to a member such as a protective film of the polarizing plate, an antireflection film, or the like to impart it a function of an ultraviolet absorbing layer. In addition, an ultraviolet absorbing agent can also be added to the above-described pressure-sensitive adhesive layer.

### Examples

Hereinafter, the present invention will be described in more detail based on Examples. The materials, using amount, ratio, details of treatment, procedures of treatment, and the like described in Examples below can be appropriately changed without departing from the spirit of the present invention. Therefore, it is to be understood that the scope of the present invention is not limited to Examples described below.

It is noted that “parts” and “%” that indicate the composition in Examples below are based on mass unless otherwise specified. Room temperature means “25° C.”.

All steps from a preparation step of a light absorption filter forming liquid to a production step of a base material-attached light absorption filter using the light absorption filter forming liquid and to the use thereof in the ultraviolet irradiation test were carried out under a yellow lamp to avoid ultraviolet irradiation.

### [Production of Light Absorption Filter]

Materials used to produce the light absorption filter are shown below.

### <Matrix Polymer (Resin)>

### (Resin 1)

A cyclohexyl methacrylate-methacrylic acid random copolymer, methacrylic acid content: 29% by mole, weight-average molecular weight: 26,300.

It is noted that the methacrylic acid moiety of the resin 1 corresponds to the compound A having an acid group defined in the present invention.

### <Compound B>

4-methylquinoline (manufactured by Tokyo Chemical Industry Co., Ltd., Lepidine, pKaH: 5.1)

### <Dye>

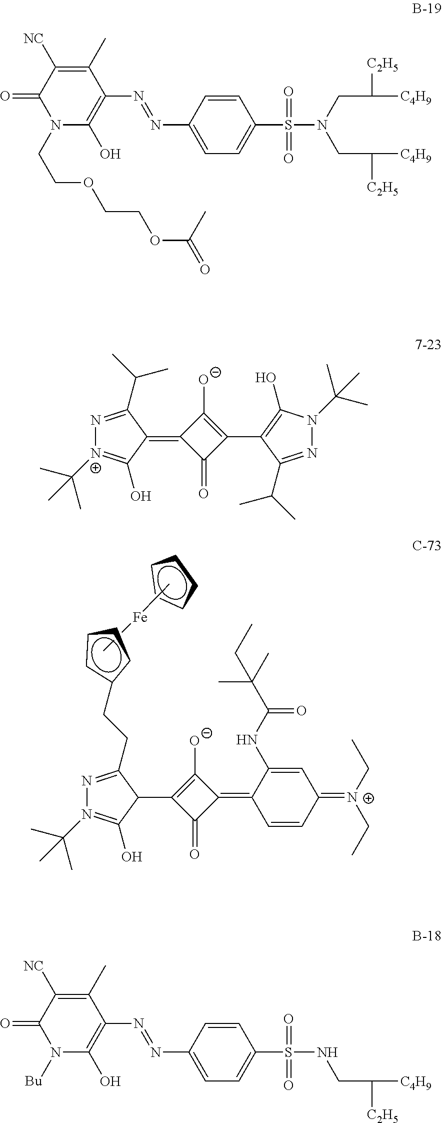

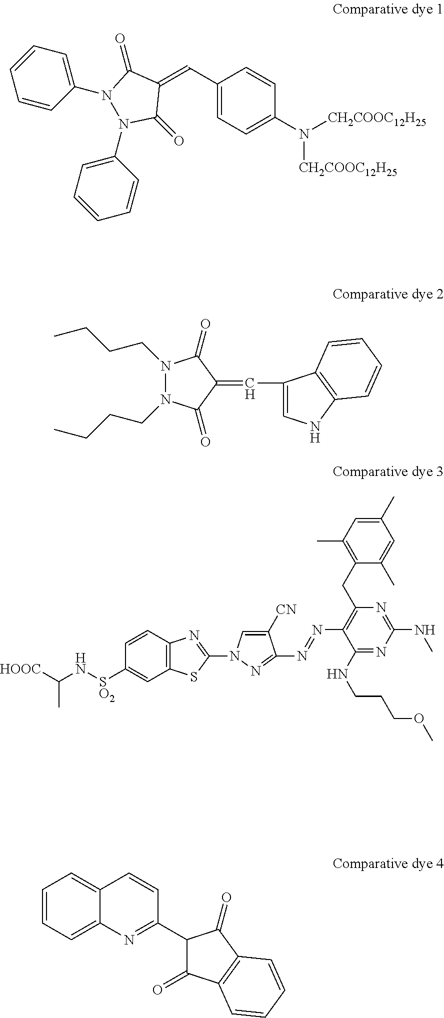

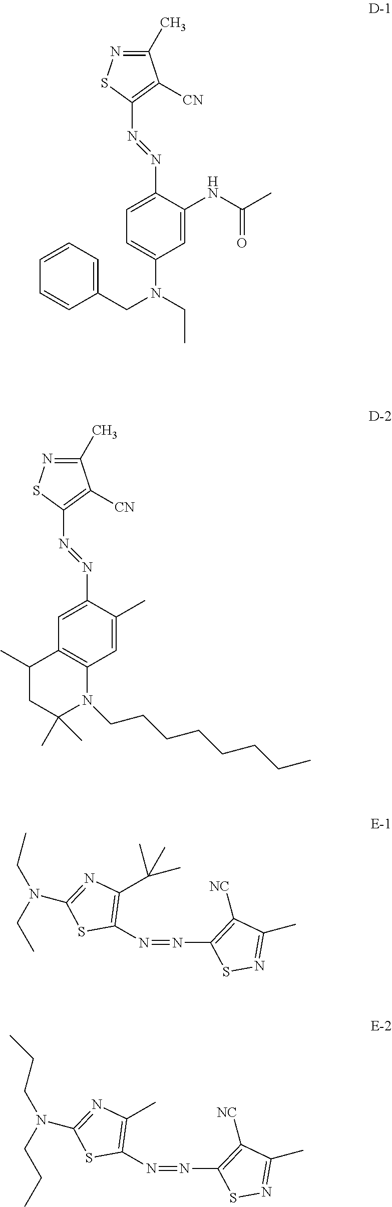

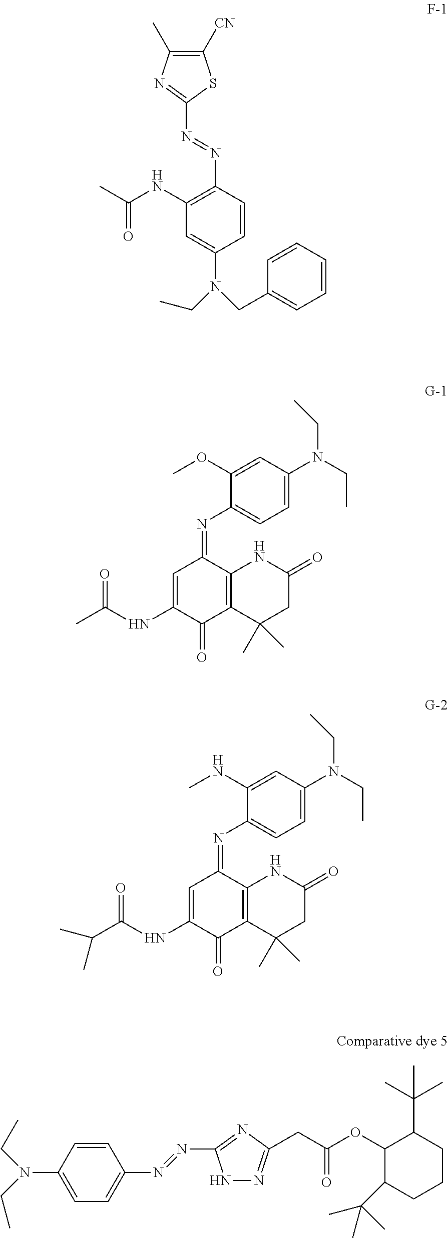

### (Leveling Agent 1)

A polymer surfactant composed of the following constitutional components was used as a leveling agent 1. In the following structural formulae, the proportion of each constitutional component is in terms of a molar ratio, and t-Bu means a tert-butyl group.

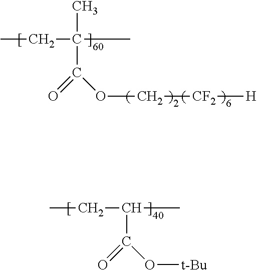

### (Base Material 1)

A polyethylene terephthalate film (manufactured by TORAY INDUSTRIES, Inc., product name: Lumirror XD-510P, film thickness: 50 μm)

### Examples

### <1. Production of Light Absorption Filter No. 101>

### (1) Preparation of Resin Solution (Light Absorption Filter Forming Liquid)

Each component was mixed with the composition shown below to prepare a light absorption filter forming liquid (composition) Ba-1.

Composition of light absorption filter forming liquid Ba-1

| | | |
|---|---|---|
| Resin 1 | 81.1 | parts by mass |
| Leveling agent 1 | 0.08 | parts by mass |
| Dye B-19 | 1.56 | parts by mass |
| 4-methylquinoline (manufactured by | 17.2 | parts by mass |
| Tokyo Chemical Industry Co., Ltd.) | | |
| Methyl ethyl ketone (solvent) | 566.7 | parts by mass |

Subsequently, the obtained light absorption filter forming liquid Ba-1 was filtered using a filter paper (#63, manufactured by Toyo Filter Paper Co., Ltd.) having an absolute filtration precision of 10 μm, and further subjected to filtration using a metal sintered filter (product name: Pall filter PMF, media code: FH025, manufactured by Pall) with an absolute filtration precision of 2.5 μm.

### (2) Production of Light Absorption Filter

The light absorption filter forming liquid Ba-1 after the filtration treatment was applied onto a base material 1 by using a bar coater so that the film thickness after drying was 2.2 μm, and dried at 120° C. to produce a light absorption filter No. 101.

<2. Production of Light Absorption Filters Nos. 102 to 112, r201, and c202 to c206>

Light absorption filters Nos. 102 to 112 and c202 to c206 were produced in the same manner as in the production of the light absorption filter No. 101, except that in the production of the light absorption filter No. 101, at least any one of the kind or the blending amount of the dye was changed to the content described in Table 1. It is noted that the adjustment is carried out such that the blending amount of the leveling agent 1 in the light absorption filter No. 101 is fixed, the blending amount of the resin is changed according to the change in the amount of the dye, and the mass of the entire filter does not change.

In addition, a light absorption filter No. r201 was produced in the same manner, except that in the production of the light absorption filter No. 101, the compound B and the dye were not blended and the blending amount of the resin was changed so that the mass of the entire filter was not changed.

Here, Nos. 101 to 112 are the light absorption filters according to the embodiment of the present invention, Nos. c202 to c206 are light absorption filters for comparison, and No. r201 is a light absorption filter for reference.

### [Production of Light Absorption Filter Having Gas Barrier Layer]

Regarding each of the light absorption filters Nos. 101 to 112, r201, and c202 to c206 a light absorption filter (a light absorption filter having a gas barrier layer) formed by further laminating a gas barrier layer on the light absorption filter was produced as described below, and the evaluation described later was carried out.

### (1) Production of Base Material 3

The light absorption filter side of the base material-attached light absorption filter produced above was subjected to a corona treatment using a corona treatment device (product name: Corona-Plus, manufactured by VETAPHONE) under the conditions of a discharge amount of 1,000 W·min/m² and a processing speed of 3.2 m/min and used as a base material 3.

### (2) Preparation of Resin Solution

Each component was mixed with the composition shown below, and the resultant mixture was stirred in a constant-temperature tank at 90° C. for 1 hour to dissolve Kuraray Exceval AQ-4105 (product name, manufactured by KURARAY Co., Ltd., modified polyvinyl alcohol, saponification degree: 98% to 99% by mole), whereby a gas barrier layer forming liquid was prepared.

Composition of gas barrier layer forming liquid

| | | |
|---|---|---|
| Kuraray Exceval AQ-4105 (product name, | 4.0 | parts by mass |
| manufactured by KURARAY Co., Ltd.) | | |
| Pure water | 88.5 | parts by mass |
| Isopropyl alcohol | 7.5 | parts by mass |

Subsequently, the obtained gas barrier layer forming liquid was filtered using a filter having an absolute filtration precision of 5 μm (product name: Hydrophobic Fluorepore Membrane, manufactured by Millex).

### (3) Lamination of Gas Barrier Layer

The gas barrier layer forming liquid after the filtration treatment was applied to the corona-treated surface side of the base material 3 using a bar coater so that the film thickness after drying was 1.6 μm, and dried at 120° C. for 60 seconds, whereby a light absorption filter having a gas barrier layer was produced.

The light absorption filter having a gas barrier layer has a configuration in which the base material 1, the light absorption filter, and the gas barrier layer are laminated in this order.

### <Evaluation of Physical Properties of Gas Barrier Layer>

The physical properties of the gas barrier layer, which had been measured by the method described in [0182] to [0184] of WO02022/149510A, were a degree of crystallinity of 53%, an oxygen permeability of 0.4 cc/m²·day·atm, and a thickness of 1.6 μm, respectively.

### <Absorbance of Light Absorption Filter (Before Ultraviolet Irradiation)>

### (1) Measurement of Absorbance

Using a UV3600 spectrophotometer (product name) manufactured by Shimadzu Corporation, the absorbance of the light absorption filter having a gas barrier layer and the standard filter in a wavelength range of 380 to 800 nm was measured for every 1 nm.

A standard filter for the light absorption filters Nos. 101 to 112, and c202 to c206, which contain the resin 1, is the light absorption filter No. r201 which has been changed not to contain the dye and the compound B.

### (2) Calculation of Absorbance

Using the absorbance value Abₓ (λ) of the light absorption filter having a gas barrier layer at each wavelength λ nm measured as described above and the absorbance value Ab₀ (λ) of the standard filter containing the same resin at each wavelength λ nm, the absorbance Ab (λ) of the light absorption filter before ultraviolet irradiation was calculated according to the following expression.

$$Ab ( λ ) = {Ab}_{x} ( λ ) - {Ab}_{0} ( λ )$$

Hereinafter, among the absorbances Ab (λ) of the light absorption filter in a wavelength range of 400 to 700 nm, the wavelength at which the highest absorbance Ab (λ) among the wavelengths at which the highest maximal absorption is exhibited was defined as the maximal absorption wavelength (hereinafter, also simply referred to as “λₘₐₓ”), and the absorbance at λₘₐₓ was defined as the absorption maximal value (hereinafter, also simply referred to as “Ab (λₘₐₓ)”).

It is noted that the above-described maximal absorption wavelength and absorption maximal value were determined for each of the dye A, the dye B, and the dye C, and the decolorization rate described later was evaluated for each dye. Here, the dyes B-19 and B-18, which are the azo-based coloring agents represented by General Formula (i) described above, and the comparative dyes 1 to 4 are classified into the dye A, the dye 7-23, the dye F-1 which is the azo-based coloring agent represented by General Formula (ii) described above, the dyes E-1 and E-2, which are the azo-based coloring agents represented by General Formula (iii) described above, the dyes D-1 and D-2, which are the azo-based coloring agents represented by General Formula (iv) described above, and the comparative dye 5 are classified into the dye B, and the dyes G-1 and G-2, which are the indoaniline-based dyes represented by General Formula (v) described above, and the dye C-73 are classified into the dye C.

### <<Evaluation 1>>

The decolorization rate of each light absorption filter was evaluated.

The results are summarized in Table 2 below.

### (Ultraviolet Irradiation Test)

At room temperature, the light absorption filter having a gas barrier layer and the standard filter were irradiated with ultraviolet rays (UV) at an illuminance of 100 mW/cm² and an irradiation amount shown in Table 1 from the gas barrier layer side (the side opposite to the base material 1) by using an ultra-high pressure mercury lamp (manufactured by HOYA Corporation, product name: UL750) under atmospheric pressure (101.33 kPa).

<Absorbance of Light Absorption Filter (after Ultraviolet Irradiation)>

Using the light absorption filter having a gas barrier layer after ultraviolet irradiation and the standard filter, the absorbance Ab (λ) of the light absorption filter after ultraviolet irradiation was calculated according to the same method as described in <Absorbance of light absorption filter (before ultraviolet irradiation)> described above.

### [1. Evaluation of Decolorization Rate]

The decolorization rate was calculated according to the following expression using the maximal absorption values (Ab (λₘₐₓ)) before and after the ultraviolet irradiation test.

$$Decolorization rate ( \% ) = 100 - ( Ab ( {λ}_{max} ) after ultraviolet irradiation / Ab ( {λ}_{max} ) before ultraviolet irradiation ) \times 100 \%$$

[2. Evaluation of Presence or Absence of Secondary Absorption Associated with Decomposition of Coloring Agent]

The presence or absence of the absorption (secondary absorption) derived from the new coloration structure associated with the decomposition of the coloring agent was evaluated based on a ratio of an absorbance at a wavelength of 450 nm (hereinafter, also simply referred to as “Ab (450)”) to the absorption maximal value (Ab (λₘₐₓ)) before ultraviolet irradiation and a ratio of an absorbance at a wavelength of 650 nm (hereinafter, also simply referred to as “Ab (650)”) to the absorption maximal value (Ab (λₘₐₓ)) before ultraviolet irradiation. It means that the smaller the value obtained by subtracting the ratio of the following (I) from the ratio of the following (II) and the value obtained by subtracting the ratio of the following (III) from the ratio of the following (IV), the less the absorption derived from the new coloration structure associated with the decomposition of the coloring agent occurs.

It is noted that in the description of Table 2 described later, as a wavelength at which the coloring agent before ultraviolet irradiation seldom exhibits absorption but new absorption due to the decomposition of the coloring agent is observed, where the wavelength is a wavelength at which the presence or absence of the secondary absorption associated with the decomposition of the coloring agent can be evaluated, a wavelength of 450 nm can be selected for evaluations of Nos. 101, 105, 106, 109 to 111, and c203, and a wavelength of 650 nm can be selected for evaluations of Nos. 101 to 109, 112, and c202 to c206, respectively.

Ab (450) before ultraviolet irradiation/Ab (λₘₐₓ)×100% before ultraviolet irradiation (I)

Ab (450) after ultraviolet irradiation/Ab (λₘₐₓ) before ultraviolet irradiation×100% (II)

Ab (650) before ultraviolet irradiation/Ab (λₘₐₓ) before ultraviolet irradiation×100% (III)

Ab (650) after ultraviolet irradiation/Ab (λₘₐₓ) before ultraviolet irradiation×100% (IV)

### [Simulation of Tint of Reflected Light]

In a configuration in which the light absorption filter produced above was transferred to an aluminum foil substrate through a pressure-sensitive adhesive and then the base material was peeled off, a simulation regarding the reflection of external light on the aluminum foil substrate was carried out, and the tint (a* and b*) of the reflected light was calculated.

Specifically, in the configuration shown in FIG. 2, the intensity of light obtained in a case where white light having a spectrum of standard illuminant D65 defined by the International Commission on Illumination (CIE) is transmitted through the light absorption filter, subsequently reflected by an aluminum foil substrate having a reflectivity of 85%, and further transmitted again through the optical filter was calculated every 1 nm in a range of a wavelength of 380 nm to a wavelength of 780 nm, and this was multiplied by the standard photopic relative luminous efficiency and summed (corrected for luminous efficiency) to calculate the tint (a* and b*).

From the viewpoint of making the tint of the reflected light close to neutral (adjusting the tint of the reflected light), both a* and b* are preferably close to 0 in terms of absolute value, and for example, a level of 3.0 or less is a preferred level.

TABLE 1

| | Dye | | | | Compound B | | Irradiation |
|---|---|---|---|---|---|---|---|
| | | λₘₐₓ | Blending | | | Blending | amount |
| No. | Kind | (nm) | amount | Resin | Kind | amount | (mJ/cm²) |
| 101 | B-19 | 431 | 1.56 | 1 | 4-methylquinoline | 17.2 | 750 |
| 102 | B-19 | 431 | 0.85 | 1 | 4-methylquinoline | 17.2 | 1250 |
| | 7-23 | 505 | 0.72 | | | | |
| | C-73 | 593 | 1.10 | | | | |
| 103 | B-19 | 431 | 1.34 | 1 | 4-methylquinoline | 17.2 | 1500 |
| | 7-23 | 505 | 0.92 | | | | |
| | C-73 | 593 | 1.57 | | | | |
| 104 | B-18 | 431 | 1.14 | 1 | 4-methylquinoline | 17.2 | 750 |
| 105 | D-1 | 549 | 0.95 | 1 | 4-methylquinoline | 17.2 | 1000 |
| 106 | D-2 | 566 | 1.03 | 1 | 4-methylquinoline | 17.2 | 1000 |
| 107 | E-1 | 527 | 0.82 | 1 | 4-methylquinoline | 17.2 | 1000 |
| 108 | E-2 | 520 | 0.79 | 1 | 4-methylquinoline | 17.2 | 1000 |
| 109 | F-1 | 546 | 0.95 | 1 | 4-methylquinoline | 17.2 | 1000 |
| 110 | G-1 | 658 | 0.99 | 1 | 4-methylquinoline | 17.2 | 1000 |
| 111 | G-2 | 634 | 1.12 | 1 | 4-methylquinoline | 17.2 | 1000 |
| 112 | B-19 | 431 | 1.31 | 1 | 4-methylquinoline | 17.2 | 1250 |
| | E-2 | 520 | 0.46 | | | | |
| | C-73 | 593 | 1.17 | | | | |
| c202 | Comparative dye 1 | 450 | 1.96 | 1 | 4-methylquinoline | 17.2 | 750 |
| c203 | Comparative dye 2 | 416 | 0.77 | 1 | 4-methylquinoline | 17.2 | 750 |
| c204 | Comparative dye 3 | 443 | 1.66 | 1 | 4-methylquinoline | 17.2 | 750 |
| c205 | Comparative dye 4 | 421 | 1.14 | 1 | 4-methylquinoline | 17.2 | 750 |
| c206 | Comparative dye 5 | 453 | 1.16 | 1 | 4-methylquinoline | 17.2 | 1000 |

TABLE 2

| | | | | | | Ratio of Ab(450) | | | | Ratio of Ab(650) | | | |
|---|---|---|---|---|---|---|---|---|---|---|---|---|---|
| | | | | | | to Ab(λₘₐₓ) | | | | to Ab (λₘₐₓ) | | | |
| | | | | | | before ultraviolet | | | | before ultraviolet | | | |
| | | | | Ab (450) [symbol] | | irradiation [symbol] | | Ab(650) [symbol] | | irradiation [symbol] | | | |
| | | | | Before | After | Before | After | Before | After | Before | After | | |
| | Decolorization | | | ultra- | ultra- | ultra- | ultra- | ultra- | ultra- | ultra- | ultra- | Tint of | |
| | rate [symbol] | | | violet | violet | violet | violet | violet | violet | violet | violet | reflected | |
| | Dye | Dye | Dye | irradi- | irradi- | irradi- | irradi- | irradi- | irradi- | irradi- | irradi- | light [symbol] | |
| No. [symbol] | A [symbol] | B [symbol] | C [symbol] | ation [symbol] | ation [symbol] | ation [symbol] | ation [symbol] | ation [symbol] | ation [symbol] | ation [symbol] | ation [symbol] | a* [symbol] | b* [symbol] |
| 101 [symbol] | 93% [symbol] | — [symbol] | — [symbol] | 0.012 [symbol] | 0.012 [symbol] | 5% [symbol] | 5% [symbol] | 0.009 [symbol] | 0.005 [symbol] | 3% [symbol] | 2% [symbol] | −15.4 [symbol] | 39.0 [symbol] |
| 102 [symbol] | 93% [symbol] | 96% [symbol] | 99% [symbol] | 0.195 [symbol] | 0.013 [symbol] | 24% [symbol] | 2% [symbol] | 0.008 [symbol] | 0.009 [symbol] | 1% [symbol] | 1% [symbol] | 2.3 [symbol] | −0.6 [symbol] |
| 103 [symbol] | 90% [symbol] | 93% [symbol] | 97% [symbol] | 0.252 [symbol] | 0.030 [symbol] | 24% [symbol] | 3% [symbol] | 0.013 [symbol] | 0.015 [symbol] | 1% [symbol] | 1% [symbol] | 1.0 [symbol] | 1.4 [symbol] |
| 104 [symbol] | 91% [symbol] | — [symbol] | — [symbol] | 0.220 [symbol] | 0.034 [symbol] | 82% [symbol] | 13% [symbol] | 0.005 [symbol] | 0.009 [symbol] | 2% [symbol] | 3% [symbol] | −16.0 [symbol] | 38.1 [symbol] |
| 105 [symbol] | — [symbol] | 95% [symbol] | — [symbol] | 0.052 [symbol] | 0.006 [symbol] | 14% [symbol] | 2% [symbol] | 0.009 [symbol] | 0.009 [symbol] | 2% [symbol] | 2% [symbol] | 59.0 [symbol] | −29.9 [symbol] |
| 106 [symbol] | — [symbol] | 96% [symbol] | — [symbol] | 0.028 [symbol] | 0.004 [symbol] | 8% [symbol] | 1% [symbol] | 0.012 [symbol] | 0.007 [symbol] | 4% [symbol] | 2% [symbol] | 42.4 [symbol] | −39.3 [symbol] |
| 107 [symbol] | — [symbol] | 95% [symbol] | — [symbol] | 0.049 [symbol] | 0.005 [symbol] | 17% [symbol] | 2% [symbol] | 0.011 [symbol] | 0.012 [symbol] | 4% [symbol] | 4% [symbol] | 46.9 [symbol] | −17.2 [symbol] |
| 108 [symbol] | — [symbol] | 95% [symbol] | — [symbol] | 0.061 [symbol] | 0.001 [symbol] | 22% [symbol] | 0% [symbol] | 0.007 [symbol] | 0.011 [symbol] | 3% [symbol] | 4% [symbol] | 42.8 [symbol] | −9.0 [symbol] |
| 109 [symbol] | — [symbol] | 96% [symbol] | — [symbol] | 0.049 [symbol] | 0.004 [symbol] | 16% [symbol] | 1% [symbol] | 0.009 [symbol] | 0.011 [symbol] | 3% [symbol] | 4% [symbol] | 47.0 [symbol] | −30.7 [symbol] |
| 110 [symbol] | — [symbol] | — [symbol] | 96% [symbol] | 0.007 [symbol] | 0.001 [symbol] | 4% [symbol] | 1% [symbol] | 0.146 [symbol] | 0.008 [symbol] | 92% [symbol] | 5% [symbol] | −13.7 [symbol] | −16.0 [symbol] |
| 111 [symbol] | — [symbol] | — [symbol] | 96% [symbol] | 0.010 [symbol] | 0.001 [symbol] | 5% [symbol] | 0% [symbol] | 0.216 [symbol] | 0.009 [symbol] | 99% [symbol] | 4% [symbol] | −18.8 [symbol] | −12.2 [symbol] |
| 112 [symbol] | 92% [symbol] | 90% [symbol] | 92% [symbol] | 0.277 [symbol] | 0.021 [symbol] | 37% [symbol] | 2% [symbol] | 0.007 [symbol] | 0.007 [symbol] | 1% [symbol] | 1% [symbol] | −1.4 [symbol] | 0.6 [symbol] |
| c202 [symbol] | 84% [symbol] | — [symbol] | — [symbol] | 0.358 [symbol] | 0.058 [symbol] | 100% [symbol] | 16% [symbol] | 0.007 [symbol] | 0.005 [symbol] | 2% [symbol] | 1% [symbol] | −17.7 [symbol] | 52.9 [symbol] |
| c203 [symbol] | 31% [symbol] | — [symbol] | — [symbol] | 0.031 [symbol] | 0.019 [symbol] | 16% [symbol] | 10% [symbol] | 0.007 [symbol] | 0.002 [symbol] | 4% [symbol] | 1% [symbol] | −6.7 [symbol] | 12.1 [symbol] |
| c204 [symbol] | 56% [symbol] | — [symbol] | — [symbol] | 0.282 [symbol] | 0.126 [symbol] | 97% [symbol] | 43% [symbol] | 0.005 [symbol] | 0.008 [symbol] | 2% [symbol] | 3% [symbol] | −16.7 [symbol] | 45.6 [symbol] |
| c205 [symbol] | 1% [symbol] | — [symbol] | — [symbol] | 0.330 [symbol] | 0.340 [symbol] | 86% [symbol] | 88% [symbol] | 0.011 [symbol] | 0.008 [symbol] | 3% [symbol] | 2% [symbol] | −17.2 [symbol] | 38.2 [symbol] |
| c206 [symbol] | — [symbol] | 73% [symbol] | — [symbol] | 0.079 [symbol] | 0.021 [symbol] | 100% [symbol] | 27% [symbol] | 0.004 [symbol] | 0.006 [symbol] | 5% [symbol] | 8% [symbol] | −4.2 [symbol] | 17.2 [symbol] |

### (Note in Table)

λₘₐₓ means a wavelength at which the highest absorbance Ab (λ) is exhibited among the maximal absorption wavelengths that the light absorption filter has in a wavelength range of 400 to 700 nm.

The blending amount of the dye and the compound B means an amount in terms of a part by mass with respect to 100 parts by mass of the filter.

Ab (λₘₐₓ) means the value of the absorbance at the maximal absorption wavelength max.

“-” in the column of decolorization rate indicates that the corresponding dye is not contained.

From the results in Table 1 and Table 2, the following points can be seen.

In all of the light absorption filters Nos. c202 to c206 of Comparative Examples, which did not contained any of the azo-based coloring agent represented by any of General Formulae (i) to (iv) and the indoaniline-based coloring agent represented by General Formula (v) but contained any of the comparative dyes 1 to 5, the decolorization rate upon irradiation with UV light was low.

In contrast to these, in all of the light absorption filters Nos. 101 and 104 according to the embodiment of the present invention which contain the dye B-19 or B-18 which is an azo-based coloring agent represented by General Formula (i), the light absorption filters Nos. 105 and 106 according to the embodiment of the present invention which contain the dye D-1 or D-2 which is an azo-based coloring agent represented by General Formula (iv), the light absorption filters Nos. 107 and 108 according to the embodiment of the present invention which contain the dye E-1 or E-2 which is an azo-based coloring agent represented by General Formula (iii), the light absorption filter No. 109 according to the embodiment of the present invention which contains the dye F-1 which is an azo-based coloring agent represented by General Formula (ii), and the light absorption filters Nos. 110 and 111 according to the embodiment of the present invention which contain the dye G-1 or G-2 which is an indoaniline-based coloring agent represented by General Formula (v), the decolorization rate upon irradiation with UV light was high, there was almost no secondary absorption associated with the decomposition of the dye upon UV light irradiation, and the decolorizing properties in a case of being irradiated with ultraviolet rays at room temperature was excellent.

In addition, it was found that, in all of the light absorption filters Nos. 102 and 103 according to the embodiment of the present invention in which the dye B-19 which is an azo-based coloring agent represented by General Formula (i) is used in combination with the dye C-73 and the dye 7-23 which are squaraine-based coloring agents represented by General Formula (1), and the light absorption filter No. 112 according to the embodiment of the present invention in which the dye B-19 which is an azo-based coloring agent represented by General Formula (i), and the dye E-2 which is an azo-based coloring agent represented by General Formula (iii), are used in combination with the dye C-73 which is a squaraine-based coloring agent represented by General Formula (1), the tint of the reflected light can also be adjusted to be neutral in addition to the excellent decolorizing properties in a case of being irradiated with ultraviolet light at room temperature.

Although the present invention has been described with reference to the embodiments, it is the intention of the inventors of the present invention that the present invention should not be limited by any of the details of the description unless otherwise specified and rather be construed broadly within the spirit and scope of the invention appended in WHAT IS CLAIMED IS.

### Explanation of References

1: upper polarizing plate
2: direction of absorption axis of upper polarizing plate
3: liquid crystal cell upper electrode substrate
4: alignment control direction of upper substrate
5: liquid crystal layer
6: liquid crystal cell lower electrode substrate
7: alignment control direction of lower substrate
8: lower polarizing plate
9: direction of absorption axis of lower polarizing plate
B: backlight unit
10: liquid crystal display device
11: aluminum foil substrate
91: light absorption filter
D65: white light having spectrum of standard illuminant D65 defined by International Commission on Illumination (CIE)
R: reflected light

What is claimed is:

1. Alight absorption filter comprising:
a resin;
a dye having a main absorption wavelength band in a wavelength range of 400 to 700 nm; and
a compound that generates a radical upon ultraviolet irradiation,
wherein the dye includes at least one of an azo-based coloring agent represented by any of General Formulae (i) to (iv) or an indoaniline-based coloring agent represented by General Formula (v), 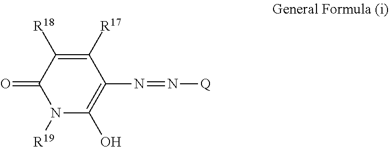
in the formula, R¹⁷ and R¹⁸ each independently represent a hydrogen atom or a monovalent substituent,
R¹⁹ represents a hydrogen atom, an aliphatic group, an aryl group, a heterocyclic group, a carbamoyl group, an alkoxycarbonyl group, an aryloxycarbonyl group, an acyl group, an alkylsulfonyl group, an arylsulfonyl group, or a sulfamoyl group, and
Q represents a diazo component residue,
provided that R¹⁷ to R¹⁹ and Q do not have a squaraine structure, 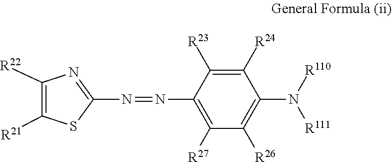
in the formula, R²¹ to R²⁴, R²⁶, and R²⁷ represent a hydrogen atom, a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)R¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, or a heterocyclic group,
R¹⁰⁸ to R¹²¹ represent a hydrogen atom, an acyclic hydrocarbon group, a monocyclic hydrocarbon group, a fused polycyclic hydrocarbon group, or a heterocyclic group, and
n is a positive integer,
here, the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR¹⁰⁸, —SR¹⁰⁹, —NR¹¹⁰R¹¹¹, —S(═O)₂NR¹¹²R¹¹³, —C(═O)NR¹¹⁴R¹¹⁵, —NHC(═O)R¹¹⁶, —C(═O)OR¹¹⁷, —O(CH₂CH₂O)ₙR¹¹⁸, —O(CH₂CH₂S)ₙR¹¹⁹, —S(CH₂CH₂O)ₙR¹²⁰, —S(CH₂CH₂S)ₙR¹²¹, an acyclic hydrocarbon group, a monocyclic hydrocarbon group, a fused polycyclic hydrocarbon group, and a heterocyclic group, 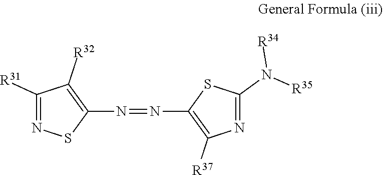
in the formula, R³¹ represents a hydrogen atom, an alkyl group, an alkoxy group, a cyano group, a carbonyl group, an aromatic group, or a heterocyclic group,
R³² represents a hydrogen atom, an alkyl group, an alkoxy group, a cyano group, a nitro group, a carbonyl group, an aromatic group, or a heterocyclic group,
R³⁴ and R³⁵ each independently represent a hydrogen atom, an alkyl group, or an aromatic group, and
R³⁷ represents a hydrogen atom, an alkyl group, an alkoxy group, a cyano group, a carbonyl group, an acylamino group, or an aromatic group, 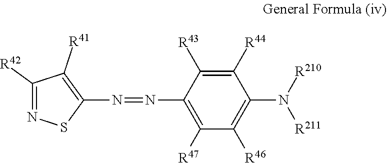
in the formula, R⁴¹ to R⁴⁴, R⁴⁶, and R⁴⁷ represent a hydrogen atom, a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, an acyclic hydrocarbon group, a monocyclic hydrocarbon group, a fused polycyclic hydrocarbon group, or a heterocyclic group,
R²⁰⁸ to R²²¹ represent a hydrogen atom, an acyclic hydrocarbon group, a monocyclic hydrocarbon group, a fused polycyclic hydrocarbon group, or a heterocyclic group, and
n is a positive integer,
here, the acyclic hydrocarbon group, the monocyclic hydrocarbon group, the fused polycyclic hydrocarbon group, or the heterocyclic group may have, as a substituent, one or two or more of a halogen atom, a cyano group, a nitro group, a carboxy group, a sulfo group, —OR²⁰⁸, —SR²⁰⁹, —NR²¹⁰R²¹¹, —S(═O)₂NR²¹²R²¹³, —C(═O)NR²¹⁴R²¹⁵, —NHC(═O)R²¹⁶, —C(═O)OR²¹⁷, —O(CH₂CH₂O)ₙR²¹⁸, —O(CH₂CH₂S)ₙR²¹⁹, —S(CH₂CH₂O)ₙR²²⁰, —S(CH₂CH₂S)ₙR²²¹, an acyclic hydrocarbon group, a monocyclic hydrocarbon group, a fused polycyclic hydrocarbon group, and a heterocyclic group, 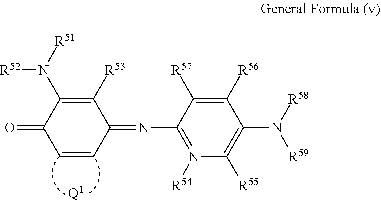
in the formula, Q¹ represents an atomic group that contains at least one nitrogen atom and is necessary for forming a 5- to 7-membered nitrogen-containing heterocyclic ring together with carbon atoms to be bonded,
R⁵¹ represents an acyl group, an alkoxycarbonyl group, an aryloxycarbonyl group, an aminocarbonyl group, or a sulfonyl group,
R⁵² represents a hydrogen atom or an alkyl group,
R⁵³ to R⁵⁷ represent a hydrogen atom, an alkyl group, an alkoxy group, an acylamino group, an alkylsulfonylamino group, or a halogen atom, and
R⁵¹ and R⁵⁹ represent a hydrogen atom, an alkyl group, or an aryl group.

2. The light absorption filter according to claim 1,
wherein the compound that generates the radical upon the ultraviolet irradiation includes a combination of a compound A having an acid group and a compound B having a structure that is capable of forming a hydrogen bond with the acid group contained in the compound A.

3. The light absorption filter according to claim 1,
wherein the dye having the main absorption wavelength band in the wavelength range of 400 to 700 nm includes a squaraine-based coloring agent represented by General Formula (1), 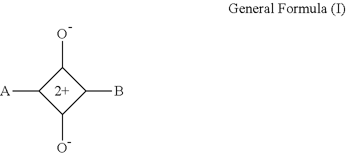
in the formula, A and B each independently represent an aryl group which may have a substituent, a heterocyclic group which may have a substituent, or —CH=G,
where G represents a heterocyclic group which may have a substituent.

4. The light absorption filter according to claim 2,
wherein the compound A having the acid group is chemically bonded to a polymer that constitutes the resin.

5. The light absorption filter according to claim 1,
wherein in the light absorption filter, the dye having the main absorption wavelength band in the wavelength range of 400 to 700 nm undergoes a chemical change and decolorizes upon ultraviolet irradiation.

6. An optical filter that is obtained by subjecting the light absorption filter according to claim 1 to mask exposure by ultraviolet irradiation.

7. An organic electroluminescent display device, an inorganic electroluminescent display device, comprising:
the optical filter according to claim 6.

8. An inorganic electroluminescent display device, or a liquid crystal display device, comprising:
the optical filter according to claim 6.

9. A liquid crystal display device, comprising:
the optical filter according to claim 6.

10. The organic electroluminescent display device according to claim 7,
wherein a layer that inhibits light absorption of the compound that generates the radical upon the ultraviolet irradiation is provided on a viewer side with respect to the optical filter.

11. The inorganic electroluminescent display device according to claim 8,
wherein a layer that inhibits light absorption of the compound that generates the radical upon the ultraviolet irradiation is provided on a viewer side with respect to the optical filter.

12. The liquid crystal display device according to claim 9,
wherein a layer that inhibits light absorption of the compound that generates the radical upon the ultraviolet irradiation is provided on a viewer side with respect to the optical filter.

13. A manufacturing method for an optical filter comprising:
irradiating the light absorption filter according to claim 1 with an ultraviolet ray to carry out mask exposure.
